(19) United States
(12) Patent Application Publication
(10) Pub. No.: US 2024/0265984 A1
(43) Pub. Date: Aug. 8, 2024

(54) MEMORY DEVICE

(71) Applicant: Kioxia Corporation, Tokyo (JP)

(72) Inventors: Noboru SHIBATA, Kawasaki Kanagawa (JP); Kikuko SUGIMAE, Yokohama Kanagawa (JP); Yusuke ARAYASHIKI, Kawasaki Kanagawa (JP); Katsuya NISHIYAMA, Yokohama Kanagawa (JP); Motohiko FUJIMATSU, Tokyo (JP); Akiyuki MURAYAMA, Tokyo (JP)

(73) Assignee: Kioxia Corporation, Tokyo (JP)

(21) Appl. No.: 18/432,269

(22) Filed: Feb. 5, 2024

(30) Foreign Application Priority Data
Feb. 7, 2023 (JP) 2023-017150

(51) Int. Cl. G11C 16/34; G11C 16/10; G11C 16/26

(52) U.S. Cl. CPC G11C 16/3459; G11C 16/102; G11C 16/26

(57) ABSTRACT

According to one embodiment, a memory device includes a first memory cell and a sequencer. The first memory cell is configured to store multi-bit data with a k-value threshold voltage level (k is an integer of 2 or larger). The sequencer is configured to execute a write operation having a loop process including a program operation and a verify operation. The program operation includes a first program process and a second program process. The sequencer is further configured to cause the first memory cell to store data by either the first program process or the second program process according to data to be written into the first memory cell in the write operation.

### CROSS-REFERENCE TO RELATED APPLICATIONS

This application is based upon and claims the benefit of priority from Japanese Patent Application No. 2023-017150, filed Feb. 7, 2023, the entire contents of which are incorporated herein by reference.

### FIELD

Embodiments described herein relate generally to a memory device.

### BACKGROUND

There is known a NAND-type flash memory that is capable of storing data in a nonvolatile manner.

### BRIEF DESCRIPTION OF DRAWINGS

FIG. 1 is a block diagram illustrating an example of a configuration of a memory device according to a first embodiment.

FIG. 2 is a circuit diagram illustrating an example of a circuit configuration of a memory cell array included in the memory device according to the first embodiment.

FIG. 3 is a circuit diagram illustrating an example of a circuit configuration of a row decoder module included in the memory device according to the first embodiment.

FIG. 4 is a circuit diagram illustrating an example of a circuit configuration of a sense amplifier module included in the memory device according to the first embodiment.

FIG. 5 is a plan view of an example of a planar layout of the memory cell array included in the memory device according to the first embodiment.

FIG. 6 is a cross-sectional view taken along line VI-VI of FIG. 5 of an example of a cross-sectional structure of the memory cell array included in the memory device according to the first embodiment.

FIG. 7 is a cross-sectional view taken along line VII-VII of FIG. 6 of an example of a cross-sectional structure of a memory pillar included in the memory device according to the first embodiment.

FIG. 8 is a schematic diagram illustrating an example of a data storage area of a NAND string included in the memory device according to the first embodiment.

FIG. 9 is a distribution diagram illustrating an example of threshold voltage distribution of a memory cell transistor included in the memory device according to the first embodiment.

FIG. 10 is a table illustrating an example of allocation of data used in the memory device according to the first embodiment.

FIG. 11 is a time chart illustrating an outline of a write operation of the memory device according to the first embodiment.

FIG. 12 is a flowchart illustrating an example of a write operation of the memory device according to the first embodiment.

FIG. 13 is a schematic diagram illustrating a specific example of an “ACE” program of the memory device according to the first embodiment.

FIG. 14 is a schematic diagram illustrating a specific example of a “BDFG” program of the memory device according to the first embodiment.

FIG. 15 is a timing chart illustrating an example of lower-page read of the memory device according to the first embodiment.

FIG. 16 is a timing chart illustrating an example of middle-page read of the memory device according to the first embodiment.

FIG. 17 is a timing chart illustrating an example of upper-page read of the memory device according to the first embodiment.

FIG. 18 is a graph illustrating an example of IV characteristics of a memory cell transistor in a memory device according to a comparative example.

FIG. 19 is a graph illustrating an example of IV characteristics of the memory cell transistor in the memory device according to the first embodiment.

FIG. 20 is a table illustrating an example of data allocation in a modification of the first embodiment.

FIG. 21 is a timing chart illustrating an example of lower-page read according to a modification of the first embodiment.

FIG. 22 is a timing chart illustrating an example of middle-page read according to the modification of the first embodiment.

FIG. 23 is a timing chart illustrating an example of upper-page read according to the modification of the first embodiment.

FIG. 24 is a distribution diagram illustrating an example of threshold voltage distribution of a memory cell transistor included in a memory device according to a second embodiment.

FIG. 25 is a flowchart illustrating an example of a write operation of the memory device according to the second embodiment.

FIG. 26 is a graph illustrating an example of IV characteristics of the memory cell transistor in the memory device according to the second embodiment.

FIG. 27 is a cross-sectional view of an example of a cross-sectional structure of a memory pillar included in a memory device according to a third embodiment.

FIG. 28 is a cross-sectional view taken along line XXVIII-XXVIII of FIG. 27 of an example of the cross-sectional structure of the memory pillar included in the memory device according to the third embodiment.

FIG. 29 is a cross-sectional view taken along line XXIX-XXIX of FIG. 27 of an example of the cross-sectional structure of the memory pillar included in the memory device according to the third embodiment.

FIG. 30 is a schematic diagram illustrating an example of a data storage area of a NAND string included in the memory device according to the third embodiment.

FIG. 31 is a graph illustrating an example of IV characteristics of a memory cell transistor included in the memory device according to the third embodiment.

FIG. 32 is a flowchart illustrating an example of a write operation of the memory device according to the third embodiment.

FIG. 33 is a schematic diagram illustrating a specific example of an HE program for a selected string in the memory device according to the third embodiment.

FIG. 34 is a schematic diagram illustrating a specific example of an HE program for an unselected string in the memory device according to the third embodiment.

FIG. 35 is a schematic diagram illustrating a specific example of an FN program for a selected string in the memory device according to the third embodiment.

FIG. 36 is a schematic diagram illustrating a specific example of an FN program for an unselected string in the memory device according to the third embodiment.

FIG. 37 is a flowchart illustrating an example of a method for manufacturing the memory device according to the third embodiment.

FIG. 38 is a cross-sectional view of an example of a cross-sectional structure in the process of manufacturing the memory device according to the third embodiment.

FIG. 39 is a cross-sectional view taken along line XXXIX-XXXIX of FIG. 38 of an example of a cross-sectional structure in the process of manufacturing the memory device according to the third embodiment.

FIG. 40 is a cross-sectional view of an example of a cross-sectional structure in the process of manufacturing the memory device according to the third embodiment.

FIG. 41 is a cross-sectional view taken along line XXXXI-XXXXI of FIG. 40 of an example of a cross-sectional structure in the process of manufacturing the memory device according to the third embodiment.

FIG. 42 is a cross-sectional view of an example of a cross-sectional structure in the process of manufacturing the memory device according to the third embodiment.

FIG. 43 is a cross-sectional view taken along line XXXXIII-XXXXIII of FIG. 42 of an example of a cross-sectional structure in the process of manufacturing the memory device according to the third embodiment.

FIG. 44 is a cross-sectional view of an example of a cross-sectional structure in the process of manufacturing the memory device according to the third embodiment.

FIG. 45 is a cross-sectional view taken along line XXXXV-XXXXV in FIG. 44 of an example of a cross-sectional structure in the process of manufacturing the memory device according to the third embodiment.

FIG. 46 is a cross-sectional view of an example of a cross-sectional structure in the process of manufacturing the memory device according to the third embodiment.

FIG. 47 is a cross-sectional view taken along line XXXXVII-XXXXVII of FIG. 46 of an example of a cross-sectional structure in the process of manufacturing the memory device according to the third embodiment.

FIG. 48 is a cross-sectional view of an example of a cross-sectional structure in the process of manufacturing the memory device according to the third embodiment.

FIG. 49 is a cross-sectional view taken along line XXXXIX-XXXXIX of FIG. 48 of an example of a cross-sectional structure in the process of manufacturing the memory device according to the third embodiment.

FIG. 50 is a cross-sectional view of an example of a cross-sectional structure in the process of manufacturing the memory device according to the third embodiment.

FIG. 51 is a cross-sectional view taken along line LI-LI in FIG. 50 of an example of a cross-sectional structure in the process of manufacturing the memory device according to the third embodiment.

FIG. 52 is a cross-sectional view of an example of a cross-sectional structure in the process of manufacturing the memory device according to the third embodiment.

FIG. 53 is a cross-sectional view taken along line LIII-LIII of FIG. 52 of an example of a cross-sectional structure in the process of manufacturing the memory device according to the third embodiment.

FIG. 54 is a cross-sectional view taken along line LIV-LIV of FIG. 52 of an example of a cross-sectional structure in the process of manufacturing the memory device according to the third embodiment.

FIG. 55 is a circuit diagram illustrating an example of a circuit configuration of a memory cell array included in a memory device according to a fourth embodiment.

FIG. 56 is a plan view of an example of a planar layout of the memory cell array included in the memory device according to the fourth embodiment.

FIG. 57 is a cross-sectional view of an example of a cross-sectional structure of the memory cell array included in the memory device according to the fourth embodiment.

FIG. 58 is a cross-sectional view of an example of a cross-sectional structure of a memory pillar included in the memory device according to the fourth embodiment.

FIG. 59 is a cross-sectional view taken along line LIX-LIX of FIG. 58 of an example of a cross-sectional structure of the memory pillar included in the memory device according to the fourth embodiment.

FIG. 60 is a schematic diagram illustrating a specific example of an HE program for a selected memory group in the memory device according to the fourth embodiment.

FIG. 61 is a schematic diagram illustrating a specific example of an HE program for an unselected memory group in the memory device according to the fourth embodiment.

FIG. 62 is a schematic diagram illustrating a specific example of an FN program for a selected memory group in the memory device according to the fourth embodiment.

FIG. 63 is a schematic diagram illustrating a specific example of an FN program for an unselected memory group in the memory device according to the fourth embodiment.

FIG. 64 is a flowchart illustrating an example of a method for manufacturing the memory device according to the fourth embodiment.

FIGS. 65 to 72 are cross-sectional views of an example of a cross-sectional structure in the process of manufacturing the memory device according to the fourth embodiment.

### DETAILED DESCRIPTION

In general, according to one embodiment, a memory device includes a first memory cell and a sequencer. The first memory cell is configured to store multi-bit data with a k-value threshold voltage level (k is an integer of 2 or larger). The sequencer is configured to execute a write operation having a loop process including a program operation and a verify operation. The program operation includes a first program process and a second program process. The sequencer is further configured to cause the first memory cell to store data by either the first program process or the second program process according to data to be written into the first memory cell in the write operation.

Embodiments will be described below with reference to the drawings. Each of the embodiments exemplifies a device or method for carrying out the technical ideas of the invention. The drawings are schematic or conceptual. Dimensions, ratios, and the like in the drawings are not necessarily the same as actual ones. The illustration of components is omitted as appropriate. The hatching added to the plan views is not necessarily related to the materials and characteristics of the constituent elements. Herein, constituent elements having substantially the same function and configuration are denoted by the same reference numerals. Numbers, characters, and the like added to reference numerals are referred to by the same reference numerals, and are used to distinguish between similar elements.

### <1> First Embodiment

A memory device 1 according to a first embodiment executes a write operation in which the state of an S-factor of a memory cell can be written in two types. The memory device 1 according to the first embodiment reads multi-bit data from the memory cell using two types of sense times. Hereinafter, details of the memory device 1 according to the first embodiment will be described.

### <1-1> Configuration

First, a configuration of the memory device 1 according to the first embodiment will be described.

### <1-1-1> Configuration of Memory Device 1

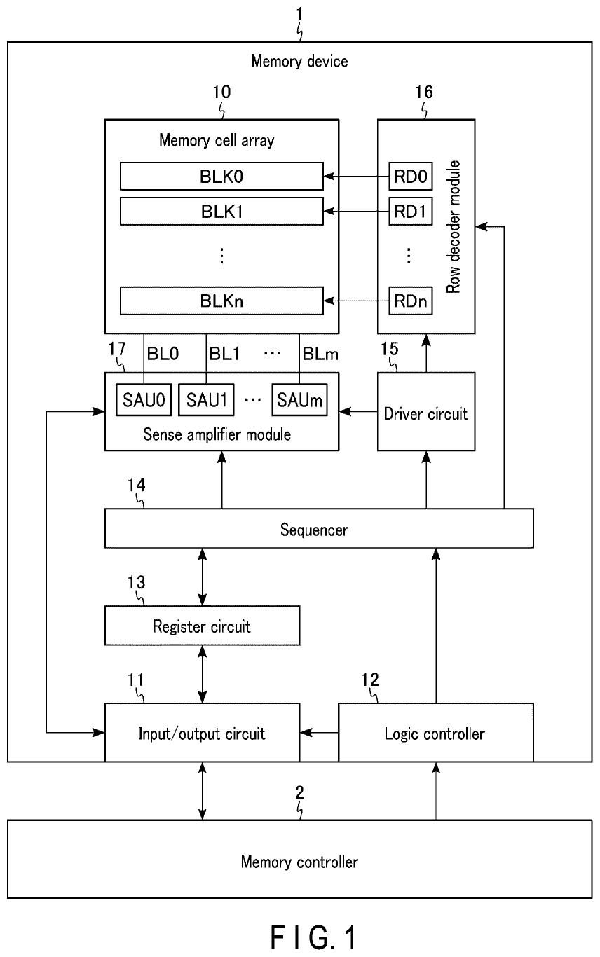

FIG. 1 is a block diagram illustrating an example of a configuration of a memory device 1 according to a first embodiment. As illustrated in FIG. 1, the memory device 1 is controlled by an external memory controller 2. The memory device 1 is a NAND-type flash memory capable of storing data in a nonvolatile manner, for example. The memory device 1 includes, for example, a memory cell array 10, an input/output circuit 11, a logic controller 12, a register circuit 13, a sequencer 14, a driver circuit 15, a row decoder module 16, and a sense amplifier module 17.

The memory cell array 10 includes a plurality of blocks BLK0 to BLKn (“n” is an integer of 1 or larger). The block BLK is a set of a plurality of memory cells. The block BLK corresponds to the unit of erasing data, for example. The block BLK includes a plurality of pages. The page corresponds to a unit in which read and write of data are executed. Although not illustrated, the memory cell array 10 is provided with a plurality of bit lines BL0 to BLm (“m” is an integer of 1 or larger) and a plurality of word lines WL. Each memory cell is associated with one bit line BL and one word line WL, for example. Each block BLK is assigned with a block address. Each bit line BL is assigned with a column address. Each word line WL is assigned with a page address.

The input/output circuit 11 is an interface circuit that controls transmission and reception of input/output signals to and from the memory controller 2. The input/output signal includes data, status information, address information, a command, and the like, for example. The input/output circuit 11 can input and output data between the sense amplifier module 17 and the memory controller 2. The input/output circuit 11 can output the status information transferred from the register circuit 13 to the memory controller 2. The input/output circuit 11 can output the address information and the command transferred from the memory controller 2 to the register circuit 13.

The logic controller 12 controls the input/output circuit 11 and the sequencer 14 based on a control signal input from the memory controller 2. For example, the logic controller 12 controls the sequencer 14 to enable the memory device 1. The logic controller 12 notifies the input/output circuit 11 that the input/output signal received by the input/output circuit 11 is a command or address information. The logic controller 12 orders the input/output circuit 11 to input or output an input/output signal.

The register circuit 13 temporarily stores status information, address information, and commands. The status information is updated under the control of the sequencer 14 and transferred to the input/output circuit 11. The address information includes a block address, a page address, a column address, and the like. The commands include instructions relating to various operations of the memory device 1.

The sequencer 14 controls the entire operations of the memory device 1. The sequencer 14 executes a read operation, a write operation, an erase operation, and the like, based on the command and the address information stored in the register circuit 13.

The driver circuit 15 generates a voltage used in a read operation, a write operation, an erase operation, and the like. Then, the driver circuit 15 supplies the generated voltage to the row decoder module 16, the sense amplifier module 17, and the like.

The row decoder module 16 is a circuit used for selecting the block BLK to be operated and transferring a voltage to wiring such as the word line WL. The row decoder module 16 includes a plurality of row decoders RD0 to RDn. The row decoders RD0 to RDn are associated with the blocks BLK0 to BLKn, respectively.

The sense amplifier module 17 is a circuit used for transferring a voltage to each bit line BL and reading data. The sense amplifier module 17 includes a plurality of sense amplifier units SAU0 to SAUm. The sense amplifier units SAU0 to SAUm are associated with the plurality of bit lines BL0 to BLm, respectively.

A combination of the memory device 1 and the memory controller 2 may constitute one semiconductor device. Examples of such a semiconductor device include a memory card such as SD™ card, a solid state drive (SSD), and others.

### <1-1-2> Circuit Configuration of Memory Device 1

Next, a circuit configuration of the memory device 1 according to the first embodiment will be described.

### (Circuit Configuration of Memory Cell Array 10)

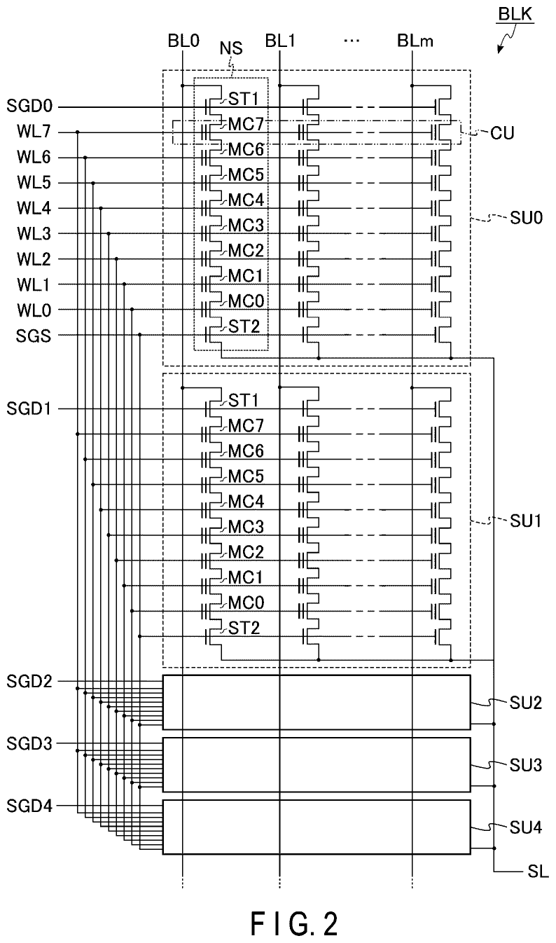

FIG. 2 is a circuit diagram illustrating an example of a circuit configuration of the memory cell array 10 included in the memory device 1 according to the first embodiment. FIG. 2 illustrates one block BLK among the plurality of blocks BLK included in the memory cell array 10. As illustrated in FIG. 2, the block BLK includes five string units SU0 to SU4, for example. Select gate lines SGD0 to SGD4 and SGS and word lines WL0 to WL7 are provided for each block BLK. The bit lines BL0 to BLm and the source line SL are shared by the plurality of blocks BLK, for example.

Each string unit SU includes a plurality of NAND strings NS. The plurality of NAND strings NS is associated with the bit lines BL0 to BLm, respectively. Each NAND string NS is connected between the associated bit line BL and source line SL. Each NAND string NS includes memory cell transistors MC0 to MC7 and select transistors ST1 and ST2, for example. Each memory cell transistor MC is a transistor having a control gate and a charge storage layer, and holds (stores) data in a nonvolatile manner. The memory cell transistor MC of the first embodiment is a charge trap-type memory cell. Each of the select transistors ST1 and ST2 is used to select the string unit SU.

In each NAND string NS, the select transistor ST1, the memory cell transistors MC7 to MC0, and the select transistor ST2 are connected in series. Specifically, the drain end and source end of the select transistor ST1 are connected to the associated bit line BL and the drain end of the memory cell transistor MC7, respectively. The drain end and source end of the select transistor ST2 are connected to the source end of the memory cell transistor MC0 and the source line SL, respectively. The memory cell transistors MC0 to MC7 are connected in series between the select transistors ST1 and ST2.

The select gate lines SGD0 to SGD4 are associated with the string units SU0 to SU4, respectively. Each select gate line SGD is connected to the gate ends of the plurality of select transistors ST1 included in the associated string unit SU. The select gate line SGS is connected to the gate ends of the plurality of select transistors ST2 included in the associated block BLK. The word lines WL0 to WL7 are connected to the control gate ends of the memory cell transistors MC0 to MC7 of the NAND strings NS included in the associated block BLK, respectively.

A set of the plurality of memory cell transistors MC connected to the common word line WL in the same string unit SU is called “cell unit CU”, for example. For example, the storage capacity of the cell unit CU in a case where each memory cell transistor MC stores 1-bit data, is defined as “1-page data”. The cell unit CU can have a storage capacity of two-page data or more according to the bit count of the data stored in each memory cell transistor MC.

The circuit configuration of the memory cell array 10 included in the memory device 1 according to the first embodiment may be another configuration. For example, the number of the string units SU included in each block BLK and the number of the memory cell transistors MC and the select transistors ST1 and ST2 included in each NAND string NS can be designed to any numbers.

### (Circuit Configuration of Row Decoder Module 16)

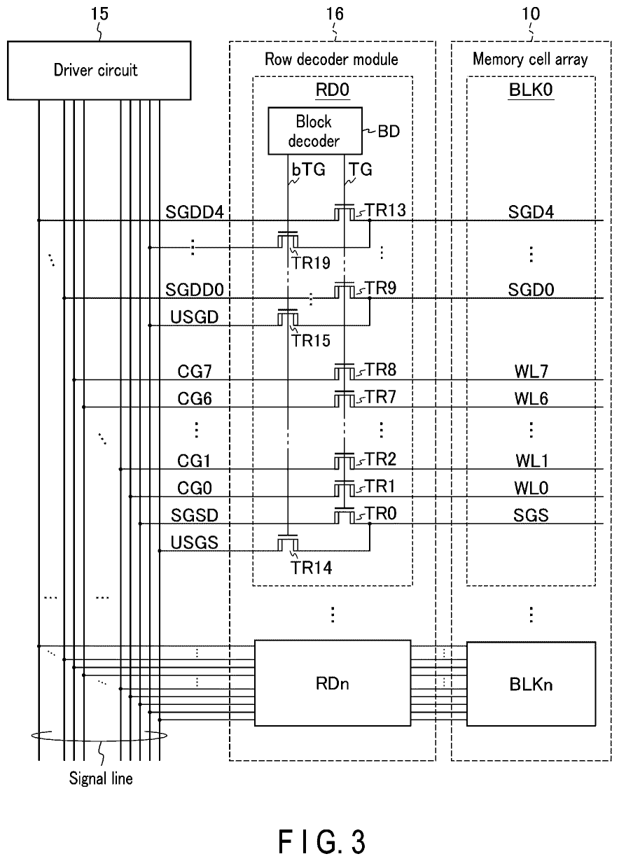

FIG. 3 is a circuit diagram illustrating an example of a circuit configuration of the row decoder module 16 included in the memory device 1 according to the first embodiment. FIG. 3 illustrates a connection relationship among the row decoder module 16, the driver circuit 15, and the memory cell array 10, and a detailed circuit configuration of the row decoder RD0. As illustrated in FIG. 3, the row decoders RD and the driver circuit 15 are connected via signal lines CG0 to CG7, SGDD0 to SGDD4, SGSD, USGD, and USGS, for example. Each row decoder RD and the associated block BLK are connected via the word lines WL0 to WL7 and the select gate lines SGS and SGD0 to SGD4, for example.

Hereinafter, a connection relationship among each element of the row decoder RD, the driver circuit 15, and the block BLK0 will be described focusing on the row decoder RD0. Configurations of the other row decoders RD are similar to that of the row decoder RD0 except that the block BLK associated therewith is different. The row decoder RD0 includes transistors TR0 to TR19, transfer gate lines TG and bTG, and a block decoder BD, for example.

Each of the transistors TR0 to TR19 is an N-type MOS transistor (hereinafter, also referred to as “high-voltage transistor”) having a high withstand voltage. Herein, the threshold voltage of the high-voltage transistor is designed to be 10 V or more. The drain end and source end of the transistor TR0 are connected to the signal line SGSD and the select gate line SGS, respectively. The drain ends of the transistors TR1 to TR8 are connected to the signal lines CG0 to CG7, respectively. The source ends of the transistors TR1 to TR8 are connected to word lines WL0 to WL7, respectively. The drain ends of the transistors TR9 to TR13 are connected to the signal lines SGDD0 to SGDD4, respectively. The source ends of the transistors TR9 to TR13 are connected to the select gate lines SGD0 to SGD4, respectively. The drain end and source end of the transistor TR14 are connected to the signal line USGS and the select gate line SGS, respectively. The drain ends of the transistors TR15 to TR19 are connected to the signal line USGD. The source ends of the transistors TR15 to TR19 are connected to the select gate lines SGD0 to SGD4, respectively. The gate ends of the transistors TR0 to TR13 are connected to the transfer gate line TG. The gate ends of the transistors TR14 to TR19 are connected to a transfer gate line bTG. An inverted signal of a signal input to the transfer gate line TG is input to the transfer gate line bTG.

The block decoder BD is a circuit having a function of decoding a block address. The block decoder BD applies a predetermined voltage to the transfer gate lines TG and bTG based on the decoding result of the block address. Specifically, the block decoder BD corresponding to the selected block BLK applies voltages at “H” level and “L” level to the transfer gate lines TG and bTG, respectively. The block decoder BD corresponding to the unselected block BLK applies voltages at “L” level and “H” level to the transfer gate lines TG and bTG, respectively. Accordingly, the voltages of the signal lines CG0 to CG7 are transferred to the word lines WL0 to WL7 of the selected block BLK, respectively, the voltages of the signal lines SGDD0 to SGDD4 and SGSD are transferred to the select gate lines SGD0 to SGD4 and SGS of the selected block BLK, respectively, and the voltages of the signal lines USGD and USGS are transferred to the select gate lines SGD and SGS of the unselected block BLK, respectively.

The row decoder module 16 may have another circuit configuration. For example, the number of transistors TR included in the row decoder module 16 can be changed according to the number of wirings provided in each block BLK. The signal line CG may also be referred to as “global word line” because it is shared among the plurality of blocks BLK. The word line WL may also be referred to as “local word line” because it is provided for each block. Each of the signal lines SGDD and SGSD may also be referred to as “global transfer gate line” because they are shared among the plurality of blocks BLK. Each of the select gate lines SGD and SGS may also be referred to as “local transfer gate line” because they are provided for each block BLK.

### (Circuit Configuration of Sense Amplifier Module 17)

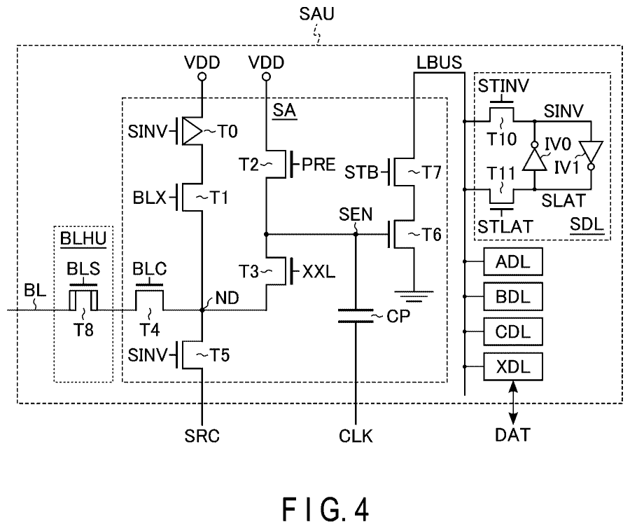

FIG. 4 is a circuit diagram illustrating an example of a circuit configuration of the sense amplifier module 17 included in the memory device 1 according to the first embodiment. FIG. 4 illustrates an extracted circuit configuration of one sense amplifier unit SAU. As illustrated in FIG. 4, the sense amplifier unit SAU includes a sense amplifier part SA, a bit line connection part BLHU, latch circuits SDL, ADL, BDL, CDL, and XDL, and a bus LBUS, for example. The sense amplifier part SA and the latch circuits SDL, ADL, BDL, CDL, and XDL are capable of transmitting and receiving data via the bus LBUS, for example.

The sense amplifier part SA is a circuit that is used for determination of data based on the voltage of the bit line BL and application of a voltage to the bit line BL. In response to assertion of the control signal STB during the read operation, the sense amplifier part SA determines whether the data read from the selected memory cell transistor MC is “0” or “1” based on the voltage of the associated bit line BL. Each of the latch circuits SDL, ADL, BDL, CDL, and XDL is a circuit capable of temporarily holding data. The latch circuit XDL is used for input/output of data DAT between the sense amplifier unit SAU and the input/output circuit 11. The latch circuit XDL can also be used as a cache memory. The latch circuit XDL may be sharable among a plurality of sense amplifier units SAU.

The sense amplifier part SA includes transistors T0 to T7, a capacitor CP, and nodes ND, SEN, and SRC. The bit line connection part BLHU is a switch circuit for preventing a high voltage to be applied to the channel of the NAND string NS from being applied to the sense amplifier part SA in the erase operation. The bit line connection part BLHU includes a transistor T8. The latch circuit SDL includes inverters IV0 and IV1, transistors T10 and T11, and nodes SINV and SLAT. The transistor T0 is a P-type MOS transistor. The transistors T1 to T8, T10, and T11 are N-type MOS transistors. The transistor T8 is an N-type high-voltage transistor.

The gate end of the transistor T0 is connected to the node SINV. The source end of the transistor T0 is connected to a power supply line. The drain end of the transistor T0 is connected to the source end of the transistor T1. The source end of the transistor T1 is connected to the node ND. The drain end of the transistor T2 is connected to the power supply line. The source end of the transistor T2 is connected to the node SEN. The node SEN is connected to the drain end of the transistor T3, the gate end of the transistor T6, and one electrode of the capacitor CP. The source end of the transistor T3 is connected to the node ND. The node ND is connected to the drain ends of the transistors T4 and T5. The source end of the transistor T4 is connected to the drain end of the transistor T8. The source end of the transistor T8 is electrically connected to the associated bit line BL. The source end of the transistor T5 is connected to the node SRC. The gate end of the transistor T5 is connected to the node SINV. The source end of the transistor T6 is connected to the ground node. The drain end and source end of the transistor T7 are connected to the bus LBUS and the drain end of the transistor T6, respectively.

For example, a power supply voltage VDD is applied to the source end of the transistor T0. For example, a ground voltage VSS is applied to the node SRC. Control signals BLX, PRE, XXL, BLC, and STB are input to the gate ends of the transistors T1, T2, T3, T4, and T7, respectively. A control signal BLS is input to the gate end of the transistor T8. A clock signal CLK is input to the other electrode of the capacitor CP.

The input node and output node of the inverter IV0 are connected to the nodes SLAT and SINV, respectively. The input node and output node of the inverter IV1 are connected to the nodes SINV and SLAT, respectively. One end and the other end of the transistor T10 are connected to the node SINV and the bus LBUS, respectively. A control signal STINV is input to the gate end of the transistor T10. One end and the other end of the transistor T11 are connected to the node SLAT and the bus LBUS, respectively. A control signal STLAT is input to the gate end of the transistor T11. The latch circuit SDL holds data in the node SLAT, and holds inverted data of the data held in the node SLAT, in the node SINV.

The circuit configurations of the latch circuits ADL, BDL, CDL, and XDL are similar to those of the latch circuit SDL. For example, the latch circuit ADL holds data in the node ALAT and holds inverted data thereof in the node AINV. A control signal ATINV is input to the gate end of the transistor T10 of the latch circuit ADL, and a control signal ATLAT is input to the gate end of the transistor T11 of the latch circuit ADL. The latch circuit BDL holds data in the node BLAT and holds inverted data thereof in the node BINV. A control signal BTINV is input to the gate end of the transistor T10 of the latch circuit BDL, and a control signal BTLAT is input to the gate end of the transistor T11 of the latch circuit BDL. The same applies to the latch circuits CDL and XDL, and thus description thereof is omitted.

The control signals BLX, PRE, XXL, BLC, STB, BLS, STINV, and STLAT are generated by the sequencer 14, for example. The sense amplifier module 17 may have another circuit configuration. For example, the number of latch circuits included in each sense amplifier unit SAU can be changed according to the number of bits stored in the memory cell transistor MC. The sense amplifier unit SAU may have an arithmetic circuit capable of executing simple logical operations. The sense amplifier module 17 can make definite (determine) data stored in the memory cell transistor MC by executing arithmetic processing using the latch circuit as appropriate in the read operation of each page.

### <1-1-3> Structure of Memory Device 1

Next, a structure of the memory device 1 according to the first embodiment will be described. In the drawings referred to below, a three-dimensional Cartesian coordinate system is used. The X direction corresponds to the extending direction of the word line WL. The Y direction corresponds to the extending direction of the bit line BL. The Z direction corresponds to the vertical direction with respect to the surface of the board as a reference.

### (Planar Layout of Memory Cell Array 10)

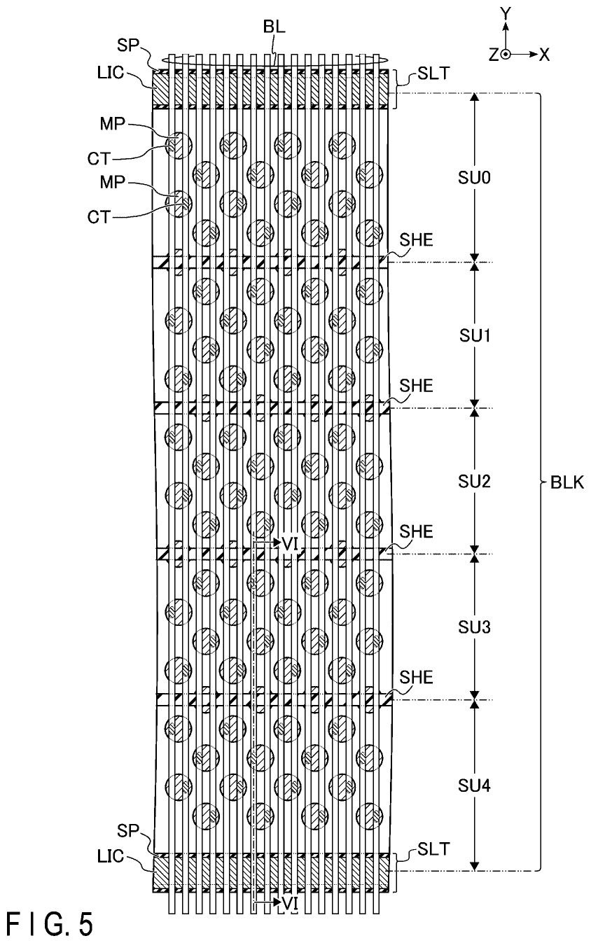

FIG. 5 is a plan view illustrating an example of a planar layout of the memory cell array 10 included in the memory device 1 according to the first embodiment. FIG. 5 illustrates a region including one block BLK (string units SU0 to SU4). As illustrated in FIG. 5, the memory cell array 10 includes a plurality of slits SLT, a plurality of slits SHE, a plurality of memory pillars MP, a plurality of contacts CT, and a plurality of bit lines BL. Each slit SLT includes a contact LIC and a spacer SP.

Each slit SLT has a portion extending along the X direction. The plurality of slits SLT is arranged in the Y direction. Each slit SLT has a structure in which an insulator or a plate-like contact is embedded, for example. Each slit SLT divides wirings (for example, the word lines WL0 to WL7 and the select gate lines SGD and SGS) adjacent to each other with the slit SLT in between. In the memory cell array 10, each of the regions divided by the slits SLT corresponds to one block BLK.

Each slit SHE has a portion extending along the X direction. The plurality of slits SHE is arranged in the Y direction. In this example, four slits SHE are arranged between two slits SLT adjacent to each other in the Y direction. Each slit SHE has a structure in which an insulator is embedded, for example. Each slit SHE divides the wirings (at least select gate lines SGD) adjacent to each other with the slit SHE in between. In the memory cell array 10, each of the regions divided by the slits SLT and SHE corresponds to one string unit SU.

Each memory pillar MP functions as one NAND string NS. The plurality of memory pillars MP is arranged in a staggered manner in 24 rows in a region between two adjacent slits SLT, for example. For example, one slit SHE overlaps each of the memory pillar MP in the fifth column, the memory pillar MP in the 10th column, the memory pillar MP in the 15th column, and the memory pillar MP in the 20th column, from the upper side of the paper surface.

Each bit line BL is a conductor having a portion extending in the Y direction. The plurality of bit lines is arranged in the X direction. For example, the bit lines BL are arranged in such a manner as to overlap at least one memory pillar MP in each of the string units SU. In this example, two bit lines BL overlap one memory pillar MP. The memory pillar MP is electrically connected to one bit line BL among the plurality of bit lines BL arranged in an overlapping manner via the contact CT. The contact CT between the memory pillar MP and the bit line BL in contact with the two different select gate lines SGD can be omitted.

The contact LIC is a conductor having a portion extending in the X direction. The spacer SP is an insulator provided on side surfaces of the contact LIC. In the illustrated region, the contact LIC is sandwiched between the spacers SP in the Y direction. The contact LIC and the conductor (for example, the word lines WL0 to WL7 and the select gate lines SGD and SGS) adjacent to the contact LIC in the Y direction are separated and insulated by the spacers SP. The spacer SP is an oxide film, for example.

The planar layout of the memory cell array 10 may be another layout. For example, the numbers and arrangements of the memory pillars MP, the slits SHE, and the like arranged between two adjacent slits SLT can be appropriately changed. The number of the string units SU in each block BLK can be changed based on the number of the slits SHE between two adjacent slits SLT. The number of the bit lines BL overlapping each memory pillar MP can be freely designed.

### (Cross-Sectional Structure of Memory Cell Array 10)

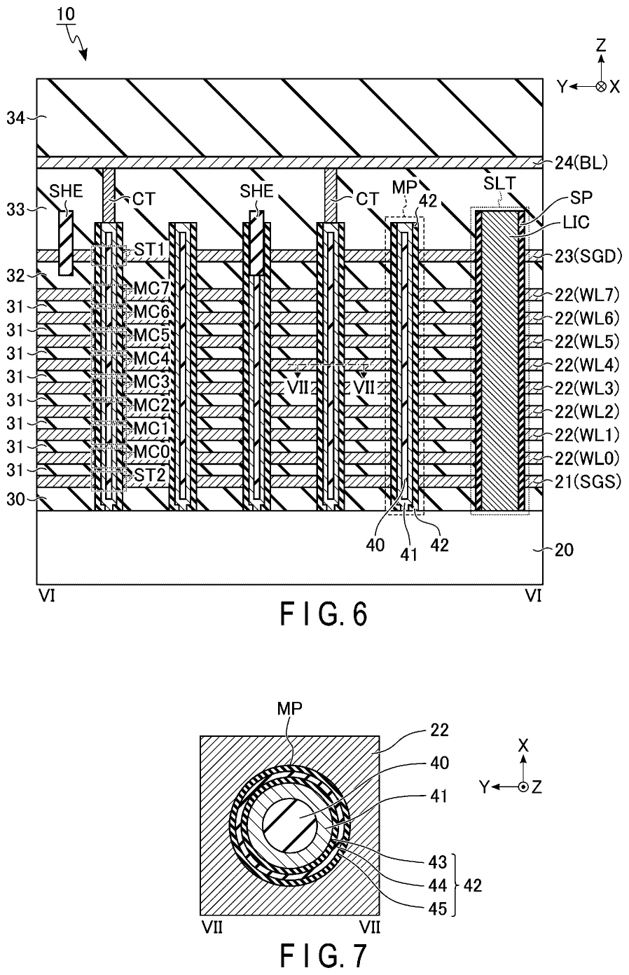

FIG. 6 is a cross-sectional view taken along line VI-VI of FIG. 5 of an example of a cross-sectional structure of the memory cell array 10 included in the memory device 1 according to the first embodiment. As illustrated in FIG. 6, the memory cell array 10 includes a semiconductor substrate 20, conductor layers 21 to 24, and insulator layers 30 to 34, for example. In the following description, the direction away from the front surface side of the semiconductor substrate 20 will be referred to as a positive direction (upward). The front surface of the substrate corresponds to the surface on which an element such as a transistor (CMOS circuit) is formed. The back surface of the substrate corresponds to the surface opposite to the front surface.

The semiconductor substrate 20 is a P-type silicon substrate, for example. The insulator layer 30 is provided on the semiconductor substrate 20. The conductor layer 21 is provided on the insulator layer 30. The insulator layers 31 and the conductor layers 22 are alternately stacked on the conductor layer 21. The insulator layer 32 is provided on the uppermost conductor layer 22. The conductor layer 23 is provided on the insulator layer 32. The insulator layer 33 is provided on the conductor layer 23. The conductor layer 24 is provided on the insulator layer 33. The insulator layer 34 is provided on the conductor layer 24. Although not illustrated, the wiring layer on which the insulator layer 34 is formed is provided with wiring, contacts, and the like for connecting the memory cell array 10 to the row decoder module 16 and the sense amplifier module 17.

Each of the conductor layers 21, 22, and 23 has a plate-like portion widened along the XY plane. The conductor layer 24 has a linear portion extending along the Y direction. The conductor layer 21 is used as the select gate line SGS. The plurality of conductor layers 22 is used as the word lines WL0 to WL7 in order from the bottom. The conductor layer 23 is used as the select gate line SGD. The conductor layer 24 is used as the bit line BL. Each of the conductor layers 21, 22, and 23 contains tungsten, for example. The conductor layer 24 contains copper, for example.

Each memory pillar MP extends along the Z direction. Each memory pillar MP penetrates the insulator layers 30 to 32 and the conductor layers 21 to 23. The bottom of the memory pillar MP reaches the semiconductor substrate 20. The portion of intersection between the memory pillar MP and the conductor layer 21 functions as the select transistor ST2. The portion of intersection between the memory pillar MP and one conductor layer 22 functions as the memory cell transistor MC. The portion of intersection between the memory pillar MP and the conductor layer 23 functions as the select transistor ST1.

Each memory pillar MP includes a core member 40, a semiconductor layer 41, and a stacked film 42, for example. The core member 40 extends along the Z direction. The semiconductor layer 41 covers the periphery of the core member 40. The bottom portion of the semiconductor layer 41 is in contact with the semiconductor substrate 20. The stacked film 42 covers the side surfaces and bottom surface of the semiconductor layer 41 except for a portion where the semiconductor layer 41 and the semiconductor substrate 20 are in contact with each other. The core member 40 includes an insulator such as silicon oxide. The semiconductor layer 41 contains silicon, for example.

The contacts CT are provided in a columnar shape extending along the Z direction. Each contact CT is provided on the semiconductor layer 41 of the associated memory pillar MP. One conductor layer 24 is in contact with each contact CT. For example, the memory pillar MP between the adjacent slits SLT and SHE and the memory pillar MP between the two adjacent slits SHE are electrically connected to each conductor layer 24.

The slit SLT has a portion provided along the XZ plane, for example, and divides the conductor layers 21 to 23 and the insulator layers 30 to 32. The contact LIC in the slit SLT is provided along the slit SLT. The upper end of the contact LIC is located at a height between the upper end of the memory pillar MP and the conductor layer 24. The lower end of the contact LIC is in contact with the semiconductor substrate 20. The semiconductor substrate 20 has an impurity diffusion region in a portion in contact with the contact LIC. The contact LIC is used as a part of the source line SL, for example. The spacer SP insulates the contact LIC from the conductor layers 21 to 23.

The slit SHE has a portion provided along the XZ plane, for example, and divides the conductor layer 23. The upper end of the slit SHE is provided at a height between the upper end of the memory pillar MP and the conductor layer 24. The lower end of the slit SHE is provided at the height of the insulator layer 32. The slit SHE includes an insulator such as silicon oxide.

A contact is connected to the top of each of the conductor layers 21 to 23 in a region not illustrated. The conductor layers 21 to 23 and the row decoder module 16 are electrically connected via the contact. Accordingly, the row decoder module 16 can apply a voltage to the conductor layers 21 to 23 (the select gate lines SGS and SGD and the word line WL) provided in the memory cell array 10.

### (Cross-Sectional Structure of Memory Pillar MP)

FIG. 7 is a cross-sectional view taken along line VII-VII of FIG. 6 of an example of a cross-sectional structure of the memory pillar MP included in the memory device 1 according to the first embodiment. FIG. 7 illustrates a cross-sectional structure of the memory pillar MP in a layer parallel to the surface of the semiconductor substrate 20 and including the conductor layer 22. As illustrated in FIG. 7, the stacked film 42 includes a tunnel insulating film 43, an insulating film 44, and a block insulating film 45, for example.

The core member 40 is provided at the central portion of the memory pillar MP. The semiconductor layer 41 surrounds the side surfaces of the core member 40. The tunnel insulating film 43 surrounds the side surfaces of the semiconductor layer 41. The insulating film 44 surrounds the side surfaces of the tunnel insulating film 43. The block insulating film 45 surrounds the side surfaces of the insulating film 44. The conductor layer 22 surrounds the side surfaces of the block insulating film 45. Each of the tunnel insulating film 43 and the block insulating film 45 contains silicon oxide, for example. The insulating film 44 contains silicon nitride, for example.

In the memory pillar MP, the semiconductor layer 41 is used as a channel (current path) of the memory cell transistors MC0 to MC7 and the select transistors ST1 and ST2. The insulating film 44 is used as a charge storage layer of the charge trap-type memory cell transistor MC. The memory device 1 can flow a current through the memory pillar MP between the bit line BL and the contact LIC (source line SL) by turning on the memory cell transistors MC0 to MC7 and the select transistors ST1 and ST2.

### <1-1-4> Data Storage Method

Next, a configuration related to a data storage method of the memory device 1 according to the first embodiment will be described. In the following description, it is assumed that the write order of data in each NAND string NS starts from the memory cell transistor MC on the bit line BL side. In addition, a case where the memory cell transistor MC stores 3-bit data will be described as an example.

### (Data Storage Area)

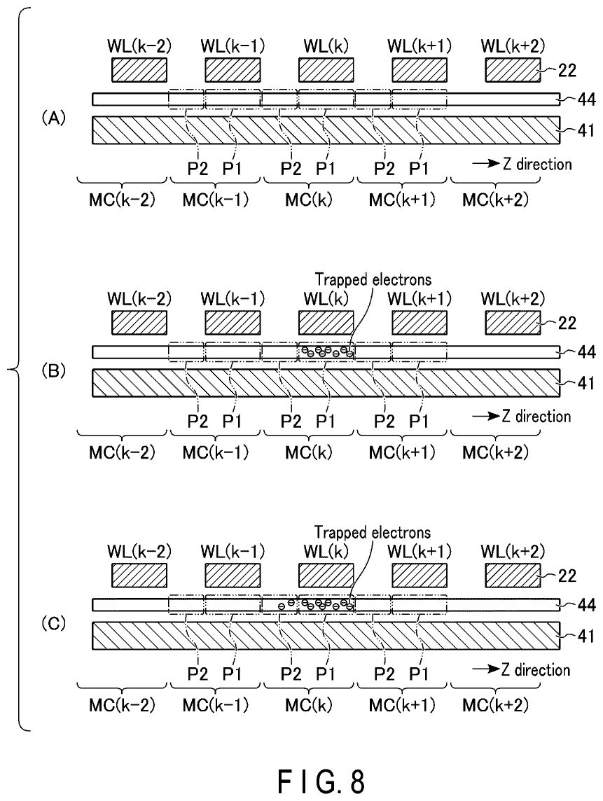

FIG. 8 is a schematic diagram illustrating an example of a data storage area of the NAND string NS included in the memory device 1 according to the first embodiment. FIG. 8 illustrates extracted portions of the NAND string NS corresponding to the memory cell transistors MC (k−2) to MC (k+2), and illustrates five word lines WL (k−2) to WL (k+2) (five conductor layers 22), the insulating film 44 (charge storage layer), and the semiconductor layer 41. In this example, “k” is an integer of 2 or larger and 5 or smaller. The upper limit of “k” in the first embodiment can vary depending on the design of the memory cell array 10.

The memory cell transistor MC is a charge trap-type memory cell, and the charge storage layer (insulating film 44) of the NAND string NS is continuously provided. The insulating film 44 includes storage units P1 and P2 for each memory cell transistor MC. The storage unit P1 corresponds to a portion of the insulating film 44 between the conductor layer 22 and the semiconductor layer 41. The storage unit P1 of the memory cell transistor MC (k) faces the conductor layer 22 corresponding to the word line WL (k). The storage unit P2 corresponds to a portion of the insulating film 44 between a portion between two adjacent conductor layers 22 and the semiconductor layer 41. In other words, the storage unit P2 corresponds to a portion of the insulating film 44 that does not face the conductor layer 22. The storage unit P2 of the memory cell transistor MC (k) faces a portion between the word lines WL (k) and WL (k−1) and is adjacent to the storage unit P1 of the memory cell transistor MC (k).
(A) of FIG. 8 corresponds to a case where the memory cell transistor MC (k) in the first embodiment is in the erase state. As illustrated in (A) of FIG. 8, each of the storage units P1 and P2 of the memory cell transistor MC (k) in the erase state is in a state of not trapping electrons.
(B) of FIG. 8 corresponds to a case where the memory cell transistor MC (k) according to the first embodiment stores data associated with a first S-factor. As illustrated in (B) of FIG. 8, the storage unit P1 of the memory cell transistor MC (k) having the first S-factor has trapped an amount of electrons corresponding to the data. On the other hand, the storage unit P2 of the memory cell transistor MC (k) having the first S-factor does not trap electrons or is suppressed from trapping electrons.
(C) of FIG. 8 corresponds to a case where the memory cell transistor MC (k) according to the first embodiment stores data associated with a second S-factor lower than the first S-factor. As illustrated in (C) of FIG. 8, the storage unit P1 of the memory cell transistor MC (k) having the second S-factor has trapped an amount of electrons corresponding to the data. The storage unit P2 of the memory cell transistor MC (k) having the second S-factor has trapped electrons more than the storage unit P2 of the memory cell transistor MC (k) having the first S-factor.

### (Threshold Voltage Distribution of Memory Cell Transistor MC)

In a case where 3-bit data is stored, the memory cell transistor MC is programmed to any one of eight-value threshold voltage levels according to the data. Therefore, if one cell unit CU stores 3-page data, eight types of states can be formed in the threshold voltage distribution of the memory cell transistor MC. Herein, the eight types of states will be called “Z”, “A”, “B”, “C”, “D”, “E”, “F”, and “G” states in order from the lowest threshold voltage. In this example, different 3-bit data is allocated to the “Z”, “A”, “B”, “C”, “D”, “E”, “F”, and “G” states. The “Z” state is formed corresponding to the threshold voltage of the memory cell transistor MC in the erase state. Each of the “A”, “B”, “C”, “D”, “E”, “F”, and “G” states is formed corresponding to the memory cell transistor MC in which the threshold voltage is higher than that in the erase state by the write operation.

In the memory device 1 according to the first embodiment, the memory cell transistor MC in which data corresponding to any of the “A”, “C”, and “E” states is written has the first S-factor. The memory cell transistor MC in which data corresponding to any of the “B”, “D”, and “F” states is written has the second S-factor. The S-factor of the memory cell transistor MC in which the data corresponding to the “G” state is written has the first S-factor, for example. The present invention is not limited thereto, and the S-factor of the memory cell transistor MC in which data corresponding to the “G” state is written may be either the first S-factor or the second S-factor. In the first embodiment, in a plurality of states distributed between the lowermost state (for example, the “Z” state) and the uppermost state (for example, the “G” state), two adjacent states may have S-factors different from each other.

In the present specification, the read voltages associated with the “A”, “B”, “C”, “D”, “E”, “F”, and “G” states will be called read voltages AR, BR, CR, DR, ER, FR, and GR, respectively. The read voltages AR, BR, CR, DR, ER, FR, and GR are set to voltage levels that make it possible to distinguish between the memory cell transistor MC in which data corresponding to the “A”, “B”, “C”, “D”, “E”, “F”, and “G” states is stored and the memory cell transistor MC in which data corresponding to a state immediately below is stored.

In addition, herein, verify voltages associated with the “A”, “B”, “C”, “D”, “E”, “F”, and “G” states will be called verify voltages AV, BV, CV, DV, EV, FV, and GV, respectively. The verify voltages AV, BV, CV, DV, EV, FV, and GV are used as reference levels at the time of writing data corresponding to the “A”, “B”, “C”, “D”, “E”, “F”, and “G” states, respectively. Hereinafter, the read operation using the verify voltage executed in the write operation will be called “verify read”.

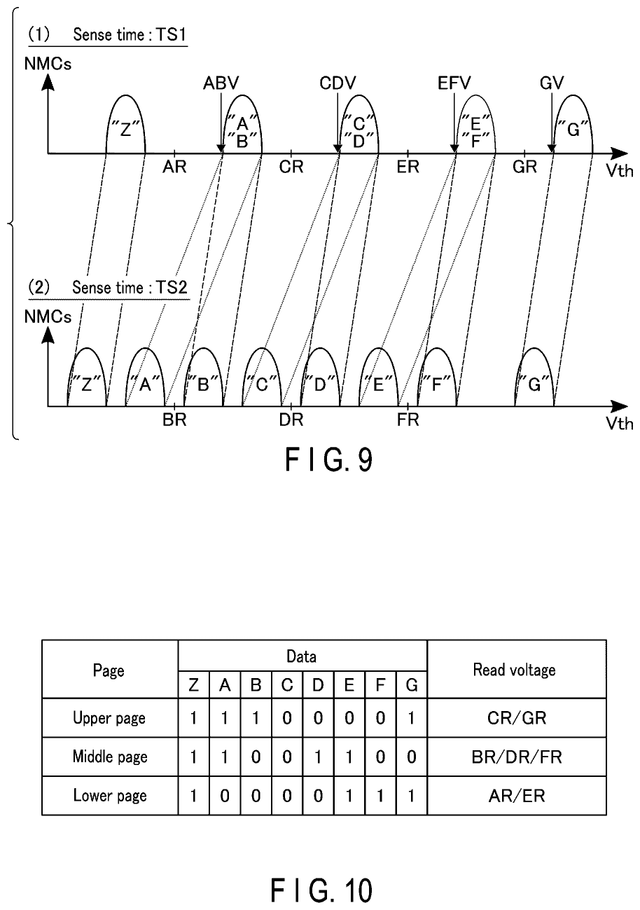

FIG. 9 is a distribution diagram illustrating an example of threshold voltage distribution of the memory cell transistor MC included in the memory device 1 according to the first embodiment. In the graph illustrated in FIG. 9, the horizontal axis represents a threshold voltage Vth of the memory cell transistor MC, and the vertical axis represents number NMCs of the memory cell transistors MC. As illustrated in FIG. 9, in the memory device 1 according to the first embodiment, the threshold voltage distribution of the memory cell transistor MC is formed in association with two sense times TS1 and TS2. Each of the sense times TS1 and TS2 corresponds to a time from the start to the stop of the discharge of the node SEN charged in the sense amplifier unit SAU in a state where the read voltage or the verify voltage is applied to a selected word line WLsel in the read operation. The sense time TS2 is longer than the sense time TS1.
(1) of FIG. 9 corresponds to the threshold voltage distribution of the memory cell transistor MC in the read using the sense time TS1. As illustrated in (1) of FIG. 9, in the threshold voltage distribution of the memory cell transistor MC in the case of the sense time TS1, the “A” state and the “B” state overlap, the “C” state and the “D” state overlap, and the “E” state and the “F” state overlap. In addition, the “Z” state and a set of “A” and “B” states are spaced apart, the set of “A” and “B” states and a set of “C” and “D” states are spaced apart, the set of “C” and “D” states and a set of “E” and “F” states are spaced apart, and the set of “E” and “F” states and the “G” state are spaced apart.

In the first embodiment, the read voltages AR, CR, ER, and GR are associated with the sense time TS1. Specifically, the read voltage AR is set to a voltage level between the “Z” state and the set of “A” and “B” states in the case of the sense time TS1. The read voltage CR is set to a voltage level between the set of “A” and “B” states and the set of “C” and “D” states in the case of the sense time TS1. The read voltage ER is set to a voltage level between the set of “C” and “D” states and the set of “E” and “F” states in the case of the sense time TS1. The read voltage GR is set to a voltage level between the set of “E” and “F” states and the “G” state in the case of the sense time TS1.

In the first embodiment, the verify voltages AV and BV are integrated and used as verify voltage ABV. The verify voltage ABV is used for the verify read using the sense time TS1 in the write operation, and is used as a reference level in writing data corresponding to either the “A” or “B” state. Similarly, the verify voltages CV and DV are integrated and used as verify voltage CDV. The verify voltage CDV is used for the verify read using the sense time TS1 in the write operation, and is used as a reference level in writing data corresponding to either the “C” or “D” state. Similarly, the verify voltages EV and FV are integrated and used as verify voltage EFV. The verify voltage EFV is used for the verify read using the sense time TS1 in the write operation, and is used as a reference level in writing data corresponding to either the “E” or “F” state.
(2) of FIG. 9 corresponds to the threshold voltage distribution of the memory cell transistor MC in the read using the sense time TS2. As illustrated in (2) of FIG. 9, the voltage level at which each state is distributed in the threshold voltage distribution of the memory cell transistor MC in the case of the sense time TS2 is lower than that in the case of the sense time TS1 because the sense time TS2 is longer than the sense time TS1. Accordingly, in the threshold voltage distribution of the memory cell transistor MC in the case of the sense time TS2, differently from the state of the sense time TS1, the “A” state and the “B” state are separated, the “C” state and the “D” state are separated, and the “E” state and the “F” state are separated.

In the first embodiment, the read voltages BR, DR, and FR are associated with the sense time TS2. Specifically, the read voltage BR is set to a voltage level between the “A” state and the “B” state in the case of the sense time TS2. The read voltage DR is set to a voltage level between the “C” state and the “D” state in the case of the sense time TS2. The read voltage FR is set to a voltage level between the “E” state and the “F” state in the case of the sense time TS2. In the first embodiment, the read voltage GR may be associated with the sense time TS2. In this case, the read voltage GR is set to a voltage level between the “F” state and the “G” state in the case of the sense time TS2.

### (Data Allocation)

FIG. 10 is a table illustrating an example of allocation of data used in the memory device 1 according to the first embodiment. Hereinafter, data allocation in the first embodiment will be described with reference to FIG. 10.

In this example, each memory cell transistor MC is capable of storing 3-bit data including an upper bit, a middle bit, and a lower bit. Hereinafter, one-page data configured by upper bits will be called “upper-page data”. One-page data configured by middle bits will be called “middle-page data”. One-page data configured by lower bits will be called “lower-page data”. The read operation of the lower-page data will be called “lower-page read”. The read operation of the middle-page data will be called “middle-page read”. The read operation of the upper-page data will be called “upper-page read”. The names of “upper”, “middle”, and “lower” used in the description of data allocation are merely examples, and may be interchanged or changed.

The allocation of 3-bit data to each of the “Z”, “A”, “B”, “C”, “D”, “E”, “F”, and “G” states in the first embodiment is as follows.
(Example) State name: “upper-bit/middle-bit/lower-bit” data
“Z” state: “111” data
“A” state: “110” data
“B” state: “100” data
“C” state: “000” data
“D” state: “010” data
“E” state: “011” data
“F” state: “001” data
“G” state: “101” data

In the upper-page read in the first embodiment, the upper-page data stored in the cell unit CU to be read is determined by two iterations of read using the read voltages CR and GR. In the middle-page read in the first embodiment, the middle-page data stored in the cell unit CU to be read is determined by three iterations of read using the read voltages BR, DR, and FR. In the lower-page read in the first embodiment, the lower-page data stored in the cell unit CU to be read is determined by two iterations of read using the read voltages AR and ER.

In the first embodiment, the multi-page data stored in one cell unit CU is classified into a group of memory cell transistors MC written by the first S-factor and a group of memory cell transistors MC written by the second S-factor. In the above data allocation, each of the lower-page read and the upper-page read corresponds to the read operation of the group of the memory cell transistors MC written by the first S-factor. On the other hand, the middle-page read corresponds to the read operation of the group of the memory cell transistors MC written by the second S-factor.

### <1-2> Operations

Next, operations of the memory device 1 according to the first embodiment will be described. In the following description, the memory cell transistor MC included in the cell unit CU to be subjected to the write operation or the read operation will be called “selected memory cell transistor MCsel”. The word line WL connected to the selected memory cell transistor MCsel will be called “selected word line WLsel”. The bit line BL connected to the program-target selected memory cell transistor MCsel will be called “program bit line BLprog”. The bit line BL connected to the program-inhibit selected memory cell transistor MCsel will be called “program-inhibit bit line BLinh”. The NAND string NS connected to the program bit line BLprog will be called “selected string”. The NAND string NS connected to the program-inhibit bit line BLinh will be called “unselected string”.

### <1-2-1> Write Operation

First, a write operation of the memory device 1 according to the first embodiment will be described.

### (Outline of Write Operation)

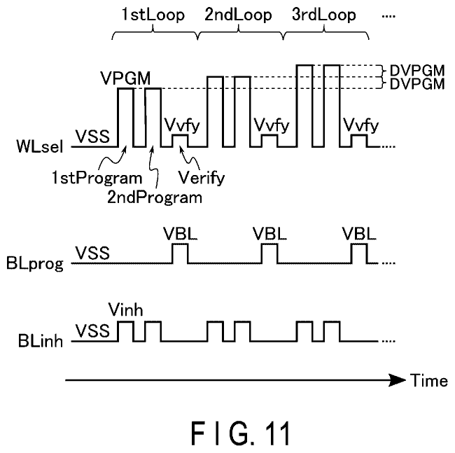

FIG. 11 is a time chart illustrating an outline of the write operation of the memory device 1 according to the first embodiment. FIG. 11 illustrates changes in the voltages of the selected word line WLsel, the program bit line BLprog, and the program-inhibit bit line BLinh in the write operation. As illustrated in FIG. 11, the memory device 1 executes a loop process (program loop process) including a program operation and a verify operation in the write operation. Although FIG. 11 illustrates three loop processes (1st Loop, 2nd Loop, and 3rd Loop), the number of loop processes may vary depending on the settings of the write operation and the like.

The program operation is an operation capable of increasing the threshold voltage of the selected memory cell transistor MCsel. The sequencer 14 sets each selected memory cell transistor MCsel to be a program-target memory cell transistor or a program-inhibit memory cell transistor, and executes the program operation. The program-target selected memory cell transistor MCsel is the selected memory cell transistor MCsel that has not reached the threshold voltage of the state corresponding to the data to be written (hereinafter, called “target state”). The program-inhibit selected memory cell transistor MCsel is the selected memory cell transistor MCsel that has reached the threshold voltage of the target state.

For example, if the sense amplifier unit SAU holds data in a state other than the erase state, the sequencer 14 handles the selected memory cell transistor MCsel connected to the sense amplifier unit SAU as the program-target selected memory cell transistor MCsel. In addition, if the sense amplifier unit SAU holds data in the erase state (“Z” state), the sequencer 14 handles the selected memory cell transistor MCsel connected to the sense amplifier unit SAU as the program-inhibit selected memory cell transistor MCsel. The sequencer 14 can set the data held in the sense amplifier unit SAU to the same data as the data allocated to the erase state according to the progress of the write operation, thereby to set the selected memory cell transistor MCsel connected to the sense amplifier unit SAU to be program-inhibited.

The program operation of the memory device 1 according to the first embodiment includes a first program process (1st program) and a second program process (2nd program). The first program process is an operation capable of increasing the threshold voltage of the selected memory cell transistor MCsel so as to have the first S-factor. The second program process is an operation capable of increasing the threshold voltage of the selected memory cell transistor MCsel so as to have the second S-factor. The sequencer 14 sets the program-target selected memory cell transistor MCsel in the first program process to be program-inhibited in the second program process. The sequencer 14 also sets the program-target selected memory cell transistor MCsel in the second program process to be program-inhibited in the first program process.

In each of the first program process and the second program process, the sequencer 14 controls the driver circuit 15, the row decoder module 16, and the sense amplifier module 17 such that the threshold voltage of the selected memory cell transistor MCsel connected to the program bit line BLprog increases and the threshold voltage of the selected memory cell transistor MCsel connected to the program-inhibit bit line BLinh is suppressed from increasing. Specifically, the sequencer 14 applies VPGM, VSS, and Vinh to the selected word line WLsel, the program bit line BLprog, and the program-inhibit bit line BLinh, respectively. VPGM is a high voltage capable of increasing the threshold voltage of the selected memory cell transistor MCsel. VSS is a ground voltage of the memory device 1. Vinh is a voltage higher than VSS and lower than VPGM.

Then, in each of the first program process and the second program process, in the selected memory cell transistor MCsel connected to the program bit line BLprog, electrons are injected into the charge storage layer based on the voltage difference between the selected word line WLsel and the channel, and the threshold voltage increases. On the other hand, in the selected memory cell transistor MCsel connected to the program-inhibit bit line BLinh, the select transistor ST1 is cut off to boost the channel potential, and the threshold voltage is suppressed from increasing. The voltage value of the VPGM is stepped up in accordance with repetition of the loop process. FIG. 11 illustrates the voltage difference corresponding to the step-up width of the VPGM in each loop process is illustrated as DVPGM. In each program operation, the VPGM used in the first program process and the VPGM used in the second program process are in the same voltage level, for example. A specific method for separately writing the first S-factor and the second S-factor in each of the first program process and the second program process will be described later.

Upon completion of the program operation, the sequencer 14 executes a verify operation. The verify operation is an operation of confirming whether the threshold voltage of the selected memory cell transistor MCsel has reached the threshold voltage of the target state. The verify operation includes at least one verify read. In other words, the sequencer 14 executes the verify read using a verify voltage Vvfy in each loop process. The verify voltage Vvfy is any one of the verify voltages AV, BV, CV, DV, EV, FV, and GV. A plurality of types of verify read may be executed in each loop process. If a plurality of types of verify read is executed in each loop process, verify voltages Vvfy in a plurality of voltage levels are sequentially applied to the selected word line WLsel.

The verify read is executed on the selected memory cell transistor MCsel that is set as a program target in the same loop process and in which the state associated with the verify voltage Vvfy is the target state. For example, in the verify read, the sequencer 14 applies VBL and VSS to the program bit line BLprog and the program-inhibit bit line BLinh, respectively. VBL is a voltage higher than the VSS. In the verify read, the VSS may be applied to the program bit line BLprog if the verify voltage Vvfy for a state different from the target state of the selected memory cell transistor MCsel connected thereto is used.

In the verify read, each sense amplifier unit SAU determines whether the threshold voltage of the associated selected memory cell transistor MCsel has exceeded the verify voltage Vvfy applied to the selected word line WLsel, based on the voltage of its own node SEN. The selected memory cell transistor MCsel that can be regarded that the threshold voltage of the selected memory cell transistor MCsel has exceeded the verify voltage, that is, has reached the threshold voltage of the target state, is determined as “verify pass”. On the other hand, the selected memory cell transistor MCsel that can be considered that the threshold voltage of the selected memory cell transistor MCsel is equal to or less than the verify voltage Vvfy, that is, has not reached the threshold voltage of the target state, is determined as “verify fail”. Each sense amplifier unit SAU stores the result of the verify read of the target state in any internal latch circuit.

If the verify operation ends, the sequencer 14 sets the selected memory cell transistor MCsel in which the threshold voltage has reached the target state to be program-inhibited based on the result of the verify read in the current loop process. For example, the sequencer 14 sets the data held in the sense amplifier unit SAU associated with the selected memory cell transistor MCsel determined as verify pass to the same data as the data allocated to the erase state. Thereafter, the sequencer 14 starts the next loop process.

The memory device 1 can execute a detection operation after each loop process. In the detection operation, the number of the selected memory cell transistors MTsel that have been determined as verify pass is counted for each state. Then, the sequencer 14 determines whether the write has been completed for each state. The completion of the write is determined based on that the number of the selected memory cell transistors MCsel determined as verify fail is less than a predetermined number, for example. In the repetition of the loop process, for example, upon detection of completion of the write in each of the “A” to “G” states, the sequencer 14 ends the write operation.

### (Flow of Write Operation)

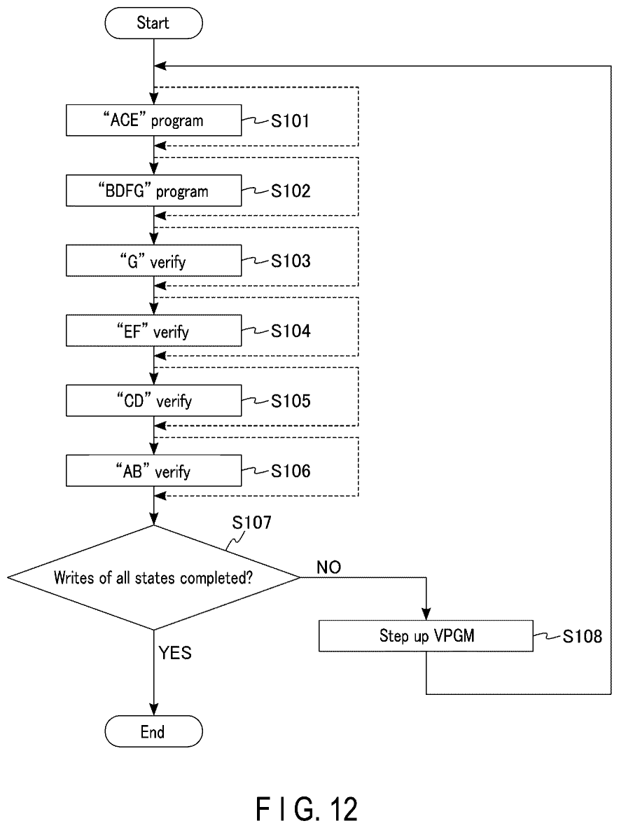

Hereinafter, a flow of the write operation of the memory device 1 according to the first embodiment will be described with reference to FIG. 12 as appropriate. FIG. 12 is a flowchart illustrating an example of the write operation of the memory device 1 according to the first embodiment. Broken lines in FIG. 12 indicate a path of a processing flow in a case where the associated step is omitted.

When the memory device 1 receives a command for instructing the write operation, the address of the cell unit CU as the write destination, and the data to be written from the memory controller 2, the sequencer 14 starts the write operation (start).

First, the sequencer 14 executes an “ACE” program (S101). The “ACE” program is a first program process for the selected memory cell transistor MCsel in which any of the “A”, “C”, and “E” states is the target state. The threshold voltage of the selected memory cell transistor MCsel in which any of the “A”, “C”, and “E” states is the target state is increased by the “ACE” program. In step S101, the selected memory cell transistor MCsel in which any of the “B”, “D”, “F”, and “G” states is the target state is set to be write-inhibited (program-inhibit). Step S101 is omitted in a case where the writes of the “A”, “C”, and “E” states are completed.

Next, the sequencer 14 executes a “BDFG” program (S102). The “BDFG” program is a second program process for the selected memory cell transistor MCsel in which any of the “B”, “D”, “F”, and “G” states is the target state. The threshold voltage of the selected memory cell transistor MCsel in which any of the “B”, “D”, “F”, and “G” states is the target state is increased by the “BDFG” program. In step S102, the selected memory cell transistor MCsel in which any of the “A”, “C”, and “E” states is the target state is set to be write-inhibited (program-inhibit). Step S102 is omitted in a case where the writes of the “B”, “D”, “F”, and “G” states are completed.

Next, the sequencer 14 executes a “G” verify (S103). The “G” verify is a verify read for the selected memory cell transistor MCsel in which the “G” state is the target state. In the “G” verify, the sequencer 14 determines whether the threshold voltage of the selected memory cell transistor MCsel that is the target of the “G” verify has exceeded the verify voltage GV using the sense time TS1. Step S103 may be omitted in a loop process in which it is estimated that the threshold voltage of the program-target selected memory cell transistor MCsel has obviously not reached the “G” state.

Next, the sequencer 14 executes an “EF” verify (S104). The “EF” verify is a verify read for the selected memory cell transistor MCsel in which the “E” state or the “F” state is the target state. In the “EF” verify, the sequencer 14 determines whether the threshold voltage of the selected memory cell transistor MCsel that is the target of the “EF” verify has exceeded the verify voltage EFV using the sense time TS1. Step S104 is omitted in a case where the writes of the “E” and “F” states are completed. In addition, step S104 may be omitted in a loop process in which it is estimated that the threshold voltage of the program-target selected memory cell transistor MCsel has obviously not reached the “E” or “F” state.

Next, the sequencer 14 executes a “CD” verify (S105). The “CD” verify is a verify read for the selected memory cell transistor MCsel in which the “C” state or the “D” state is the target state. In the “CD” verify, the sequencer 14 determines whether the threshold voltage of the selected memory cell transistor MCsel that is the target of the “CD” verify has exceeded the verify voltage CDV using the sense time TS1. Step S105 is omitted in a case where the writes of the “C” and “D” states are completed. In addition, step S105 may be omitted in a loop process in which it is estimated that the threshold voltage of the program-target selected memory cell transistor MCsel has obviously not reached the “C” or “D” state.

Next, the sequencer 14 executes an “AB” verify (S106). The “AB verify is a verify read for the selected memory cell transistor MCsel in which the “A” state or the “B” state is the target state. In the “AB” verify, the sequencer 14 determines whether the threshold voltage of the selected memory cell transistor MCsel that is the target of the “AB” verify has exceeded the verify voltage ABV using the sense time TS1. Step S106 is omitted in a case where the writes of the “A” and “B” states are completed.

Next, the sequencer 14 checks whether the writes of all the states have been completed (S107). That is, the sequencer 14 determines whether the writes of the “A”, “B”, “C”, “D”, “E”, “F”, and “G” states have been completed based on the results of the processes in S103 to S106.

In step S107, if the writes of all the states have been not completed (S107: NO), the sequencer 14 steps up the VPGM (S108). Upon completion of step S108, the sequencer 14 proceeds to step S101. That is, if the writes of all the states have not been completed in step S107, the sequencer 14 executes the next loop process using the stepped-up VPGM.

In step S107, if the writes of all the states have been completed (S107: YES), the sequencer 14 ends the series of processes in FIG. 12 (end). That is, the sequencer 14 ends the write operation and notifies the memory controller 2 of the end of the write operation.

### (Specific Example of “ACE” Program)

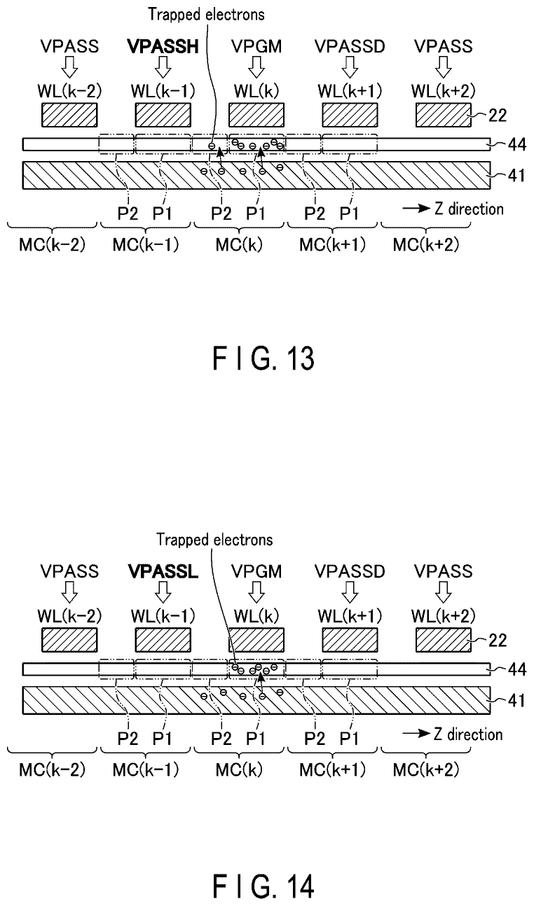

FIG. 13 is a schematic diagram illustrating a specific example of the “ACE” program (first program process) of the memory device 1 according to the first embodiment. FIG. 13 illustrates voltages applied to the word lines WL (k−2) to WL (k+2) and a state in which electrons are injected into the charge storage layer (insulating film 44) of the selected memory cell transistor MCsel in a case where the word line WL (k) is set as the selected word line WLsel in the “ACE” program. In this example, the memory cell transistor MC connected to the word lines WL (k−1), WL (k−2), . . . is in the erase state, and the memory cell transistor MC connected to any one of the word lines WL (k+1), WL (k+2), . . . has a threshold voltage corresponding to data.

As illustrated in FIG. 13, in the “ACE” program, the sequencer 14 applies VPASS, VPASSH, VPGM, VPASSD, and VPASS to the word lines WL (k−2), WL (k−1), WL (k), WL (k+1), and WL (k+2), respectively. VPASS is a voltage higher than the threshold voltage of the memory cell transistor MC distributed in the highest state, and is 10 V, for example. VPASSD is a voltage equal to or higher than VPASS and lower than VPGM. VPASSH is a voltage higher than the threshold voltage of the memory cell transistor MC distributed in the highest state and lower than VPGM. The sequencer 14 also applies VDD, for example, to each of the select gate lines SGD and SGS (not illustrated) while applying VPGM to the word line WL (k). VDD is a voltage capable of turning on the select transistors ST1 and ST2, and is 3 V, for example.

Accordingly, the select transistors ST1 and ST2 are turned on, and the channel potential of the NAND string NS becomes VSS, for example, based on the voltage of the program bit line BLprog. Then, electrons are injected into the insulating film 44 near the memory cell transistor MC (k) based on the potential difference between the channel (semiconductor layer 41) and the word line WL (k). The injected electrons are trapped in the storage unit P1 of the memory cell transistor MC (k) and further trapped in the storage unit P2 of the memory cell transistor MC (k) based on the potential difference between the channel (semiconductor layer 41) and the word line WL (k−1). In this manner, the electrons trapped in the charge storage layer by the “ACE” program are distributed to the storage units P1 and P2 of the selected memory cell transistor MCsel.

In the “ACE” program, VPASSH is set to a voltage level at which electrons can be trapped in the storage unit P2 of the selected memory cell transistor MCsel. In the “ACE” program, the sequencer 14 may apply VPASS to the word line WL (k+1) while applying VPGM to the word line WL (k). The write into the storage unit P2 of the selected memory cell transistor MCsel may be implemented by changing the length of the program pulse corresponding to VPGM.

### (Specific Example of “BDFG” Program)

FIG. 14 is a schematic diagram illustrating a specific example of the “BDFG” program (second program process) of the memory device 1 according to the first embodiment. FIG. 14 illustrates voltages applied to the word lines WL (k−2) to WL (k+2) and a state in which electrons are injected into the charge storage layer (insulating film 44) of the selected memory cell transistor MCsel in a case where the word line WL (k) is set as the selected word line WLsel in the “BDFG” program. In this example, the memory cell transistor MC connected to the word lines WL (k−1), WL (k−2), . . . is in the erase state, and the memory cell transistor MC connected to any one of the word lines WL (k+1), WL (k+2), . . . has a threshold voltage corresponding to data.

As illustrated in FIG. 14, in the “BDFG” program, the sequencer 14 applies VPASS, VPASSL, VPGM, VPASSD, and VPASS to the word lines WL (k−2), WL (k−1), WL (k), WL (k+1), and WL (k+2), respectively. VPASSL is a voltage higher than the threshold voltage of the memory cell transistor MC distributed in the highest state and lower than VPASSH. The sequencer 14 also applies VDD, for example, to each of the select gate lines SGD and SGS (not illustrated) while applying VPGM to the word line WL (k).

Accordingly, the channel potential becomes VSS, for example, based on the voltage of the program bit line BLprog. Then, electrons are injected into the insulating film 44 near the memory cell transistor MC (k) based on the potential difference between the channel (semiconductor layer 41) and the word line WL (k). The injected electrons are trapped in the storage unit P1 of the memory cell transistor MC (k). In this manner, the electrons trapped in the charge storage layer by the “BDFG” program are distributed to the storage unit P1 of the selected memory cell transistor MCsel.

In the “BDFG” program, the trapping of electrons in the storage unit P2 of the selected memory cell transistor MCsel is preferably suppressed by the voltage applied to the word line WL (k−1). In the “BDFG” program, the sequencer 14 may apply VPASS to each of the word lines WL (k−1) and WL (k+1) while applying VPGM to the word line WL (k).

### <1-2-2> Read Operation

Next, a read operation of the memory device 1 according to the first embodiment will be described. In the drawings referred to below, the voltages of the selected word line WLsel, the node SEN, and the bit line BL before the start of the read operation are VSS, for example. The control signals BLX, BLC, PRE, XXL, and STB are at the “L” level, for example.

### (Specific Example of Lower-Page Read)

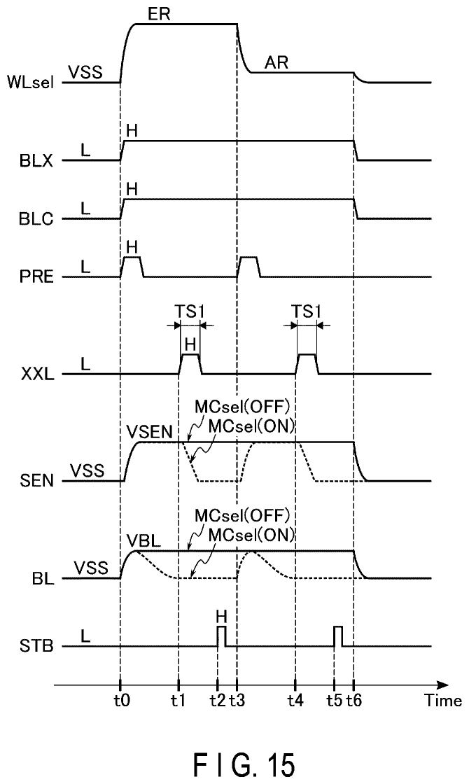

FIG. 15 is a timing chart illustrating an example of lower-page read of the memory device 1 according to the first embodiment. FIG. 15 illustrates changes in the voltages of the selected word line WLsel, the bit line BL, the control signals BLX, BLC, PRE, XXL, and STB, and the node SEN in the lower-page read. As illustrated in FIG. 15, in the lower-page read of the first embodiment, the sequencer 14 sequentially executes the processes at times t0 to t6.

At time t0 of the lower-page read, the sequencer 14 applies the read voltage ER to the selected word line WLsel. The sequencer 14 also sets the control signals BLX, BLC, and PRE to the “H” level. Accordingly, the voltage of the node SEN rises to VSEN, and the voltage of the bit line BL rises to VPCH. When the voltage of the selected word line WLsel becomes the read voltage ER, the selected memory cell transistor MCsel is turned on or off according to the threshold voltage. If the selected memory cell transistor MCsel is in the off state (MCsel (OFF)), the voltage of the bit line BL is maintained VPCH. If the selected memory cell transistor MCsel is in the on state (MCsel (ON)), the voltage of the bit line BL falls to a level lower than VPCH. Then, after the voltage of the node SEN rises to VSEN, the sequencer 14 sets the control signal PRE to the “L” level.

At time t1 of the lower-page read, the sequencer 14 sets the control signal XXL to the “H” level. Accordingly, a current path between the node SEN and the bit line BL is formed, and the voltage of the node SEN becomes a state corresponding to the voltage of the bit line BL. Specifically, if the selected memory cell transistor MCsel is in the off state (MCsel (OFF)), the voltage of the node SEN is maintained VSEN. If the selected memory cell transistor MCsel is in the on state (MCsel (ON)), the voltage of the node SEN falls from VSEN. Then, When the sense time TS1 has elapsed from the time t1, the sequencer 14 sets the control signal XXL to the “L” level. Accordingly, the current path between the node SEN and the bit line BL is shut off, and the drop in the voltage of the node SEN stops. That is, the voltage of the node SEN is fixed to a level corresponding to the threshold voltage of the selected memory cell transistor MCsel and the sense time TS1.

At time t2 of the lower-page read, the sequencer 14 asserts the control signal STB. That is, the sequencer 14 temporarily sets the control signal STB to the “H” level. Accordingly, the transistor T6 is turned on or off based on the voltage of the node SEN, and the read result is reflected in the voltage of the bus LBUS. Then, the sense amplifier unit SAU stores data based on the voltage of the bus LBUS in any of the latch circuits inside. That is, it is determined whether the threshold voltage of the selected memory cell transistor MCsel has exceeded the read voltage ER in the case of the sense time TS1, and the determination result is stored in any of the latch circuits of the sense amplifier unit SAU. The processes at time t0 to time t2 of the lower-page read corresponds to the read using the read voltage ER.

At time t3 of the lower-page read, the sequencer 14 applies the read voltage AR to the selected word line WLsel. The sequencer 14 also sets the control signal PRE to the “H” level and maintains the control signals BLX and BLC at the “H” level. Accordingly, the voltage of the node SEN rises to VSEN, and the voltage of the bit line BL rises to VPCH. If the voltage of the selected word line WLsel becomes the read voltage AR, the selected memory cell transistor MCsel is turned on or off. If the selected memory cell transistor MCsel is in the off state, the voltage of the bit line BL is maintained VPCH. If the selected memory cell transistor MCsel is in the on state, the voltage of the bit line BL falls to a voltage level lower than VPCH based on the amount of current flowing through the selected memory cell transistor MCsel. Then, after the voltage of the node SEN rises to VSEN, the sequencer 14 sets the control signal PRE to the “L” level.

At time t4 of the lower-page read, the sequencer 14 sets the control signal XXL to the “H” level as at time t1. Accordingly, the voltage of the node SEN becomes a state corresponding to the voltage of the bit line BL. Then, when the sense time TS1 has elapsed from the time t4, the sequencer 14 sets the control signal XXL to the “L” level and stops the drop in the voltage of the node SEN.

At time t5 of the lower-page read, the sequencer 14 asserts the control signal STB as at time t2. Accordingly, it is determined whether the threshold voltage of the selected memory cell transistor MCsel has exceeded the read voltage AR in the case of the sense time TS1, and the determination result is stored in any of the latch circuits of the sense amplifier unit SAU. The processes at time t3 to time t5 of the lower-page read corresponds to the read using the read voltage AR.

At time t6 of the lower-page read, the sequencer 14 controls the states of the selected word line WLsel, the bit line BL, the control signals BLX, BLC, PRE, XXL, and STB, and the node SEN to be the same as the states before the start of the lower-page read. In addition, each sense amplifier unit SAU determines the lower-bit data stored in the selected memory cell transistor MCsel based on the respective determination results of the read voltages ER and AR. Thereafter, the memory device 1 transmits the determined set of lower-bit data as middle-page data to the memory controller 2, and ends the lower-page read.

### (Specific Example of Middle-Page Read)

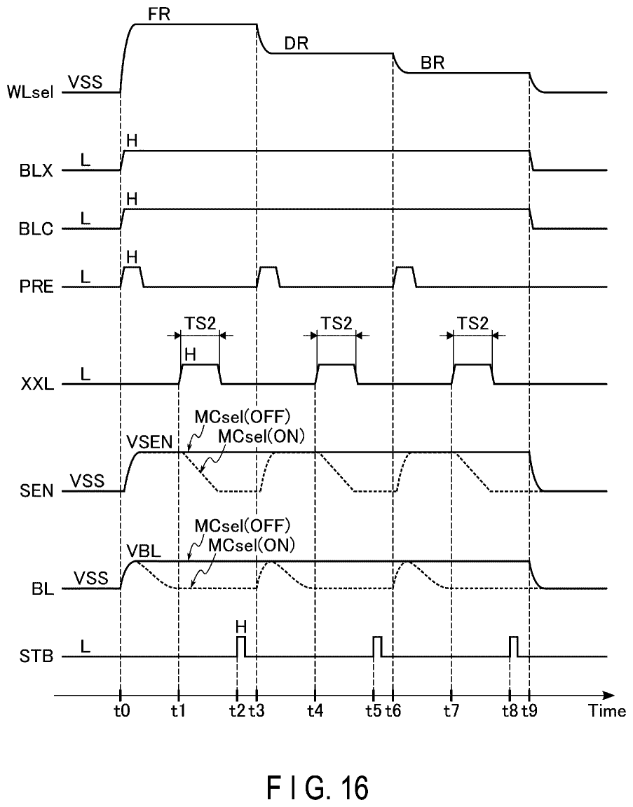

FIG. 16 is a timing chart illustrating an example of middle-page read of the memory device 1 according to the first embodiment. FIG. 16 illustrates changes in the voltages of the selected word line WLsel, the bit line BL, the control signals BLX, BLC, PRE, XXL, and STB, and the node SEN in the middle-page read. As illustrated in FIG. 16, in the middle-page read of the first embodiment, the sequencer 14 sequentially executes processes at times t0 to t9.

The processes at time t0 to time t2 of the middle-page read corresponds to the read using the read voltage FR. The processes at the time t0 to the time t2 of the middle-page read is similar to the processes at the time t0 to the time t2 of the lower-page read in which the read voltage ER is replaced with the read voltage FR and the sense time TS1 is replaced with the sense time TS2. Accordingly, it is determined whether the threshold voltage of the selected memory cell transistor MCsel has exceeded the read voltage FR in the case of the sense time TS2, and the determination result is stored in any of the latch circuits of the sense amplifier unit SAU.

The processes at time t3 to time t5 of the middle-page read corresponds to the read using the read voltage DR. The processes at the time t3 to the time t5 of the middle-page read is similar to the processes at the time t3 to the time t5 of the lower-page read in which the read voltage AR is replaced with the read voltage DR and the sense time TS1 is replaced with the sense time TS2. Accordingly, it is determined whether the threshold voltage of the selected memory cell transistor MCsel has exceeded the read voltage DR in the case of the sense time TS2, and the determination result is stored in any of the latch circuits of the sense amplifier unit SAU.

The processes at time t6 to time t8 of the middle-page read corresponds to the read using the read voltage BR. The processes at time t6 to time t8 of the middle-page read is similar to the processes at time t3 to time t5 of the middle-page read in which the read voltage DR is replaced with the read voltage BR. Accordingly, it is determined whether the threshold voltage of the selected memory cell transistor MCsel has exceeded the read voltage BR in the case of the sense time TS2, and the determination result is stored in any of the latch circuits of the sense amplifier unit SAU.

At time t9 of the middle-page read, the sequencer 14 controls the states of the selected word line WLsel, the bit line BL, the control signals BLX, BLC, PRE, XXL, and STB, and the node SEN to be the same as the states before the start of the middle-page read. In addition, each sense amplifier unit SAU determines the middle-bit data stored in the selected memory cell transistor MCsel based on the respective determination results of the read voltages FR, DR, and BR. Thereafter, the memory device 1 transmits the determined set of middle-bit data as middle-page data to the memory controller 2, and ends the middle-page read.

### (Specific Example of Upper-Page Read)

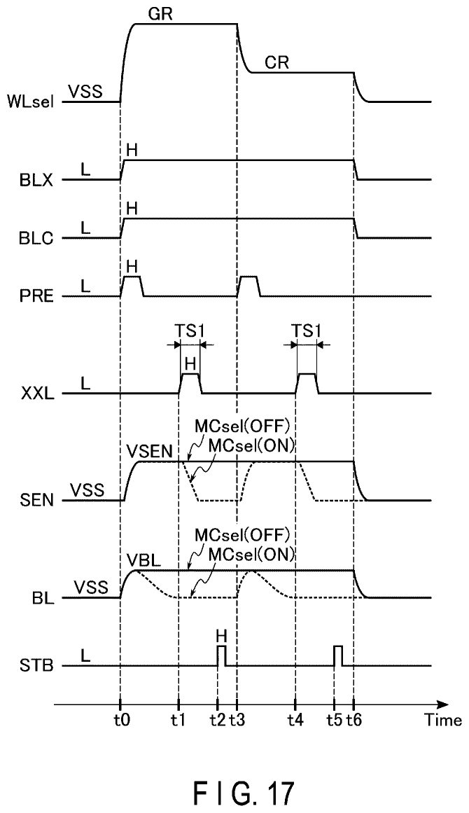

FIG. 17 is a timing chart illustrating an example of upper-page read of the memory device 1 according to the first embodiment. FIG. 17 illustrates changes in the voltages of the selected word line WLsel, the bit line BL, the control signals BLX, BLC, PRE, XXL, and STB, and the node SEN in the upper-page read. As illustrated in FIG. 17, in the upper-page read of the first embodiment, the sequencer 14 sequentially executes processes at times t0 to t9.

The processes at time t0 to time t2 of the upper-page read corresponds to the read using the read voltage GR. The processes at time t0 to time t2 of the upper-page read is similar to the processes at time t0 to time t2 of the lower-page read in which the read voltage ER is replaced with the read voltage GR. Accordingly, it is determined whether the threshold voltage of the selected memory cell transistor MCsel has exceeded the read voltage GR in the case of the sense time TS1, and the determination result is stored in any of the latch circuits of the sense amplifier unit SAU.

The processes at time t3 to time t5 of the upper-page read corresponds to the read using the read voltage CR. The processes at time t3 to time t5 of the upper-page read is similar to the processes at time t3 to time t5 of the lower-page read in which the read voltage AR is replaced with the read voltage CR. Accordingly, it is determined whether the threshold voltage of the selected memory cell transistor MCsel has exceeded the read voltage CR in the case of the sense time TS1, and the determination result is stored in any of the latch circuits of the sense amplifier unit SAU.

At time t6 of the upper-page read, the sequencer 14 controls the states of the selected word line WLsel, the bit line BL, the control signals BLX, BLC, PRE, XXL, and STB, and the node SEN to be the same as the states before the start of the upper-page read. In addition, each sense amplifier unit SAU determines the upper-bit data stored in the selected memory cell transistor MCsel based on the respective determination results of the read voltages GR and CR. Thereafter, the memory device 1 transmits the determined set of upper-bit data as upper-page data to the memory controller 2, and ends the upper-page read.

### <1-3> Advantageous Effects of First Embodiment

According to the memory device 1 according to the first embodiment described above, the storage capacity of the memory device can be increased or the read margin can be increased. Hereinafter, advantageous effects (advantages) of the first embodiment will be described in detail.

As a method for increasing the storage capacity of a memory device, storing multi-bit data in one memory cell is known. For example, the memory cell can store multi-bit data by having a threshold voltage level according to the data. In this method, if the number of bits of data to be stored in the memory cell increases, it is necessary to increase the number of threshold voltage levels according to the number of bits. However, it is difficult to widen the range of the threshold voltage that can be taken by the memory cell, due to the influence of disturbance or the like. For this reason, as the threshold voltage level is increasingly multivalued, the read margin and the data retention margin per level decrease. If the read margin and the data retention margin decrease, the number of error bits at the read time increases, and the reliability of data stored in the memory cell may be deteriorated.

Therefore, the memory device 1 according to the first embodiment stores multi-bit data in the memory cell transistor MC using a combination of the threshold voltage level and the S-factor. Specifically, in the write operation, the memory device 1 executes a first program process of increasing the threshold voltage of the memory cell transistor MC so as to have the first S-factor and a second program process of increasing the threshold voltage of the memory cell transistor MC so as to have the second S-factor larger than the first S-factor according to the data to be written.

Specifically, the memory device 1 changes the voltage to be applied to the word line WL adjacent at one side to the selected word line WLsel while applying the program voltage to the selected word line WLsel between the first program process and the second program process. Accordingly, the memory device 1 adjusts the number of electrons to be written between the adjacent memory cell transistors MC (storage unit P2). When electrons are trapped in the storage unit P2, a back bias is applied to the read operation, and the S-factor of the memory cell transistor MC increases. In the verify operation, the memory device 1 executes the verify read using the same sense time TS1 in each of the first program process and the second program process. Then, the memory device 1 uses the first sense time TS1 in the read using the read voltage associated with the threshold voltage level written in the first program process, and uses the second sense time TS2 in the read using the read voltage associated with the threshold voltage level written in the second program process.

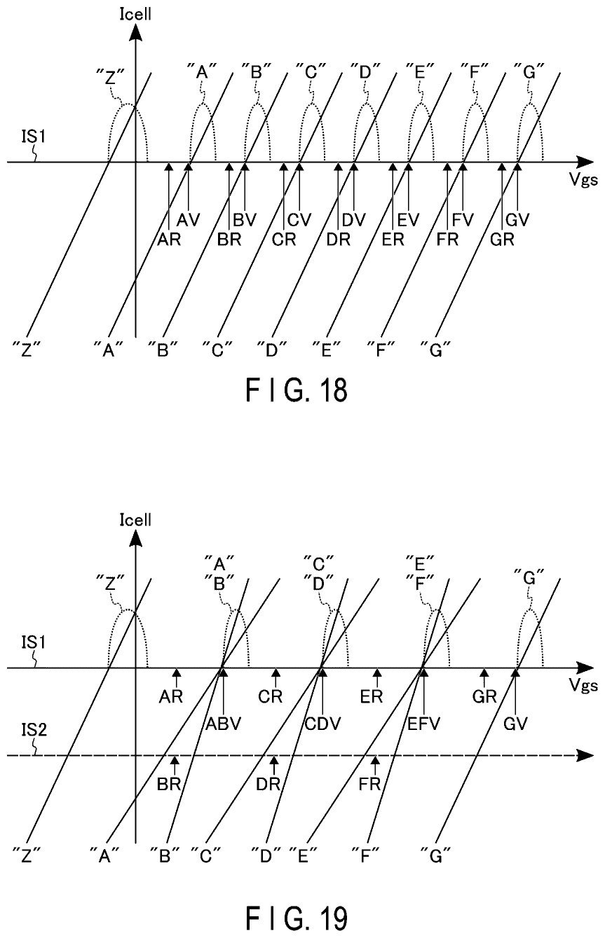

FIGS. 18 and 19 are graphs illustrating examples of IV characteristics of the memory cell transistor MC in the memory devices 1 according to the comparative example and the first embodiment, respectively. In each of FIGS. 18 and 19, the horizontal axis corresponds to a gate-source voltage Vgs of the memory cell transistor MC, and the vertical axis corresponds to a current Icell flowing through the memory cell transistor MC. The comparative example corresponds to a case where 3-bit data is stored in the memory cell transistor MC at an 8-value threshold voltage level and with the same S-factor.

In the comparative example, the S-factor is not written separately. Therefore, as illustrated in FIG. 18, the IV characteristics of the memory cell transistor MC at each threshold voltage levels have the same slope, for example. In the comparative example, the verify operation and the read operation are executed using a sense current IS1. The sense current IS1 corresponds to a cell current flowing through the selected memory cell transistor MCsel if the control signal STB is asserted in the read using the sense time TS1. As described above, in a case where the threshold voltage distribution is formed with the same sense current IS1, the interval between adjacent states becomes narrower as the number of states increases.

On the other hand, in the first embodiment, two types of S-factors are written separately. In this case, as illustrated in FIG. 19, as the IV characteristics of the memory cell transistor MC at each threshold voltage level, two types of slopes can be formed, for example. Specifically, the slopes of the IV characteristics of the memory cell transistor MC in the “A”, “C”, and “E” states having the first S-factor are the same. In addition, the slopes of the IV characteristics of the memory cell transistor MC in the “B”, “D”, and “F” states having the second S-factor larger than the first S-factor are the same. Since the second S-factor is larger than the first S-factor, the slope of the IV characteristics of the memory cell transistor MC in the “B”, “D”, and “F” states is larger than that in the “A”, “C”, and “E” states.

The memory device 1 according to the first embodiment performs the write in the “A” to “F” states using the sense current IS1, and uses the same verify voltage among the set of the “A” and “B” states, the set of the “C” and “D” states, and the set of the “E” and “F” states. Therefore, in the read operation using the sense current IS1, the set of “A” and “B” states is distributed in an overlapping manner, the set of “C” and “D” states is distributed in an overlapping manner, and the set of “E” and “F” states is distributed in an overlapping manner. The memory device 1 is capable of executing the read operation using a sense current IS2. The sense current IS2 corresponds to a cell current flowing through the selected memory cell transistor MCsel if the control signal STB is asserted in the read using the sense time TS2. In the read operation using the sense current IS2, since the sense time TS2 is longer than the sense time TS1, adjacent states can be separated according to the difference between the first S-factor and the second S-factor.

Accordingly, the memory device 1 can distinguish the two states overlapping at the time of the read operation using the sense current IS1, by setting the read voltage between the separated adjacent states. In a case where the threshold voltage distribution is formed by the sense current IS1, the memory device 1 can make the interval between the adjacent states wider than that in the comparative example. That is, the memory device 1 according to the first embodiment can widen the interval between two adjacent states by selectively using the first sense time and the second sense time. Therefore, the memory device 1 can increase the read margin and improve the reliability of the memory device 1.

The memory device 1 according to the first embodiment can also use more threshold voltage levels by increasing the read margin. In this case, the memory device 1 can increase the number of bits stored in one memory cell transistor MC, and can increase the storage capacity of the memory device 1.

Furthermore, the memory device 1 according to the first embodiment collectively executes verify read of adjacent states after the first program process and the second program process in each loop process. For example, although the number of iterations of verify is seven in the comparative example, the number of iterations of verify is four in the first embodiment. Therefore, the memory device 1 according to the first embodiment can shorten the time of the write operation as compared with the comparative example.

### <1-4> Modification of First Embodiment

The data allocation applied to the memory device 1 may be another allocation. Hereinafter, an example of another data allocation will be described as a modification of the first embodiment. The setting of the threshold voltage distribution of a memory cell transistor MC in the modification of the first embodiment is similar to that in the first embodiment. In the modification of the first embodiment, the memory cell transistor MC in which data corresponding to any of “A”, “C”, and “E” states is written has a first S-factor as in the first embodiment. The memory cell transistor MC in which data corresponding to any of “B”, “D”, and “F” states is written has a second S-factor as in the first embodiment. In the modification of the first embodiment, the S-factor of the memory cell transistor MC in which data corresponding to a “G” state is written may be either the first S-factor or the second S-factor.

### (Data Allocation)

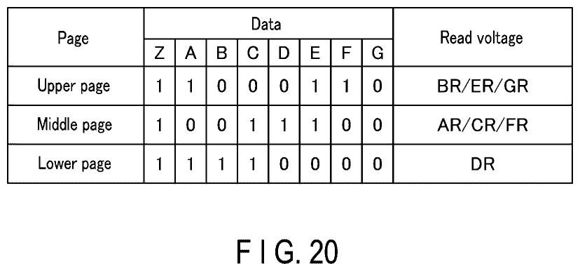

FIG. 20 is a table illustrating an example of data allocation in the modification of the first embodiment. Hereinafter, data allocation in the modification of the first embodiment will be described with reference to FIG. 20.

The allocation of 3-bit data to each of the “Z”, “A”, “B”, “C”, “D”, “E”, “F”, and “G” states in the modification of the first embodiment is as follows.
(Example) State name: “upper-bit/middle-bit/lower-bit” data
“Z” state: “111” data
“A” state: “101” data
“B” state: “001” data
“C” state: “011” data
“D” state: “010” data
“E” state: “110” data
“F” state: “100” data
“G” state: “000” data

In upper-page read in the modification of the first embodiment, upper-page data stored in a cell unit CU to be read is determined by three iterations of read using read voltages BR, ER, and GR. In middle-page read in the modification of the first embodiment, middle-page data stored in the cell unit CU to be read is determined by three iterations of read using read voltages AR, CR, and FR. In lower-page read in the modification of the first embodiment, lower-page data stored in the cell unit CU to be read is determined by one reading using a read voltage DR.

As described above, in the modification of the first embodiment, the number of iterations of each of the upper-page read and the middle-page read is three. On the other hand, the lower-page read is set such that data is determined by one iteration of read. In the modification of the first embodiment, each of the upper-page read and the middle-page read includes the read for a group of the memory cell transistors MC written with the first S-factor and the read for a group of the memory cell transistors MC written with the second S-factor at the same ratio. Further, the lower-page read includes the read for a group of the memory cell transistors MC written with the second S-factor.

### (Specific Example of Lower-Page Read)

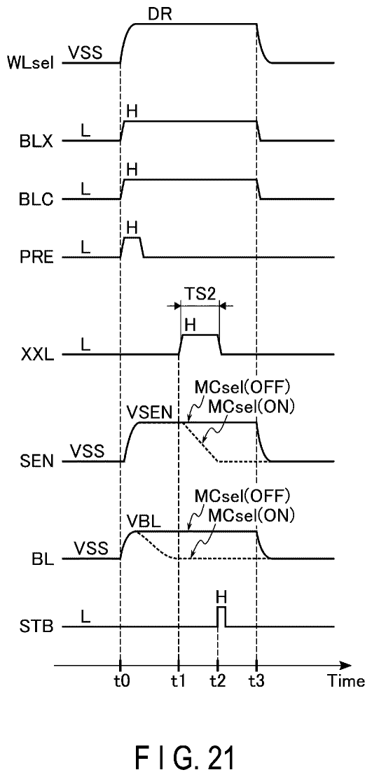

FIG. 21 is a timing chart illustrating an example of the lower-page read according to the modification of the first embodiment. FIG. 21 illustrates changes in the voltages of a selected word line WLsel, a bit line BL, control signals BLX, BLC, PRE, XXL, and STB, and a node SEN in the lower-page read of the modification of the first embodiment. As illustrated in FIG. 21, in the lower-page read of the modification of the first embodiment, a sequencer 14 sequentially executes processes at times t0 to t3.

In the lower-page read of the modification of the first embodiment, the processes at times t0 to t2 correspond to read using the read voltage DR. Details of the read using the read voltage DR are similar to those of the first embodiment. Accordingly, the result of a determination as to whether the threshold voltage of the selected memory cell transistor MCsel has exceeded the read voltage DR in the case of a sense time TS2 is stored in any of latch circuits of a sense amplifier unit SAU. This determination result corresponds to the upper-bit data stored in the selected memory cell transistor MCsel.

At time t3 of the lower-page read of the modification of the first embodiment, the sequencer 14 controls the states of the selected word line WLsel, the bit line BL, the control signals BLX, BLC, PRE, XXL, and STB, and the node SEN to be the same as the states before the start of the lower-page read. Thereafter, the memory device 1 transmits a set of lower-bit data as lower-page data to a memory controller 2, and ends the lower-page read.

### (Specific Example of Middle-Page Read)

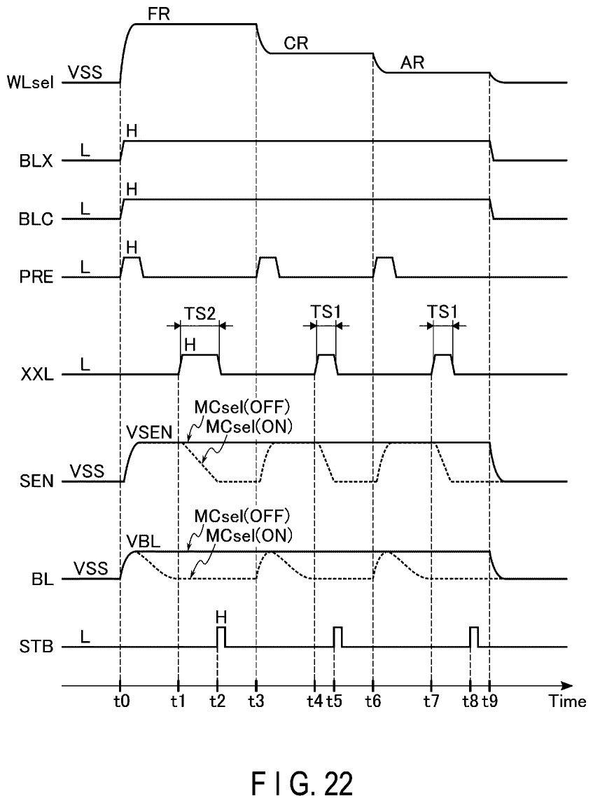

FIG. 22 is a timing chart illustrating an example of the middle-page read according to the modification of the first embodiment. FIG. 22 illustrates changes in the voltages of the selected word line WLsel, the bit line BL, the control signals BLX, BLC, PRE, XXL, and STB, and the node SEN in the middle-page read of the modification of the first embodiment. As illustrated in FIG. 22, in the middle-page read of the modification of the first embodiment, the sequencer 14 sequentially executes processes at times t0 to t9.

In the middle-page read of the modification of the first embodiment, the processes at times t0 to t2 correspond to read using the read voltage FR, the processes at times t3 to t5 correspond to read using the read voltage CR, and the processes at times t6 to t8 corresponds to read using the read voltage AR. Details of the read using the read voltage FR, the read using the read voltage CR, and the read using the read voltage AR are the same as those in the first embodiment. Accordingly, the result of a determination as to whether the threshold voltage of the selected memory cell transistor MCsel has exceeded the read voltage FR in the case of the sense time TS2, the result of a determination as to whether the threshold voltage of the selected memory cell transistor MCsel has exceeded the read voltage CR in the case of the sense time TS1, and the result of a determination as to whether the threshold voltage of the selected memory cell transistor MCsel has exceeded the read voltage AR in the case of the sense time TS1 are stored in any of the latch circuits of the sense amplifier unit SAU.

At time t9 of the middle-page read of the modification of the first embodiment, the sequencer 14 controls the states of the selected word line WLsel, the bit line BL, the control signals BLX, BLC, PRE, XXL, and STB, and the node SEN to be the same as those before the start of the middle-page read. In addition, each sense amplifier unit SAU determines the middle-bit data stored in the selected memory cell transistor MCsel based on the respective determination results of the read voltages FR, CR, and AR. Thereafter, the memory device 1 transmits the determined set of middle-bit data as middle-page data to the memory controller 2, and ends the middle-page read.

### (Specific Example of Upper-Page Read)

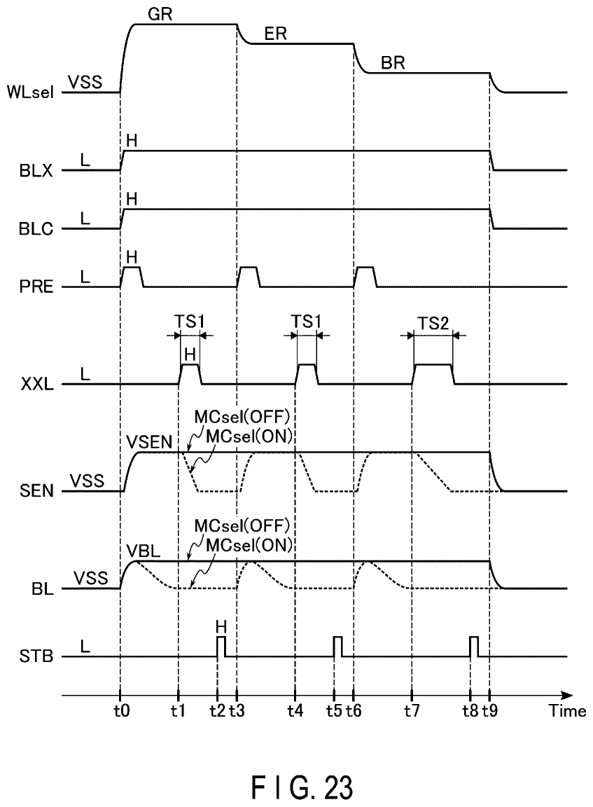

FIG. 23 is a timing chart illustrating an example of the upper-page read according to the modification of the first embodiment. FIG. 23 illustrates changes in the voltages of the selected word line WLsel, the bit line BL, the control signals BLX, BLC, PRE, XXL, and STB, and the node SEN in the upper-page read of the modification of the first embodiment. As illustrated in FIG. 23, in the upper-page read of the modification of the first embodiment, the sequencer 14 sequentially executes processes at times t0 to t9.

In the upper-page read of the modification of the first embodiment, the processing at times t0 to t2 corresponds to reading using the read voltage GR, the processing at times t3 to t5 corresponds to reading using the read voltage ER, and the processing at times t6 to t8 corresponds to reading using the read voltage BR. Details of the read using the read voltage GR, the read using the read voltage ER, and the read using the read voltage BR are the same as those in the first embodiment. Accordingly, the result of a determination as to whether the threshold voltage of the selected memory cell transistor MCsel has exceeded the read voltage GR in the case of the sense time TS1, the result of a determination as to whether the threshold voltage of the selected memory cell transistor MCsel has exceeded the read voltage ER in the case of the sense time TS1, and the result of a determination as to whether the threshold voltage of the selected memory cell transistor MCsel has exceeded the read voltage BR in the case of the sense time TS2 are stored in any of the latch circuits of the sense amplifier unit SAU.

At time t9 of the upper-page read of the modification of the first embodiment, the sequencer 14 controls the states of the selected word line WLsel, the bit line BL, the control signals BLX, BLC, PRE, XXL, and STB, and the node SEN to be the same as those before the start of the upper-page read. In addition, each sense amplifier unit SAU determines the upper bit data stored in the selected memory cell transistor MCsel based on the respective determination results of the read voltages GR, ER, and BR. Thereafter, the memory device 1 transmits the determined set of upper-bit data as upper-page data to the memory controller 2, and ends the upper-page read.

### Advantageous Effects of Modification of First Embodiment

In the read operation of the first embodiment, three iterations of read using the sense time TS2 longer than the sense time TS1 are executed in the middle-page read. Therefore, in the first embodiment, the read time in the middle-page read operation is longer than the read time in the read operations of the other pages.

On the other hand, in the modification of the first embodiment, the read using the sense time TS2 is allocated to each page. As a result, in the modification of the first embodiment, the read times of the middle-page read and the upper-page read can be equalized. Furthermore, in the modification of the first embodiment, since the lower-page data is determined by one iteration of read, the time for the lower-page read can be made shorter than those of the other pages. The lower-page read of the modification of the first embodiment is suitable for storing data requiring a low latency, and the like.

As described above, the method for separately writing the S-factors described in the first embodiment may be applied to other data allocation. The idea of the first embodiment can be applied without depending on data allocation.

### <2> Second Embodiment

Similarly to the first embodiment, a memory device 1 according to a second embodiment executes a write operation for separately writing the states of a S-factor of a memory cell and a read operation using two types of sense times. In the second embodiment, each state is arranged such that the read margin for each read voltage is widened. Hereinafter, details of a memory device 1 according to the second embodiment will be described based on differences from the first embodiment.

### <2-1> Configuration

First, a configuration of the memory device 1 according to the second embodiment will be described. A hardware configuration of the memory device 1 according to the second embodiment is similar to that of the memory device 1 according to the first embodiment. In the memory device 1 according to the second embodiment, the arrangement of each state in the threshold voltage distribution of a memory cell transistor MC is different from that in the first embodiment. Hereinafter, the threshold voltage distribution of the memory cell transistor MC in the memory device 1 according to the second embodiment will be described by exemplifying a case where each memory cell transistor MC stores 3-bit data.

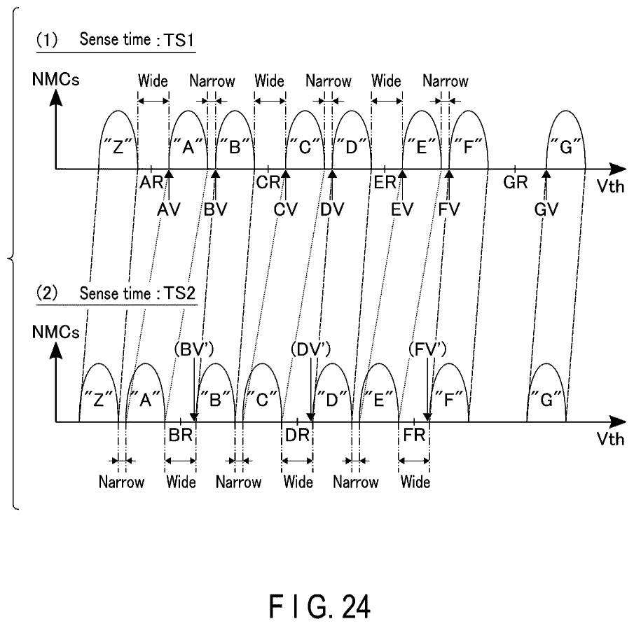

FIG. 24 is a distribution diagram illustrating an example of threshold voltage distribution of the memory cell transistor MC included in the memory device 1 according to the second embodiment. In the graph illustrated in FIG. 24, the horizontal axis represents a threshold voltage Vth of the memory cell transistor MC, and the vertical axis represents number NMCs of the memory cell transistors MC. As illustrated in FIG. 24, in the memory device 1 according to the second embodiment, as in the first embodiment, the threshold voltage distribution of the memory cell transistor MC is formed in association with each of two sense times TS1 and TS2.
(1) of FIG. 24 corresponds to the threshold voltage distribution of the memory cell transistor MC in the read using the sense time TS1. As illustrated in (1) of FIG. 24, in the threshold voltage distribution of the memory cell transistor MC in the case of the sense time TS1, “Z”, “A”, “B”, “C”, “D”, “E”, “F”, and “G” states are distributed separately. Then, an interval between the “Z” state and the “A” state, an interval between the “B” state and the “C” state, and an interval between the “D” state and the “E” state are set to be wide, and an interval between the “A” state and the “B” state, an interval between the “C” state and the “D” state, and an interval between the “E” state and the “F” state are set to be narrow.

In other words, in the threshold voltage distribution of the memory cell transistor MC in the case of the sense time TS1, the interval between the L-th (“L” is an odd number) state and the (L+1)-th state in order of increasing threshold voltage is set to be wider than the interval between the (L+1)-th state and the (L+2)-th state. In the threshold voltage distribution of the memory cell transistor MC in the case of the sense time TS1, a part of the (L+1)-th state and a part of the (L+2)-th in order of increasing threshold voltage state may overlap.

The setting of the read voltages associated with the sense time TS1 in the second embodiment is similar to that in the first embodiment. That is, in the second embodiment, read voltages AR, CR, ER, and GR are associated with the sense time TS1. In the second embodiment, for example, verify voltage of each state is associated with the sense time TS1. That is, in the second embodiment, the verify voltages AV, BV, CV, DV, EV, FV, and GV can be set in association with the sense time TS1 so that the threshold voltage distribution illustrated in (1) of FIG. 24 can be formed.
(2) of FIG. 24 corresponds to the threshold voltage distribution of the memory cell transistor MC in the read using the sense time TS2. As illustrated in (2) of FIG. 24, the voltage level at which each state is distributed in the threshold voltage distribution of the memory cell transistor MC in the case of the sense time TS2 is lower than that in the case of the sense time TS1 because the sense time TS2 is longer than the sense time TS1. Accordingly, in the threshold voltage distribution of the memory cell transistor MC in the case of the sense time TS2, the interval between the “Z” state and the “A” state, the interval between the “B” state and the “C” state, and the interval between the “D” state and the “E” state are set to be narrower from the state of the sense time TS1, and the interval between the “A” state and the “B” state, the interval between the “C” state and the “D” state, and the interval between the “E” state and the “F” state are set to be wider.

In other words, in the threshold voltage distribution of the memory cell transistor MC in the case of the sense time TS2, the interval between the (L+1)-th state and the (L+2) in order of increasing threshold voltage is set to be wider than the interval between the L-th state and the (L+1)-th state. In the threshold voltage distribution of the memory cell transistor MC in the case of the sense time TS2, a part of the L-th state and a part of the (L+1)-th state in order of increasing threshold voltage may overlap.

The setting of the read voltages associated with the sense time TS2 in the second embodiment is similar to that in the first embodiment. That is, in the second embodiment, the read voltages BR, DR, and FR are associated with the sense time TS2. In the second embodiment, some verify voltages may be associated with the sense time TS2. For example, verify voltages BV′, DV′, and FV′ may be set in association with the sense time TS2 so that the “B”, “D”, and “F” states can be formed in the threshold voltage distribution illustrated in (2) of FIG. 24.

### <2-2> Operations

Next, operations of the memory device 1 according to the second embodiment will be described. The memory device 1 according to the second embodiment executes a write operation different from that of the first embodiment.

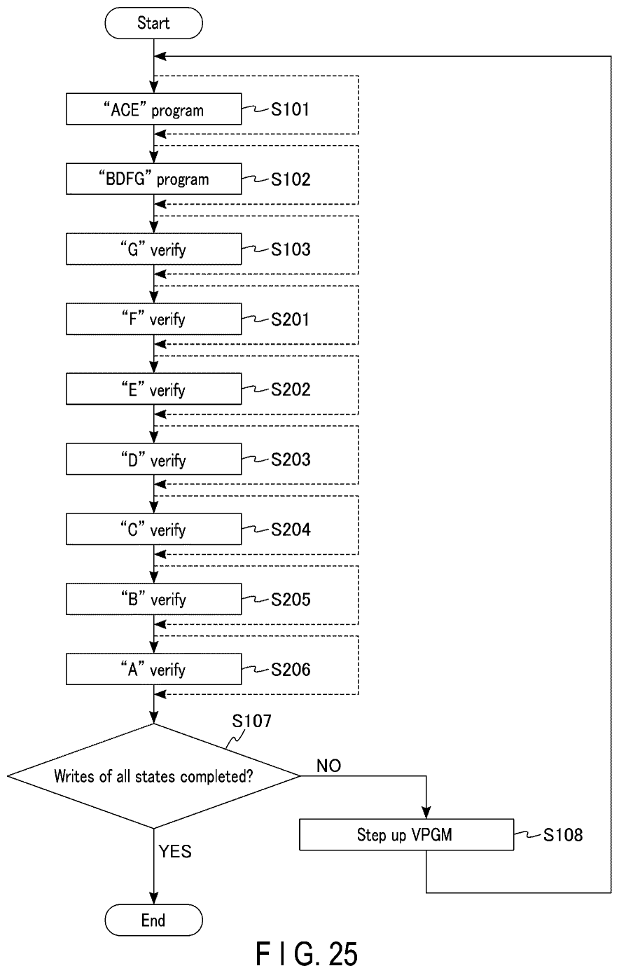

Hereinafter, a flow of the write operation of the memory device 1 according to the second embodiment will be described with reference to FIG. 25. FIG. 25 is a flowchart illustrating an example of the write operation of the memory device 1 according to the second embodiment. Broken lines in FIG. 25 indicate a path of a processing flow in a case where the associated processing is omitted.

When the memory device 1 receives a command for instructing the write operation, the address of the cell unit CU as the write destination, and the data to be written from the memory controller 2, the sequencer 14 starts the write operation (start).

First, the sequencer 14 executes an “ACE” program as in the first embodiment (S101). Step S101 is omitted in a case where the writes of the “A”, “C”, and “E” states are completed.

Next, the sequencer 14 executes a “BDFG” program as in the first embodiment (S102). Step S102 is omitted in a case where the writes of the “B”, “D”, “F”, and “G” states are completed.

Next, the sequencer 14 executes a “G” verify as in the first embodiment (S103). Step S103 may be omitted in a loop process in which it is estimated that the threshold voltage of the program-target selected memory cell transistor MCsel has obviously not reached the “G” state.

Next, the sequencer 14 executes an “F” verify (S201). The “F” verify is a verify read for the selected memory cell transistor MCsel in which the “F” state is the target state. In the “F” verify, the sequencer 14 determines whether the threshold voltage of the selected memory cell transistor MCsel that is the target of the “F” verify has exceeded the verify voltage FV using the sense time TS1, or determines whether the threshold voltage of the selected memory cell transistor MCsel that is the target of the “F” verify has exceeded the verify voltage FV′ using the sense time TS2. Step S201 is omitted in a case where the write of the “F” state is completed. In addition, step S201 may be omitted in a loop process in which it is estimated that the threshold voltage of the program-target selected memory cell transistor MCsel has obviously not reached the “F” state.

Next, the sequencer 14 executes an “E” verify (S202). The “E” verify is a verify read for the selected memory cell transistor MCsel in which the “E” state is the target state. In the “E” verify, the sequencer 14 determines whether the threshold voltage of the selected memory cell transistor MCsel that is the target of the “E” verify has exceeded the verify voltage EV using the sense time TS1. Step S202 is omitted in a case where the write of the “E” state is completed. In addition, step S202 may be omitted in a loop process in which it is estimated that the threshold voltage of the program-target selected memory cell transistor MCsel has obviously not reached the “E” state.

Next, the sequencer 14 executes a “D” verify (S203). The “D” verify is a verify read for the selected memory cell transistor MCsel in which the “D” state is the target state. In the “D” verify, the sequencer 14 determines whether the threshold voltage of the selected memory cell transistor MCsel that is the target of the “D” verify has exceeded the verify voltage DV using the sense time TS1, or determines whether the threshold voltage of the selected memory cell transistor MCsel that is the target of the “D” verify has exceeded the verify voltage DV′ using the sense time TS2. Step S203 is omitted in a case where the write of the “D” state is completed. In addition, step S203 may be omitted in a loop process in which it is estimated that the threshold voltage of the program-target selected memory cell transistor MCsel has obviously not reached the “D” state.

Next, the sequencer 14 executes a “C” verify (S204). The “C” verify is a verify read for the selected memory cell transistor MCsel in which the “C” state is the target state. In the “C” verify, the sequencer 14 determines whether the threshold voltage of the selected memory cell transistor MCsel that is the target of the “C” verify has exceeded the verify voltage CV using the sense time TS1. Step S204 is omitted in a case where the write of the “C” state is completed. In addition, step S204 may be omitted in a loop process in which it is estimated that the threshold voltage of the program-target selected memory cell transistor MCsel has obviously not reached the “C” state.

Next, the sequencer 14 executes a “B” verify (S205). The “B” verify is a verify read for the selected memory cell transistor MCsel in which the “B” state is the target state. In the “B” verify, the sequencer 14 determines whether the threshold voltage of the selected memory cell transistor MCsel that is the target of the “B” verify has exceeded the verify voltage BV using the sense time TS1, or determines whether the threshold voltage of the selected memory cell transistor MCsel that is the target of the “B” verify has exceeded the verify voltage BV′ using the sense time TS2. Step S205 is omitted in a case where the write of the “B” state is completed. In addition, step S205 may be omitted in a loop process in which it is estimated that the threshold voltage of the program-target selected memory cell transistor MCsel has obviously not reached the “B” state.

Next, the sequencer 14 executes an “A” verify (S206). The “A” verify is a verify read for the selected memory cell transistor MCsel in which the “A” state is the target state. In the “A” verify, the sequencer 14 determines whether the threshold voltage of the selected memory cell transistor MCsel that is the target of the “A” verify has exceeded the verify voltage AV using the sense time TS1. Step S206 is omitted in a case where the write of the “A” state is completed.

Next, as in the first embodiment, the sequencer 14 checks whether the writes of all the states have been completed (S107).

In step S107, if the writes of all the states have been not completed (S107: NO), the sequencer 14 steps up the VPGM (S108). Upon completion of step S108, the sequencer 14 proceeds to step S101. That is, if the writes of all the states have not been completed in step S107, the sequencer 14 executes the next loop process using the stepped-up VPGM.

In step S107, if the writes of all the states have been completed (S107: YES), the sequencer 14 ends the series of processes in FIG. 25 (end). That is, the sequencer 14 ends the write operation and notifies the memory controller 2 of the end of the write operation.

Other operations of the memory device 1 according to the second embodiment are similar to those of the first embodiment.

### <2-3> Advantageous Effects of Second Embodiment

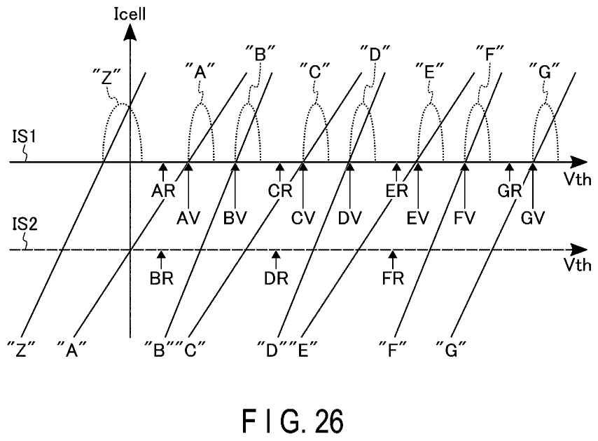

In the write operation, the memory device 1 according to the second embodiment executes the writes of the S-factor as in the first embodiment, and executes the verify operation for each state. FIG. 26 is a graph illustrating an example of IV characteristics of memory cells in the memory device 1 according to the second embodiment. In FIG. 26, the horizontal axis corresponds to a gate-source voltage Vgs of the memory cell transistor MC, and the vertical axis corresponds to a current Icell flowing through a memory cell transistor MC. As illustrated in FIG. 26, the memory device 1 can finely control the arrangement of the states in each of the threshold voltage distribution of the memory cell transistor MC in the case of a sense time TS1 and the threshold voltage distribution of the memory cell transistor MC in the case of a sense time TS2 by executing the verify operation for each state.

As a result, the memory device 1 according to the second embodiment can widen the read margin in the case of using a first sense current IS1 and the read margin in the case of using a second sense current IS2. Therefore, the memory device 1 according to the second embodiment can increase the read margin and improve the reliability of the memory device 1, as in the first embodiment.

### <3> Third Embodiment

A memory device 1 according to a third embodiment implements a data storage method similar to that of the first embodiment in a NAND flash memory using a memory cell including a floating gate. Hereinafter, details of the memory device 1 according to the third embodiment will be described based on differences from the first embodiment.

### <3-1> Configuration

First, a configuration of the memory device 1 according to the third embodiment will be described. The memory device 1 according to the third embodiment has a configuration in which the structure of a memory pillar MP and the allocation of a data storage area are different from those of the memory device 1 according to the first embodiment. Hereinafter, the memory pillar MP in the third embodiment will be called “memory pillar MPa”.

### <3-1-1> Structure of Memory Pillar MP

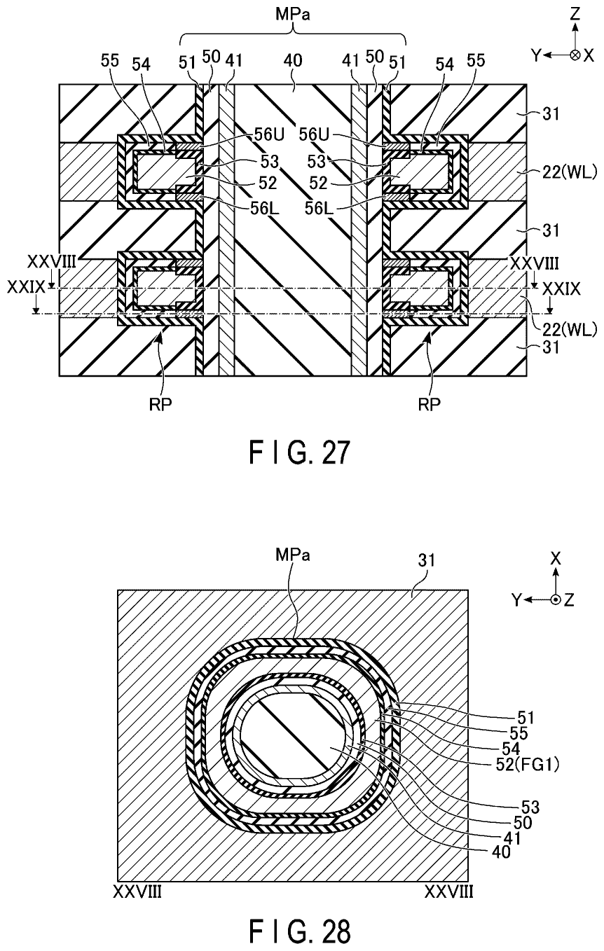

FIG. 27 is a cross-sectional view of an example of a cross-sectional structure of the memory pillar MPa included in the memory device 1 according to the third embodiment. FIG. 27 illustrates an extracted portion of intersection between two adjacent word lines WL and the memory pillar MPa. As illustrated in FIG. 27, the memory pillar MPa is different from the memory pillar MP in the first embodiment in that the memory pillar MPa has a recess portion RP and a different configuration related to the memory cell transistor MC.

The recess portion RP corresponds to a portion protruding in a direction along the Y direction from a portion provided to extend along the Z direction of the memory pillar MPa. The recess portion RP is in contact with conductor layers 21, 22, and 23. Therefore, the outer diameter of the cross section of the memory pillar MPa along the XY plane is larger in the portion including the recess portion RP than in the portion not including the recess portion RP.

The memory pillar MPa includes a core member 40, a semiconductor layer 41, insulator layers 50 and 51, a semiconductor layer 52, insulator layers 53, 54, and 55, and semiconductor layers 56U and 56L. The core member 40 extends along the Z direction. The semiconductor layer 41 covers the periphery of the core member 40. The bottom portion of the semiconductor layer 41 is in contact with a semiconductor substrate 20 (not illustrated). The insulator layer 50 covers the side surfaces of the semiconductor layer 41. The insulator layer 51 is provided along the outer peripheral portion of the memory pillar MP. For example, the insulator layer 51 is in contact with conductor layer 22 in the recess portion RP, and is in contact with insulator layer 31 and semiconductor layer 41 in the portion except for the recess portion RP.

The semiconductor layer 52 is provided in the center of the recess portion RP. The periphery of the semiconductor layer 52 is covered by a set of insulator layers 53 and 54. The insulator layer 53 has a portion provided between the insulator layer 50 and the semiconductor layer 52. The insulator layer 54 is in contact with the semiconductor layer 52 and the insulator layer 55 and has a portion provided between the semiconductor layer 52 and the conductor layer 22 and a portion provided between the semiconductor layer 52 and the insulator layer 31. The insulator layer 55 is in contact with the insulator layers 54 and 51 and has a portion provided between the insulator layer 54 and the conductor layer 22 and a portion provided between the insulator layer 54 and the insulator layer 31.

A semiconductor layer 56U is provided above a semiconductor layer 56L. The semiconductor layers 56U and 56L are separated and insulated from each other. Each of the semiconductor layers 56L and 56U is covered with a set of insulator layers 50, 51, 53, 54, and 55, for example. Each of the semiconductor layers 56L and 56U has a portion provided between the conductor layer 22 and the semiconductor layer 41. The semiconductor layer 56 is separated and insulated from at least the semiconductor layers 41 and 52 and the conductor layer 22. In the recess portion RP, the semiconductor layer 52 has a larger volume ratio than the semiconductor layer 56.

Each of the semiconductor layers 41, 52, 56L, and 56U contains silicon, for example. Each of the insulator layers 51, 53, and 54 is a silicon oxide film (SiO), for example. The insulator layer 55 is a silicon oxide film (HfSiO) containing hafnium, for example. In the memory pillar MPa, the semiconductor layer 52 corresponds to a first floating gate, and the semiconductor layers 56L and 56U correspond to a second floating gate. The memory cell transistor MC in the third embodiment stores data in a nonvolatile manner by a set of the first floating gate and the second floating gate. The functions of the first floating gate and the second floating gate are associated with the storage units P1 and P2 of the first embodiment, respectively. Hereinafter, the semiconductor layer 52 will be called “floating gate portion FG1”, and the semiconductor layers 56L and 56U will be called “floating gate portion FG2”.

FIG. 28 is a cross-sectional view taken along line XXVIII-XXVIII of FIG. 27. FIG. 28 illustrates an example of a cross section of the memory pillar MPa including the semiconductor layer 52 (floating gate portion FG1) along the XY plane. As illustrated in FIG. 28, in the memory pillar MPa, the core member 40, the semiconductor layer 41, the insulator layers 50 and 53, the semiconductor layer 52 (floating gate portion FG1), and the insulator layers 54, 55, and 51 are concentrically provided and are arranged in this order toward the outer periphery. The floating gate portion FG1 in the third embodiment is annularly provided in the cross section along the XY plane.

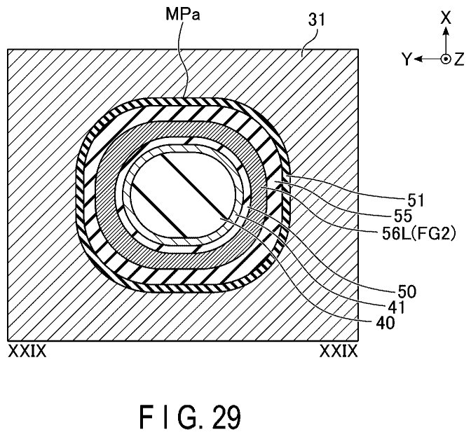

FIG. 29 is a cross-sectional view taken along line XXIX-XXIX of FIG. 27. FIG. 29 illustrates an example of a cross section of the memory pillar MPa including the semiconductor layer 56L (floating gate portion FG2) along the XY plane. As illustrated in FIG. 29, in the memory pillar MPa, the core member 40, the semiconductor layer 41, the insulator layer 50, the semiconductor layer 56L (floating gate portion FG1), and the insulator layers 55 and 51 are concentrically provided and arranged in this order toward the outer periphery. The floating gate portion FG2 in the third embodiment is annularly provided in the cross section along the XY plane. Although not illustrated, the semiconductor layer 56U is annularly provided in the cross section along the XY plane, similarly to the semiconductor layer 56L.

### <3-1-2> Data Storage Area

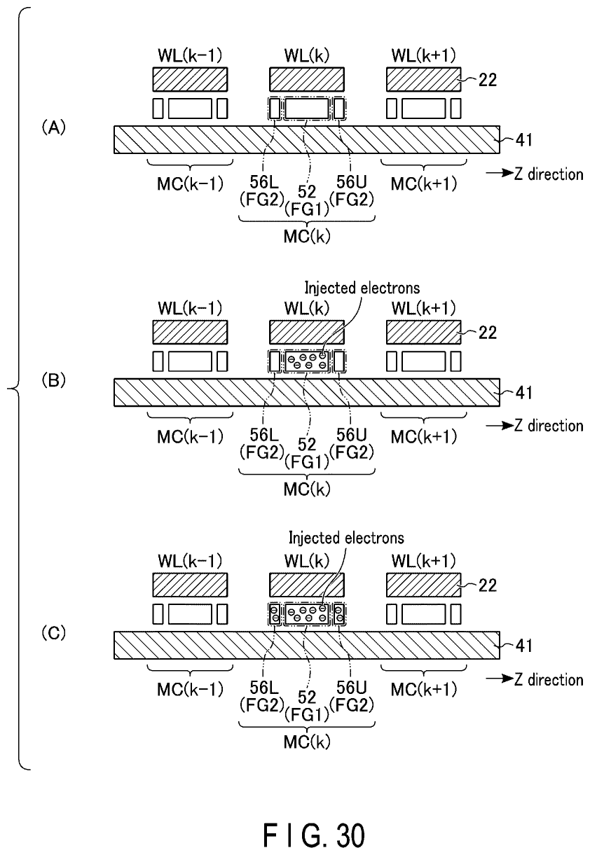

FIG. 30 is a schematic diagram illustrating an example of a data storage area of the NAND string NS included in the memory device 1 according to the third embodiment. FIG. 30 illustrates extracted portions of the NAND string NS corresponding to the memory cell transistors MC (k−1) to MC (k+1), and illustrates three word lines WL (k−1) to WL (k+1) (three conductor layers 22), the semiconductor layers 52, 56L, and 56U (charge storage layers), and the semiconductor layer 41. In this example, “k” is an integer of 1 or larger and 6 or smaller. The upper limit of “k” in the third embodiment can vary depending on the design of the memory cell array 10.

The memory cell transistor MC is a floating gate-type memory cell, and the charge storage layer of the NAND string NS is provided separately for each memory cell transistor MC. Each memory cell transistor MC includes the semiconductor layer 52 (floating gate portion FG1) and the semiconductor layers 56L and 56U (floating gate portion FG2) as charge storage layers. The semiconductor layers 52, 56L, and 56U of the memory cell transistor MC (k) are provided between the conductor layer 22 corresponding to the word line WL (k) and the semiconductor layer 41.
(A) of FIG. 30 corresponds to a case where the memory cell transistor MC (k) in the third embodiment is in the erase state. As illustrated in (A) of FIG. 30, each of the floating gate portions FG1 and FG2 of the memory cell transistor MC (k) in the erase state is in a state of not storing electrons.
(B) of FIG. 30 corresponds to a case where the memory cell transistor MC (k) according to the third embodiment has a first S-factor. As illustrated in (B) of FIG. 30, the floating gate portion FG1 of the memory cell transistor MC (k) having the first S-factor stores an amount of electrons corresponding to the data. On the other hand, the floating gate portion FG2 of the memory cell transistor MC (k) having the first S-factor does not store electrons or is suppressed from storing electrons. That is, in the memory cell transistor MC (k) having the first S-factor, electrons are injected into the floating gate portion FG1.
(C) of FIG. 30 corresponds to a case where the memory cell transistor MC (k) according to the third embodiment has a second S-factor lower than the first S-factor. As illustrated in (C) of FIG. 30, the floating gate portion FG1 of the memory cell transistor MC (k) having the second S-factor stores an amount of electrons corresponding to the data. The floating gate portion FG2 of the memory cell transistor MC (k) having the second S-factor stores electrons more than the floating gate portion FG2 of the memory cell transistor MC (k) having the first S-factor. That is, in the memory cell transistor MC (k) having the second S-factor, electrons are injected into each of the floating gate portions FG1 and FG2.

### (IV Characteristics of Memory Cell Transistor MC)

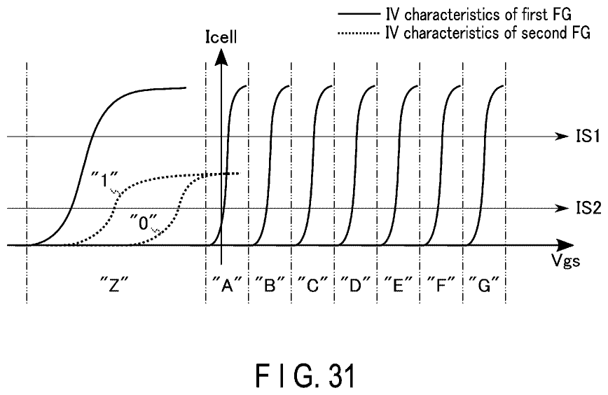

FIG. 31 is a graph illustrating an example of IV (current-voltage) characteristics of the memory cell transistor MC included in the memory device 1 according to the third embodiment. In the graph illustrated in FIG. 31, the horizontal axis corresponds to a gate-source voltage Vgs of the memory cell transistor MC, the horizontal axis indicates a gate-source voltage Vgs of the memory cell transistor MC, and the vertical axis indicates a current Icell flowing through the memory cell transistor MC. The solid lines correspond to the IV characteristics of the portion corresponding to the floating gate portion FG1, and the broken lines correspond to the IV characteristics of the portion corresponding to the floating gate portion FG2.

As illustrated in FIG. 31, each memory cell transistor MC may form eight types of IV characteristics corresponding to the “Z” state, the “A” state, the “B” state, the “C” state, the “D” state, the “E” state, the “F” state, and the “G” state based on the amount of electrons stored in the floating gate portion FG1. In addition, each memory cell transistor MC can form two types of IV characteristics based on the amount of electrons stored in the floating gate portion FG2. For example, the erase state of the floating gate portion FG2 corresponds to “1” data, and the state in which electrons are injected into the floating gate portion FG2 corresponds to “0” data. Then, the threshold voltage distribution of the cell unit CU in the third embodiment is formed based on characteristics obtained by adding the IV characteristics corresponding to the floating gate portion FG1 and the IV characteristics corresponding to the floating gate portion FG2.

The value of the saturation current in the IV characteristics corresponding to the floating gate portion FG1 is higher than the value of the saturation current in the IV characteristics corresponding to the floating gate portion FG2. Specifically, the value of the saturation current in the IV characteristics corresponding to the floating gate portion FG1 is higher than the sense current IS1. The value of the saturation current in the IV characteristics corresponding to the floating gate portion FG2 is lower than the sense current IS1 and higher than the sense current IS2. The sense current IS1 is used to read the data written in the floating gate portion FG1. The sense current IS2 is used to read the data written in the floating gate portion FG2. In the memory cell transistor MC of the third embodiment, the floating gate portion FG1 stores eight values (that is, 3-bit data), and the floating gate portion FG2 stores two values (that is, 1-bit data). Therefore, the memory cell transistor MC of the third embodiment can store 4-bit data.

In the memory device 1 according to the third embodiment, the memory cell transistor MC in which the floating gate portion FG2 is in the erase state has the first S-factor described in the first embodiment. The memory cell transistor MC in which electrons are injected into the floating gate portion FG2 has the second S-factor described in the first embodiment. Therefore, the memory device 1 according to the third embodiment can store data as in the first embodiment by the write operation in which the state of the S-factor of the memory cell transistor MC can be written in two types and the selective use of the sense times TS1 and TS2.

### <3-2> Operations

Next, operations of the memory device 1 according to the third embodiment will be described. The memory device 1 according to the third embodiment forms the threshold voltage distribution of the memory cell transistor MC described in relation to the first or second embodiment by a write operation adapted to the memory cell transistor MC having the floating gate portions FG1 and FG2. Hereinafter, the write operation of the memory device 1 according to the third embodiment will be described using a case of forming the threshold voltage distribution of the memory cell transistor MC described in relation to the first embodiment as an example.

### (Flow of Write Operation)

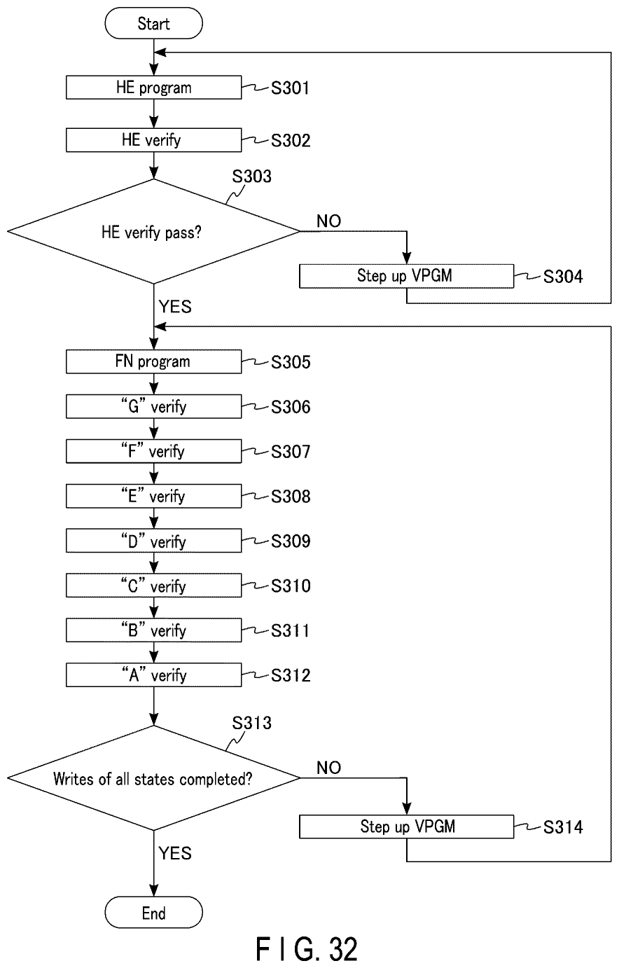

Hereinafter, a flow of the write operation of the memory device 1 according to the third embodiment will be described with reference to FIG. 32. FIG. 32 is a flowchart illustrating an example of the write operation of the memory device 1 according to the third embodiment. A broken line in FIG. 32 indicates a path of a processing flow in a case where the associated step is omitted.

When the memory device 1 receives a command for instructing the write operation, the address of the cell unit CU as the write destination, and the data to be written from the memory controller 2, the sequencer 14 starts the write operation (start).

First, the sequencer 14 executes an HE program (S301). The HE program is a program process for the selected memory cell transistor MCsel in which the state set to the second S-factor is the target state. In the HE program, electrons are injected into the floating gate portion FG2 of the program-target selected memory cell transistor MCsel using hot electrons. Accordingly, the S-factor of the program-target selected memory cell transistor MCsel becomes the second S-factor. In the HE program, electrons may or may not be injected into the floating gate portion FG1 of the selected memory cell transistor MCsel. This is because even if the threshold voltage of the selected memory cell transistor MCsel changes, the threshold voltage of the selected memory cell transistor MCsel rises due to the subsequent loop process, and the verify operation is further executed.

Next, the sequencer 14 executes an HE verify (S302). In the HE verify, the verify voltage associated with the “0” data of the sense current IS1 is applied to the selected word line WLsel, and the read operation using the sense current IS1 is executed. Then, it is checked whether the threshold voltage of the program-target memory cell transistor MCcel is written up to the level of “0” data in the sense current IS1.

Next, the sequencer 14 checks whether the HE verify has been passed (S303: HE verify pass?). For example, in step S303, the sequencer 14 checks whether the number of selected memory cell transistors MCsel having not passed the HE verify is less than a predetermined number.

In step S303, if it is confirmed that the memory cell transistor has not passed the HE verify (S303: NO), the sequencer 14 steps up the VPGM (S304). Upon completion of step S304, the sequencer 14 proceeds to step S301. That is, the sequencer 14 sequentially executes the HE program and the HE verify again using the stepped up VPGM if the memory cell transistor was determined as not passed the HE verify in step S303.

In step S303, if it is determined that the memory cell transistor has passed the HE verify (S303: YES), the sequencer 14 then executes an FN program (S305). The FN program is a program process for the selected memory cell transistor MCsel in which the threshold voltage has not reached the target state. In the FN program, electrons are injected into the floating gate portion FG1 of the program-target selected memory cell transistor MCsel using a Fowler-Nordheim (FN) tunnel current. Accordingly, the threshold voltage of the program-target selected memory cell transistor MCsel rises. At the time of transition from step S303 to step S305, the sequencer 14 resets various setting voltages such as VPGM to the initial voltages for the FN program.

Next, the sequencer 14 executes a “G” verify (S306). In the “G” verify of the third embodiment, the sense current IS1 is used, and it is determined whether the threshold voltage of the selected memory cell transistor MCsel to be subjected to the “G” verify has exceeded a verify voltage GV. Step S306 may be omitted in a loop process in which it is estimated that the threshold voltage of the program-target selected memory cell transistor MCsel has obviously not reached the “G” state.

Next, the sequencer 14 executes an “F” verify (S307). In the “F” verify of the third embodiment, the sense current IS1 is used, and it is determined whether the threshold voltage of the selected memory cell transistor MCsel to be subjected to the “F” verify has exceeded a verify voltage FV. Step S307 is omitted in a case where the program of the “F” state is completed. In addition, step S307 may be omitted in a loop process in which it is estimated that the threshold voltage of the program-target selected memory cell transistor MCsel has obviously not reached the “F” state.

Next, the sequencer 14 executes an “E” verify (S308). In the “E” verify of the third embodiment, the sense current IS1 is used, and it is determined whether the threshold voltage of the selected memory cell transistor MCsel to be subjected to the “E” verify has exceeded a verify voltage EV. Step S308 is omitted in a case where the write of the “E” state is completed. In addition, step S308 may be omitted in a loop process in which it is estimated that the threshold voltage of the program-target selected memory cell transistor MCsel has obviously not reached the “E” state.

Next, the sequencer 14 executes a “D” verify (S309). In the “D” verify of the third embodiment, the sense current IS1 is used, and it is determined whether the threshold voltage of the selected memory cell transistor MCsel to be subjected to the “D” verify has exceeded a verify voltage DV. Step S309 is omitted in a case where the write of the “D” state is completed. In addition, step S309 may be omitted in a loop process in which it is estimated that the threshold voltage of the program-target selected memory cell transistor MCsel has obviously not reached the “D” state.

Next, the sequencer 14 executes a “C” verify (S310). In the “C” verify of the third embodiment, the sense current IS1 is used, and it is determined whether the threshold voltage of the selected memory cell transistor MCsel to be subjected to the “C” verify has exceeded a verify voltage CV. Step S310 is omitted in a case where the write of the “C” state is completed. In addition, step S310 may be omitted in a loop process in which it is estimated that the threshold voltage of the program-target selected memory cell transistor MCsel has obviously not reached the “C” state.

Next, the sequencer 14 executes a “B” verify (S311). In the “B” verify of the third embodiment, the sense current IS1 is used, and it is determined whether the threshold voltage of the selected memory cell transistor MCsel to be subjected to the “B” verify has exceeded a verify voltage BV. Step S311 is omitted in a case where the write of the “B” state is completed. In addition, step S311 may be omitted in a loop process in which it is estimated that the threshold voltage of the program-target selected memory cell transistor MCsel has obviously not reached the “B” state.

Next, the sequencer 14 executes an “A” verify (S312). In the “A” verify of the third embodiment, the sense current IS1 is used, and it is determined whether the threshold voltage of the selected memory cell transistor MCsel to be subjected to the “A” verify has exceeded a verify voltage AV. Step S312 is omitted in a case where the write of the “A” state is completed.

Next, the sequencer 14 checks whether the writes of all the states have been completed (S313).

In step S313, if the writes of all the states have been not completed (S313: NO), the sequencer 14 steps up the VPGM (S314). Upon completion of step S314, the sequencer 14 proceeds to step S305. That is, if the writes of all the states have not been completed in step S313, the sequencer 14 executes the next loop process using the stepped-up VPGM.

In step S313, if the writes of all the states have been completed (S313: YES), the sequencer 14 ends the series of processes in FIG. 32 (end). That is, the sequencer 14 ends the write operation and notifies the memory controller 2 of the end of the write operation.

As described above, in the write operation of the third embodiment, after the loop process including the HE program (S301) is executed, the loop process including the FN program (S305) is executed.

### (Specific Example of HE Program)

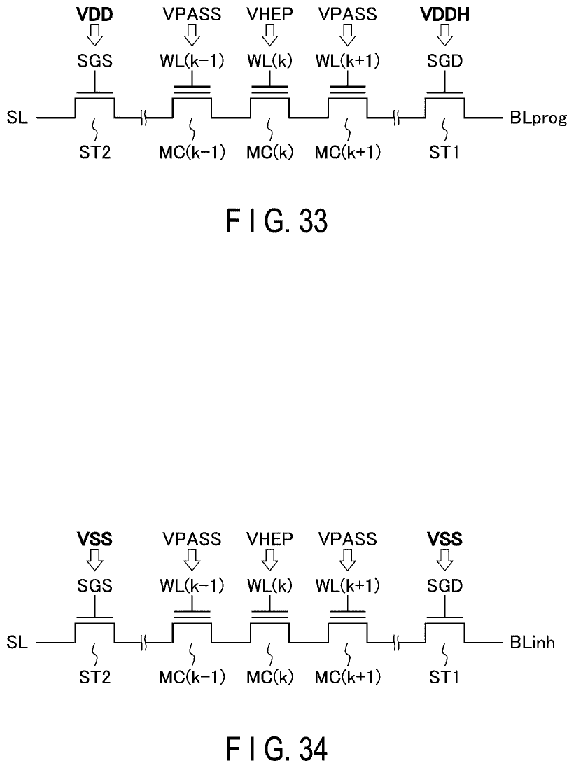

FIG. 33 is a schematic diagram illustrating a specific example of the HE program for a selected string in the memory device 1 according to the third embodiment. FIG. 33 illustrates voltages applied to the word lines WL (k−1), WL (k), and WL (k+1) and the select gate lines SGD and SGS of the selected string in a case where the word line WL (k) is the selected word line WLsel in the HE program.

As illustrated in FIG. 33, in the HE program, the sequencer 14 applies VPASS, VHEP, VPASS, VDD, and VDDH to the word lines WL (k−1), WL (k), and WL (k+1) and the select gate lines SGS and SGD of the selected string, respectively. VHEP is a high voltage capable of injecting hot electrons into the floating gate portion FG2 of the selected memory cell transistor MCsel, and is a voltage higher than VPASS, for example. VDDH is a voltage higher than VDD and lower than VPASS.

Accordingly, the select transistors ST1 and ST2 are turned on, and electrons are supplied to the channel of the NAND string NS based on the voltage difference between the source line SL and the program bit line BLprog. Then, electrons (hot electrons) are injected into the floating gate portion FG2 of the memory cell transistor MC (k) based on the voltage of the word line WL (k) and the channel current.

FIG. 34 is a schematic diagram illustrating a specific example of the HE program for an unselected string in the memory device 1 according to the third embodiment. FIG. 33 illustrates voltages applied to the word lines WL (k−1), WL (k), and WL (k+1) and the select gate lines SGD and SGS of the unselected string in a case where the word line WL (k) is the selected word line WLsel in the HE program.

As illustrated in FIG. 34, voltages applied to the word lines WL (k−1), WL (k), and WL (k+1) are similar to those in FIG. 33. In the HE program, the sequencer 14 applies VSS to each of the select gate lines SGS and SGD of the unselected string. Accordingly, the select transistors ST1 and ST2 are turned off, and the current path between the source line SL and the program bit line BLprog is shut off. Therefore, even if VHEP is applied to the word line WL (k), injection of electrons into the floating gate portion FG2 of the selected memory cell transistor MCsel is suppressed.

### (Specific Example of FN Program)

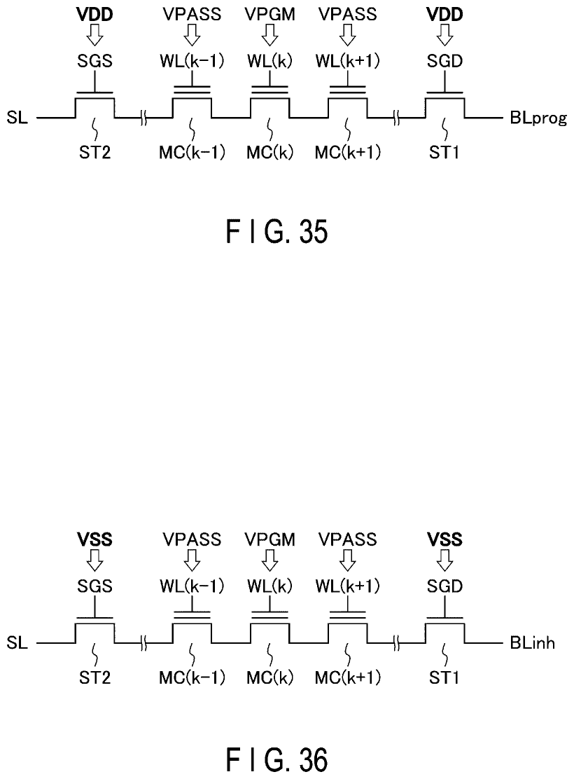

FIG. 35 is a schematic diagram illustrating a specific example of the FN program for a selected string in the memory device 1 according to the third embodiment. FIG. 35 illustrates voltages applied to the word lines WL (k−1), WL (k), and WL (k+1) and the select gate lines SGD and SGS of the selected string in a case where the word line WL (k) is the selected word line WLsel in the FN program.

As illustrated in FIG. 35, in the FN program, the sequencer 14 applies VPASS, VPGM, VPASS, VDD, and VDD to the word lines WL (k−1), WL (k), and WL (k+1) and the select gate lines SGS and SGD of the selected string, respectively. Accordingly, the select transistors ST1 and ST2 are turned on, and the channel potential becomes VSS based on the voltage applied to the program bit line BLprog. Then, electrons are injected into the floating gate portion FG1 of the memory cell transistor MC (k) based on the potential difference between the word line WL (k) and the channel.

FIG. 36 is a schematic diagram illustrating a specific example of the FN program for an unselected string in the memory device 1 according to the third embodiment. FIG. 36 illustrates voltages applied to the word lines WL (k−1), WL (k), and WL (k+1) and the select gate lines SGD and SGS of the unselected string in a case where the word line WL (k) is the selected word line WLsel in the FN program.

As illustrated in FIG. 36, voltages applied to the word lines WL (k−1), WL (k), and WL (k+1) are similar to those in FIG. 35. In the FN program, the sequencer 14 applies VSS to each of the select gate lines SGS and SGD of the unselected string. Accordingly, the select transistors ST1 and ST2 are turned off, and the current path between the source line SL and the program bit line BLprog is shut off. Accordingly, VPASS is applied to the unselected word line WL, so that the channel potential is boosted. As a result, even if VPGM is applied to the word line WL (k), injection of electrons into the floating gate portion FG1 of the selected memory cell transistor MCsel is suppressed.

Other operations of the memory device 1 according to the third embodiment are similar to those of the first embodiment.

### <3-3> Manufacturing Method

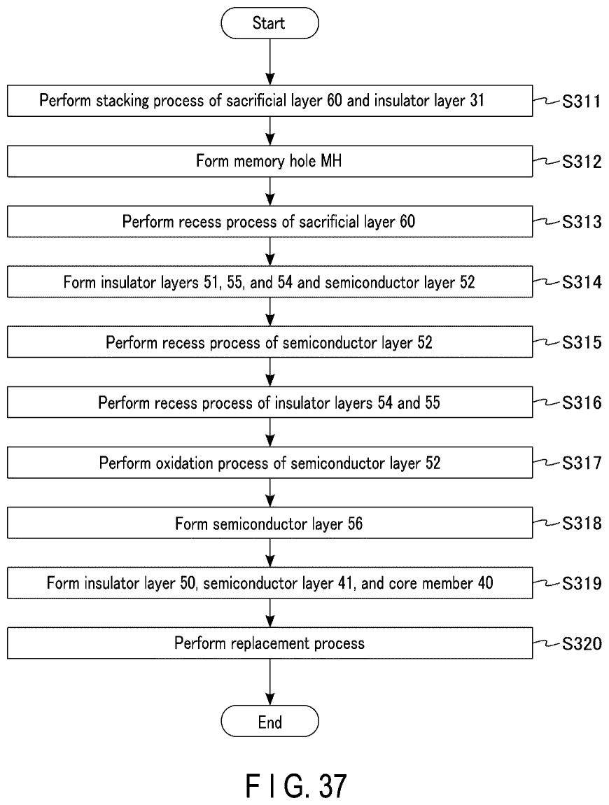

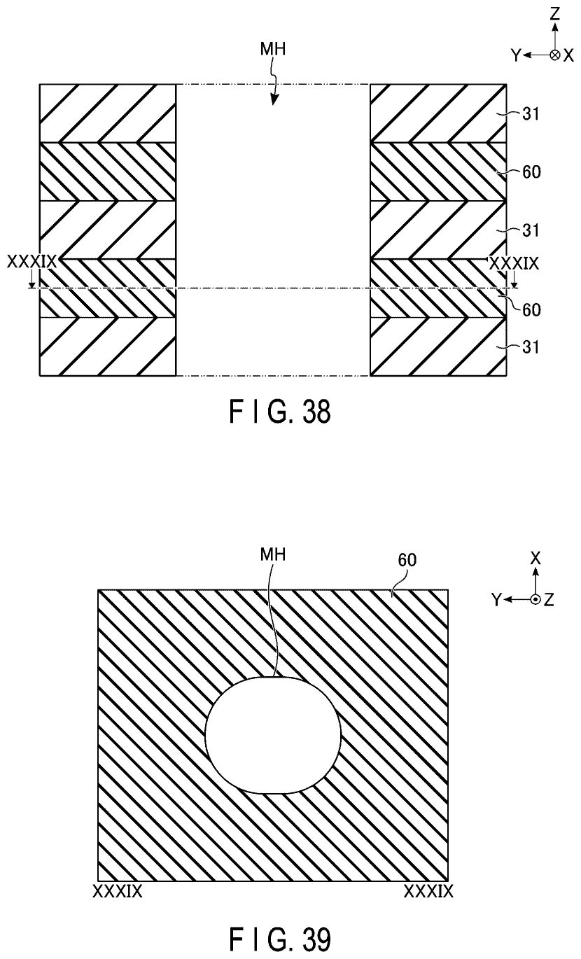

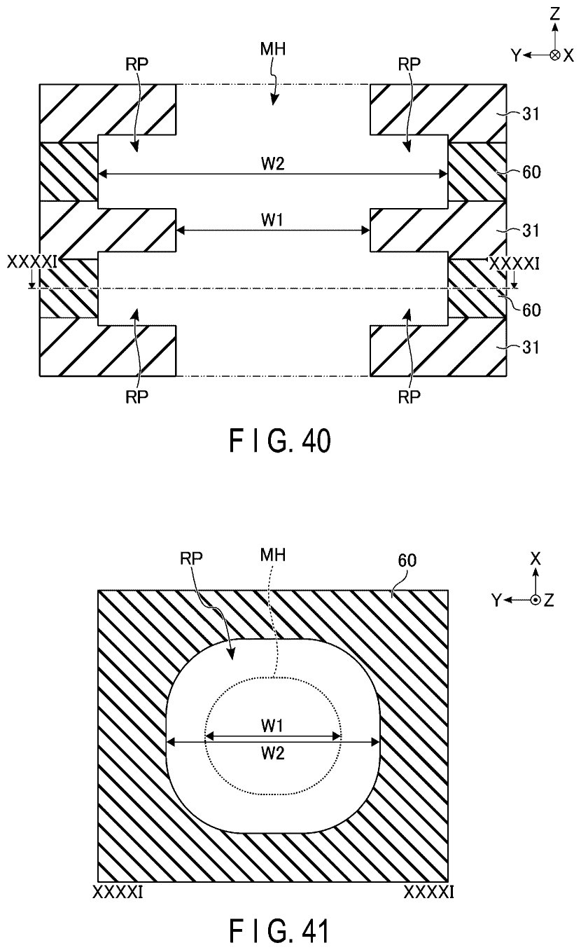

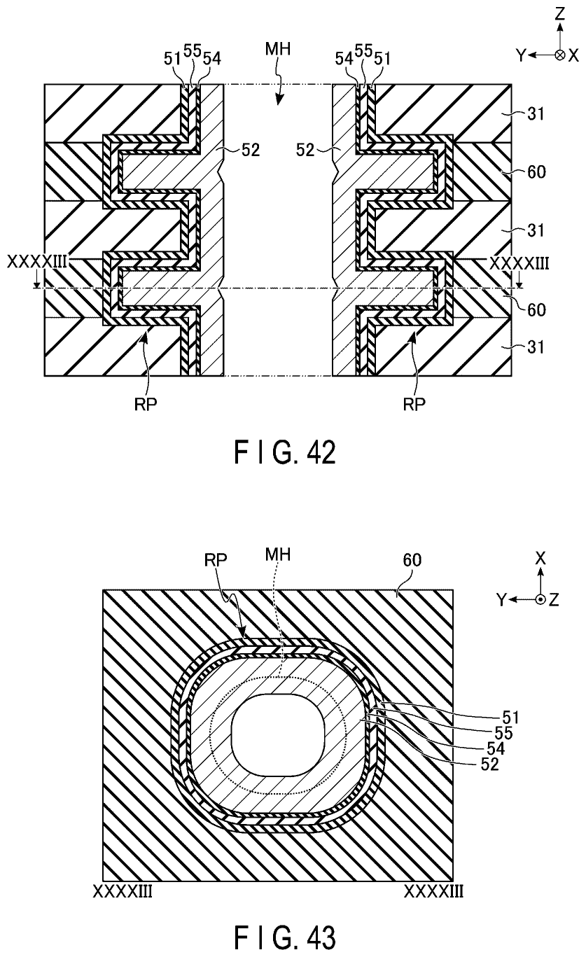

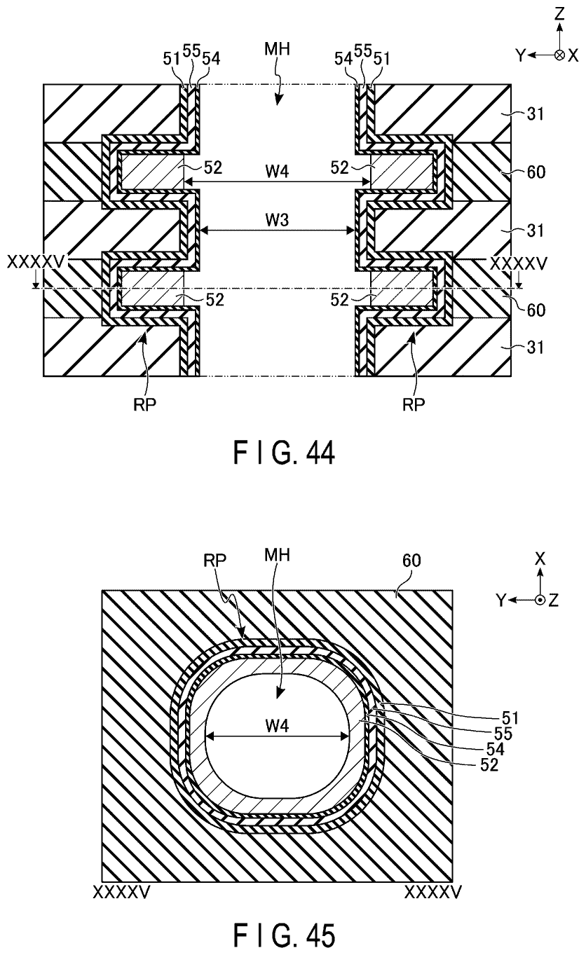

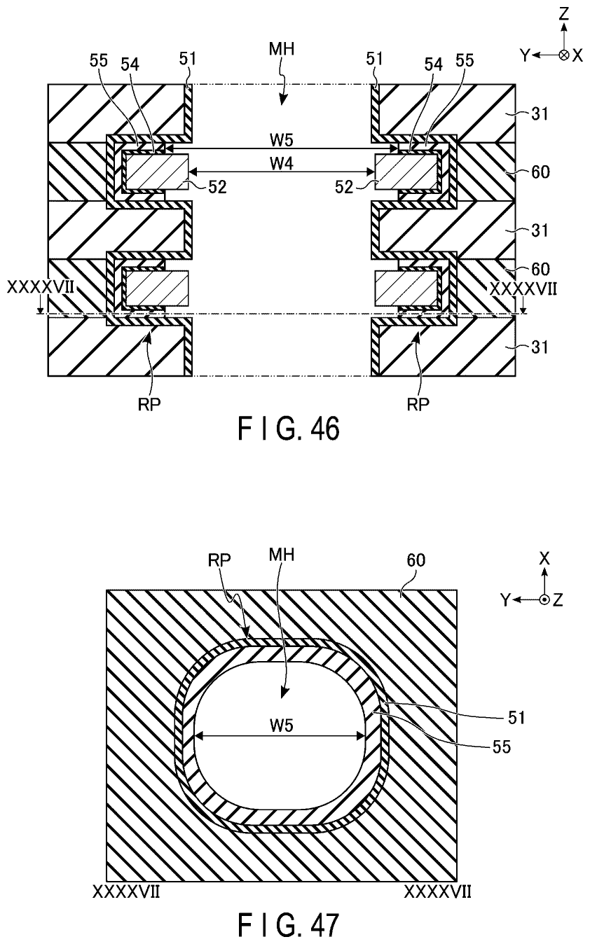

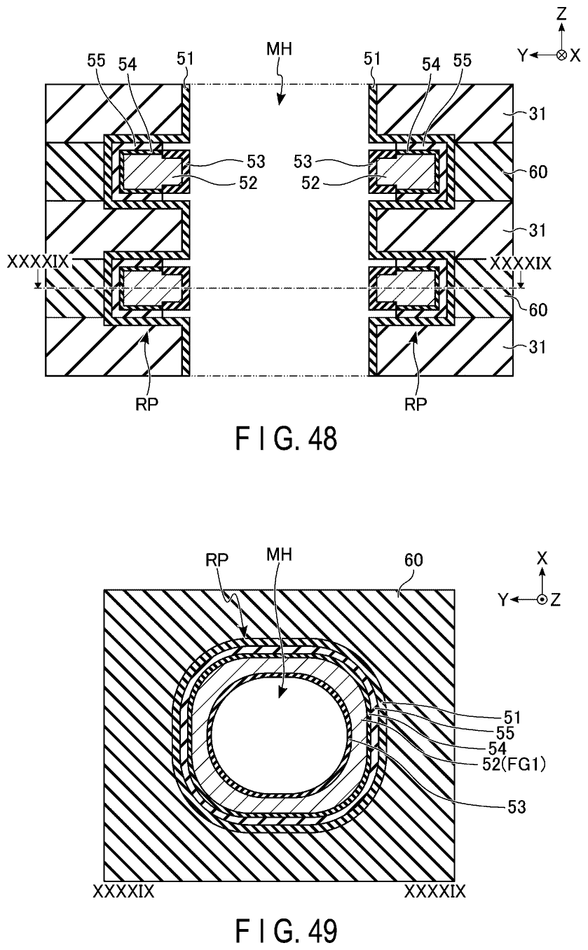

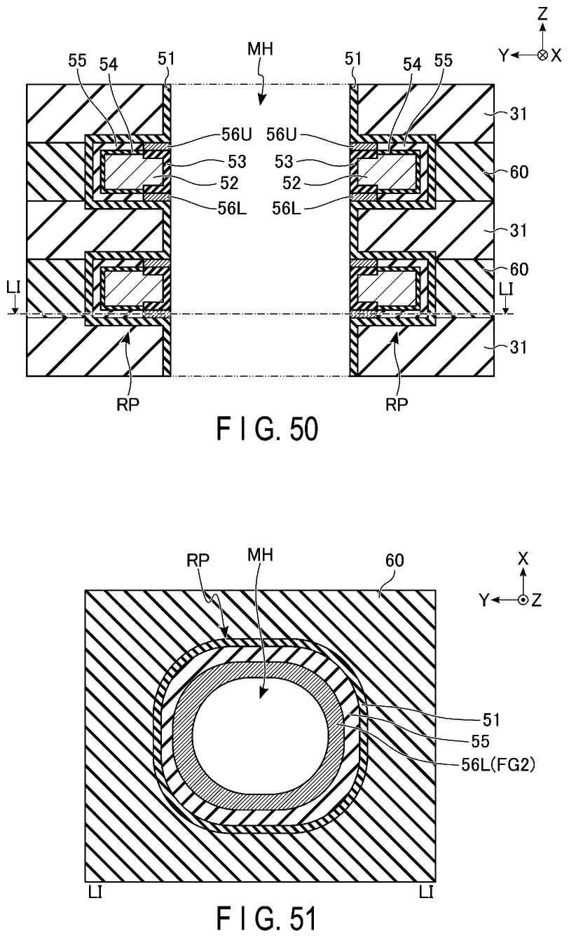

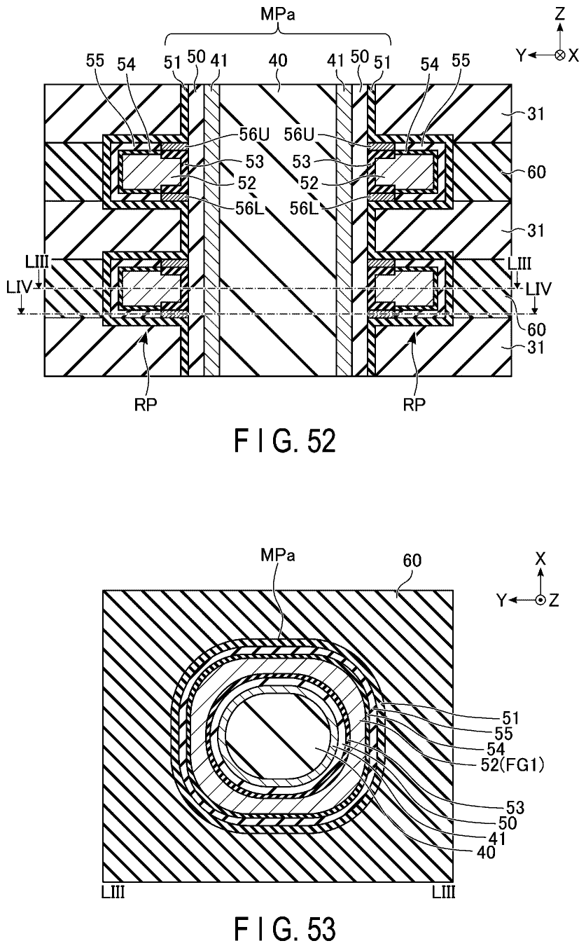

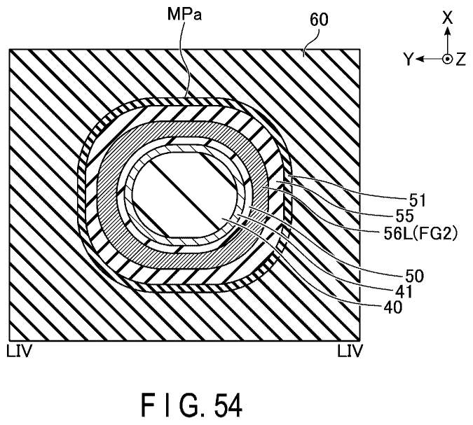

Next, an example of a method of manufacturing the memory device 1 according to the third embodiment will be described with reference to FIG. 37 as appropriate. FIG. 37 is a flowchart illustrating an example of a method of manufacturing the memory device 1 according to the third embodiment. Each of FIGS. 38 to 54 referred to below is a cross-sectional view of an example of a cross-sectional structure in the process of manufacturing the memory device according to the third embodiment. Each of FIGS. 38, 40, 42, 44, 46, 48, 50, and 52 illustrates a region where the memory pillar MP illustrated in FIG. 27 is to be formed. FIG. 39 illustrates a cross section taken along line XXXIX-XXXIX in FIG. 38. FIG. 41 illustrates a cross section taken along line XXXXI-XXXXI in FIG. 40. FIG. 43 illustrates a cross section taken along line XXXXIII-XXXXIII in FIG. 42. FIG. 45 illustrates a cross section taken along line XXXXV-XXXXV in FIG. 44. FIG. 47 illustrates a cross section taken along line XXXXVII-XXXXVII in FIG. 46. FIG. 49 illustrates a cross section taken along line XXXXIX-XXXXIX in FIG. 48. FIG. 51 illustrates a cross section taken along line LI-LI in FIG. 50. FIG. 53 illustrates a cross section taken along line LIII-LIII in FIG. 52. FIG. 54 illustrates a cross section taken along line LIV-LIV in FIG. 52.

First, a stacking process of a sacrificial layer 60 and the insulator layer 31 is executed (S311). As a result, for example, a structure in which the insulator layer 31 and the sacrificial layer 60 are alternately stacked is formed on the semiconductor substrate 20 (not illustrated). The sacrificial layer 60 is made of silicon nitride (SiN), for example.

Next, a memory hole MH is formed (S312). Step S312 includes a photolithography process and a reactive ion etching (RIE) process, for example. As illustrated in FIG. 38, the memory hole MH is provided to penetrate the stacked sacrificial layer 60 and insulator layer 31. The cross-sectional shape of the memory hole MH along the XY plane is circular as illustrated in FIG. 39.

Next, a recess process of the sacrificial layer 60 is executed (S313). Step S313 includes a wet etching process in which the selection ratio of the sacrificial layer 60 is high. In step S313, as illustrated in FIG. 40, the sacrificial layer 60 exposed on the side surfaces of the memory hole MH is partially removed. Accordingly, in the memory hole MH, an inner diameter W2 at the height including the sacrificial layer 60 is larger than an inner diameter W1 at the height including the insulator layer 31. In other words, a space corresponding to the recess portion RP of the memory pillar MP is formed on the side surfaces of the memory hole MH. As illustrated in FIG. 41, the recess portion RP is provided in a shape concentrically expanding from the opening portion of the memory hole MH in the cross section along the XY plane.

Next, as illustrated in FIG. 42, the insulator layers 51, 55, and 54 and the semiconductor layer 52 are formed (S314). The insulator layers 51, 55, and 54 are sequentially formed along the side surfaces of the memory hole MH and the recess portion RP. As illustrated in FIG. 43, the semiconductor layer 52 is formed so as to fill the space corresponding to the recess portion RP and not to fill the memory hole MH.

Next, a recess process of the semiconductor layer 52 is executed (S315). Step S315 includes a wet etching process in which the selection ratio of the semiconductor layer 52 is high. In step S315, as illustrated in FIG. 44, the semiconductor layer 52 provided on the side surface portions of the memory hole MH is removed. Accordingly, in the memory hole MH, an inner diameter W4 at the height including the sacrificial layer 60 is smaller than an inner diameter W3 at the height including the insulator layer 31. As illustrated in FIG. 45, the semiconductor layer 52 is provided in a ring shape in the cross section along the XY plane. The semiconductor layer 52 functions as the floating gate portion FG1.

Next, a recess process of the insulator layers 54 and 55 is performed (S316). Step S316 includes a wet etching process in which the selection ratio of the insulator layers 54 and 55 is high. In step S316, as illustrated in FIG. 46, the insulator layers 54 and 55 exposed at the side surface portions of the memory hole MH are partially removed so as to enter the recess portion RP. Accordingly, in the memory hole MH, an inner diameter W5 at the height including the sacrificial layer 60 along the recess portion RP is larger than the inner diameter W4 at the height including the semiconductor layer 52. As illustrated in FIG. 47, the insulator layer 55 is provided in a ring shape in the cross section along the XY plane, and is adjacent to the sacrificial layer 60 with the insulator layer 51 in between.

Next, an oxidation process of the semiconductor layer 52 is executed (S317). Accordingly, as illustrated in FIG. 48, the surface portion of the semiconductor layer 52 exposed in the memory hole MH is oxidized to form the insulator layer 53. At this time, the semiconductor layer 52 is surrounded by the insulator layers 53 and 54. As illustrated in FIG. 49, the semiconductor layer 52 is provided between the insulator layers 53 and 54 in the cross section along the XY plane.

Next, the semiconductor layer 56 is formed (S318). Specifically, first, the semiconductor layer 56 is provided on the side surface portions of the memory hole MH. Accordingly, the space provided in the recess portion RP is filled with the semiconductor layer 56. Thereafter, the semiconductor layer 56 provided on the side surface portions of the memory hole MH is removed by wet etching or the like. Accordingly, the semiconductor layer 56 is separated on the upper side and the lower side of each insulator layer 53, and as illustrated in FIG. 50, structures corresponding to the semiconductor layers 56U and 56L remain in the recess portion RP of the memory hole MH. As illustrated in FIG. 51, the semiconductor layer 56L is provided in a ring shape in the cross section along the XY plane, and is adjacent to the sacrificial layer 60 with the insulator layers 55 and 51 in between. The structure of the cross section of the semiconductor layer 56U along the XY plane is similar to that of the semiconductor layer 56L. Each of the semiconductor layers 56U and 56L functions as the floating gate portion FG2.

Next, the insulator layer 50, the semiconductor layer 41, and the core member 40 are formed (S319). The insulator layer 55 and the semiconductor layer 41 are sequentially formed along the side surfaces of the memory hole MH. As illustrated in FIG. 52, the core member 40 is formed so as to fill the memory hole MH. Accordingly, as illustrated in FIG. 53, a structure is formed in which the semiconductor layers 52 and 41 are adjacent to each other with the insulator layers 50 and 53 in between. In addition, as illustrated in FIG. 54, a structure in which the semiconductor layers 56 L and 41 are adjacent to each other with the insulator layer 50 interposed therebetween is formed. Although not illustrated, the semiconductor layers 56L, 56U and 41 are adjacent to each other with the insulator layer 50 in between.

Next, a replacement process is executed (S320). Specifically, first, a slit SLT is formed. Then, the stacked sacrificial layer 60 is selectively removed via the slit SLT by wet etching with hot phosphoric acid or the like. Then, the conductor is embedded in the space from which the sacrificial layer 60 was removed via the slit SLT. For the formation of the conductor in this step, chemical vapor deposition (CVD) is used, for example. Thereafter, the conductor formed on the side surface portions of the slit SLT is removed by etch-back processing, and the conductor formed on the adjacent wiring layers is separated. Accordingly, a stacked wiring including the plurality of conductor layers 22 functioning as the word lines WL is formed.

### <3-4> Advantageous Effects of Third Embodiment

The memory cell transistor MC of the memory device 1 according to the third embodiment has the floating gate portions FG1 and FG2 formed by separating a portion of the floating gate. In the write operation, electrons are injected into the floating gate portion FG1 by an FN tunnel current, and electrons are injected into the floating gate portion FG2 by writing with hot electrons. That is, the two types of floating gate portions FG1 and FG2 included in the memory cell transistor MC have different write principles.

In a case where electrons are injected into the floating gate portion FG2, the floating gate portion FG2 has high resistance but the memory cell transistor MC can be turned on due to the short channel effect. Accordingly, in the third embodiment, the memory cell transistors MC having different S-factors can be formed as in the first embodiment according to the presence or absence of electrons in the floating gate portion FG2. Then, the memory device 1 according to the third embodiment can inject electrons into the floating gate portion FG2 of the memory cell transistor MC associated with the second S-factor by the HE program. The memory device 1 according to the third embodiment can also inject electrons into the floating gate portion FG1 of each memory cell transistor MC by the FN program to increase the threshold voltage of each memory cell transistor MC to a desired level.

As a result, the memory device 1 according to the third embodiment can form a threshold voltage distribution similar to that of the first embodiment. The memory device 1 according to the third embodiment can also distinguish between adjacent states having different S-factors by executing the read operation using the two types of sense times TS1 and TS2. Therefore, the memory device 1 according to the third embodiment can increase the read margin and improve the reliability of the memory device 1.

### <4> Fourth Embodiment

A memory device 1 according to a fourth embodiment implements a data storage method similar to that of the first embodiment in a NAND flash memory that uses a memory cell including a floating gate and includes two NAND strings NS in which memory pillars MP are connected in parallel. Hereinafter, details of the memory device 1 according to the fourth embodiment will be described based on differences from the first to third embodiments.

### <4-1> Configuration

First, a configuration of the memory device 1 according to the fourth embodiment will be described. The memory device 1 according to the fourth embodiment has a configuration in which the memory cell array 10 is replaced with a memory cell array 10a and a row decoder module 16 can apply a voltage in accordance with the wiring configuration of the memory cell array 10a, as compared with the memory device 1 according to the third embodiment. Hereinafter, a case where the memory cell array 10a includes a plurality of blocks BLK and each block BLK has five string units SU will be described.

### <4-1-1> Circuit Configuration of Memory Cell Array 10a

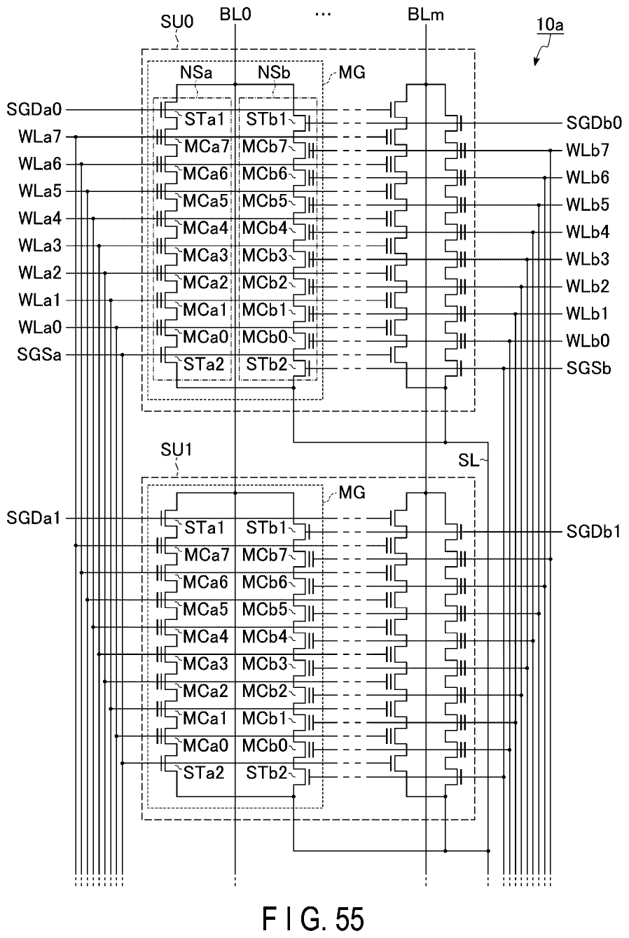

FIG. 55 is a circuit diagram illustrating an example of a circuit configuration of the memory cell array 10a included in the memory device 1 according to the fourth embodiment. FIG. 55 illustrates two extracted string units SU0 and SU1 included in the block BLK. As illustrated in FIG. 55, the memory cell array 10a includes select gate lines SGDa0 to SGDa4, SGDb0 to SGDb4, SGSa, and SGSb, word lines WLa0 to WLa7 and WLb0 to WLb7, bit lines BL0 to BLm, and a source line SL. Each of the select gate lines SGDa0 to SGDa4, SGDb0 to SGDb4, SGSa, and SGSb and the word lines WLa0 to WLa7 and WLb0 to WLb7 is provided for each block BLK. The bit lines BL0 to BLm and the source line SL are shared by the plurality of blocks BLK, for example. The row decoder module 16 of the fourth embodiment is capable of independently applying voltages to the select gate lines SGDa0 to SGDa4, SGDb0 to SGDb4, SGSa, and SGSb and the word lines WLa0 to WLa7 and WLb0 to WLb7.

Each string unit SU of the memory cell array 10a includes a plurality of memory groups MG. The plurality of memory groups MG is associated with the bit lines BL0 to BLm (m is an integer of 1 or larger). Each memory group MG includes two NAND strings NSa and NSb. The NAND string NSa includes memory cell transistors MCa0 to MCa7 and select transistors STa1 and STa2. The NAND string NSb includes memory cell transistors MCb0 to MCb7 and select transistors STb1 and STb2. The select transistors STa1, STb1, STa2, and STb2 are used to select the string unit SU and the NAND string NS. Each of the memory cell transistors MCa and MCb is a transistor having a control gate and a charge storage layer, and holds data in a nonvolatile manner. The memory cell transistors MCa and MCb are floating gate-type memory cells.

The drain ends of the select transistors STa1 and STb1 are connected to the associated bit lines BL. The source end of the select transistor STa1 is connected to one end of the memory cell transistors MCa0 to MCa7 connected in series, that is, the drain end of the memory cell transistor MCa7. The other end of the memory cell transistors MCa0 to MCa7 connected in series, that is, the source end of the memory cell transistor MCa0 is connected to the drain end of the select transistor STa2. The source end of the select transistor STb1 is connected to one end of the memory cell transistors MCb0 to MCb7 connected in series, that is, the drain end of the memory cell transistor MCb7. The other end of the memory cell transistors MCb0 to MCb7 connected in series, that is, the source end of the memory cell transistor MCb0 is connected to the drain end of the select transistor STb2. The source ends of the select transistors STa2 and STb2 are connected to the source line SL.

The gate ends of the plurality of select transistors STa1 included in the same block BLK are connected to a common select gate line SGDa for each string unit SU. The gate ends of the plurality of select transistors STb1 included in the same block BLK are connected to a common select gate line SGDb for each string unit SU. Specifically, the plurality of select transistors STa1 included in the string unit SU0 is connected to the select gate line SGDa0. The plurality of select transistors STb1 included in the string unit SU0 is connected to the select gate line SGDb0. The plurality of select transistors STa1 included in the string unit SU1 is connected to the select gate line SGDa1. The plurality of select transistors STb1 included in the string unit SU1 is connected to the select gate line SGDb1. Similarly, the plurality of select transistors STa1 included in the string units SU2 to SU5 is connected to the select gate lines SGDa2 to SGDa5, respectively. The plurality of select transistors STb1 included in the string units SU2 to SU5 is connected to the select gate lines SGDb2 to SGDb5, respectively.

The control gate ends of the plurality of memory cell transistors MCa0 to MCa7 included in the same block BLK are connected to the word lines WLa0 to WLa7, respectively. The control gate ends of the memory cell transistors MCb0 to MCb7 included in the same block BLK are connected to the word lines WLb0 to WLb7, respectively.

The gate ends of the plurality of select transistors STa2 included in the same block BLK are connected to the select gate line SGSa. The gate ends of the plurality of select transistors STb2 included in the same block BLK are connected to the select gate line SGSb.

### <4-1-2> Structure of Memory Cell Array 10a

### (Planar Layout of Memory Cell Array 10a)

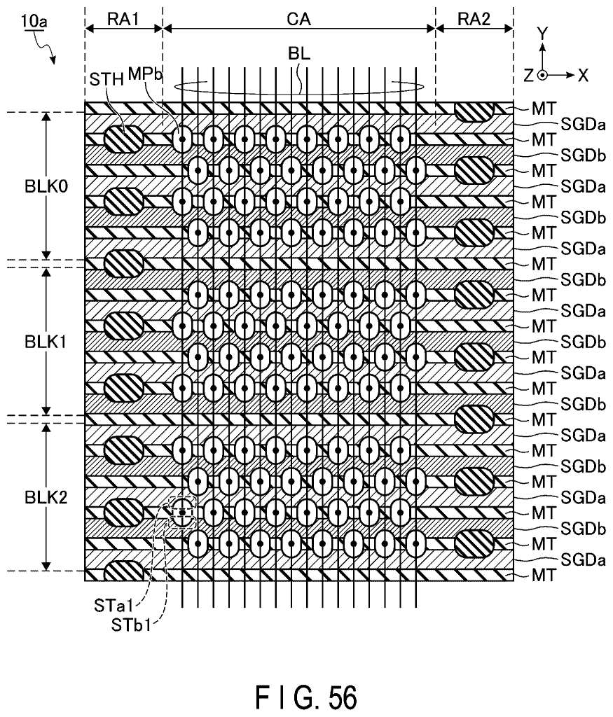

FIG. 56 is a plan view illustrating an example of a planar layout of the memory cell array 10a included in the memory device 1 according to the fourth embodiment. FIG. 56 illustrates extracted regions corresponding to three consecutive blocks BLK0 to BLK2. As illustrated in FIG. 56, the region of the memory cell array 10a includes a cell region CA and replacement regions RA1 and RA2. Each of the cell region CA and the replacement regions RA1 and RA2 is a region extending in the Y direction. The cell region CA is sandwiched between the replacement regions RA1 and RA2 in the X direction. The memory cell array 10a also includes a plurality of memory trenches MT, a plurality of memory pillars MPb, and a plurality of replacement holes STH.

Each of the select gate lines SGDa and SGDb has a portion extending along the X direction, and crosses the cell region CA and the replacement regions RA1 and RA2. The select gate lines SGDa and SGDb are alternately arranged in the Y direction. Although not illustrated, each of the word line WLa and the select gate line SGSa is arranged to overlap the select gate line SGDa in the Z direction, and each of the word line WLb and the select gate line SGSb is arranged to overlap the select gate line SGDb in the Z direction.

Each memory trench MT is arranged between the adjacent select gate lines SGDa and SGDb. The memory trench MT has a portion extending along the X direction. The memory trench MT separates adjacent wiring layers in the Y direction. For example, an insulator is embedded in the memory trench MT. The memory trench MT may have a portion divided by the memory pillar MPb or the replacement hole STH.

Each memory pillar MPb functions as one memory group MG. Each memory pillar MP is arranged so as to divide the memory trench MT and to be in contact with the select gate lines SGDa and SGDb. Although not illustrated, each memory pillar MP is in contact with the word lines WLa and WLb and the select gate lines SGSa and SGSb. A portion where the memory pillar MPb and the select gate line SGDa face each other functions as the select transistor STa1. A portion where the memory pillar MPb and the select gate line SGDb face each other functions as the select transistor STb1. The facing portion between the memory pillar MPb and the word line WLa functions as the memory cell transistor MCa. The facing portion between the memory pillar MPb and the word line WLb functions as the memory cell transistor MCb. A portion where the memory pillar MPb and the select gate line SGSa face each other functions as the select transistor STa2. A portion where the memory pillar MPb and the select gate line SGSb face each other functions as the select transistor STb2.

At least one bit line BL is provided to overlap each memory pillar MP, and one bit line BL is electrically connected to each memory pillar MP. In the region corresponding to each block BLK, the plurality of memory pillars MPb is arranged in four rows in a staggered manner, for example. In a boundary portion between the adjacent blocks BLK, the memory trench MT not divided by the memory pillar MP is arranged. The memory cell array 10b is split into blocks BLK by being partitioned by the memory trenches MT not divided by the memory pillars MPb.

Each replacement hole STH is used at the time of forming the stacked wiring. For example, the plurality of replacement holes STH includes replacement holes STH arranged to overlap the even-numbered memory trenches MT arranged in the replacement region RA1 and replacement holes STH arranged to overlap the odd-numbered memory trenches MT arranged in the replacement region RA2. Each replacement hole STH divides the memory trench MT and is in contact with the select gate lines SGDa and SGDb. For example, an insulator is embedded in the replacement hole STH.

### (Cross-Sectional Structure of Memory Cell Array 10a)

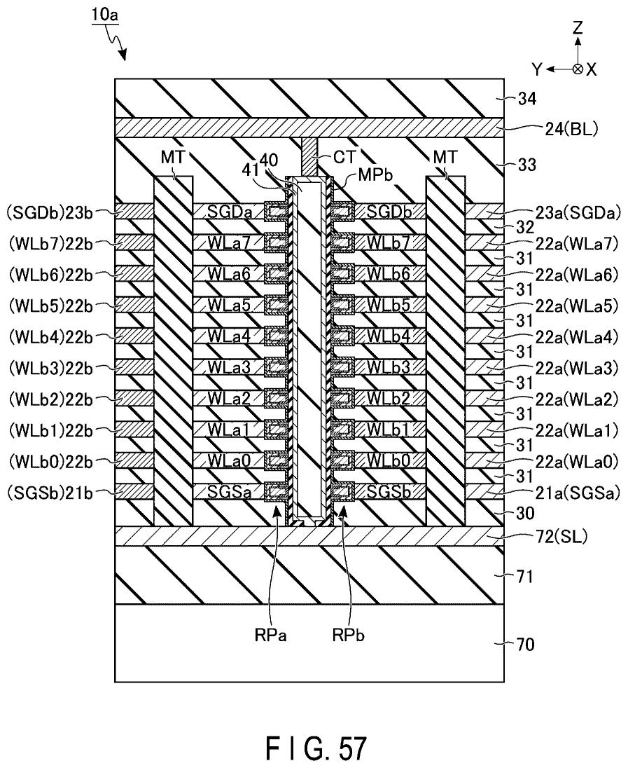

FIG. 57 is a cross-sectional view of an example of a cross-sectional structure of the memory cell array 10a included in the memory device 1 according to the fourth embodiment. FIG. 57 illustrates an extracted cross section including two adjacent memory trenches MT and a memory pillar MPb arranged between the two adjacent memory trenches MT. As illustrated in FIG. 57, the memory cell array 10a includes a semiconductor substrate 70, conductor layers 21a, 21b, 22a, 22b, 23a, 23b, 24, and 72, insulator layers 30 to 34 and 71, and a contact CT, for example.

The semiconductor substrate 70 is a P-type silicon substrate, for example. An insulator layer 71 is provided on the semiconductor substrate 70. The insulator layer 71 includes a configuration corresponding to elements provided on the semiconductor substrate 70, wiring, and a contact. For example, the insulator layer 71 is provided with a circuit such as the row decoder module 16. A conductor layer 72 is provided on the insulator layer 71. The conductor layer 72 is formed in a plate shape extending along the XY plane, for example, and is used as the source line SL. The conductor layer 72 includes phosphorus-doped silicon, for example. The conductor layer 72 may include a plurality of types of semiconductor layers or may include a metal layer.

The insulator layer 30 is provided on the conductor layer 72. The conductor layer 21 is provided on the insulator layer 30. The conductor layer 21 in the fourth embodiment is divided into the conductor layers 21a and 21b by the memory trenches MT and the memory pillars MPb. The insulator layers 31 and the conductor layers 22 are alternately stacked on the conductor layer 21. The conductor layer 22 in the fourth embodiment is divided into the conductor layers 22a and 22b by the memory trenches MT and the memory pillars MPb. The insulator layer 32 is provided on the uppermost conductor layer 22. The conductor layer 23 is provided on the insulator layer 32. The conductor layer 23 in the fourth embodiment is divided into the conductor layers 23a and 23b by the memory trenches MT and the memory pillars MPb. The insulator layer 33 is provided on the conductor layer 23. The conductor layer 24 is provided on the insulator layer 33. The insulator layer 34 is provided on the conductor layer 24. The wiring layer on which the insulator layer 34 is formed is provided with wiring, contacts, and the like for connecting the memory cell array 10a to the row decoder module 16 and the sense amplifier module 17.

Each of the conductor layers 21a, 21b, 22a, 22b, 23a, and 23b has a portion formed in a line shape extending along the X direction. The conductor layers 21a and 21b are used as select gate lines SGSa and SGSb, respectively. The plurality of conductor layers 22a is used as the word lines WLa0 to WLa7 in order from the bottom. The plurality of conductor layers 22b is used as the word lines WLb0 to WLb7 in order from the bottom. The conductor layers 23a and 23b are used as the select gate lines SGDa and SGDb, respectively. The conductor layer 24 is used as the bit line BL. Each of the conductor layers 21a, 21b, 22a, 22b, 23a, and 23b contains tungsten, for example.

The memory pillar MPb extends along the Z direction. The memory pillar MPb has recess portions RPa and RPb. Each of the recess portions RPa and RPb corresponds to a portion protruding in a direction along the Y direction from a portion provided to extend along the Z direction of the memory pillar MPb. The recess portion RPa is in contact with conductor layers 21a, 22a, and 23a. The recess portion RPb is in contact with conductor layers 21b, 22b, and 23b. The memory pillar MPb includes a core member 40 and a semiconductor layer 41. The core member 40 extends along the Z direction. The semiconductor layer 41 of the memory pillar MPb covers the periphery of the core member 40. A lower portion of the semiconductor layer 41 is in contact with the conductor layer 72. An upper portion of the semiconductor layer 41 is connected to the conductor layer 24 via the contact CT. The memory pillar MPb is provided on the side surfaces of the semiconductor layer 41 and includes a stacked portion including the floating gate portions FG1 and FG2. Details of the stacked portion will be described later.

The memory trench MT divides the conductor layers 21 to 23 and the insulator layers 30 to 32. An insulator is embedded in the memory trench MT. The upper end of the memory trench MT is in contact with the insulator layer 33. The lower end of the memory trench MT is in contact with the conductor layer 72. A plurality of types of materials may be embedded in the memory trench MT. The memory trench MT insulates at least adjacent conductor layers.

The plurality of conductor layers 22a (word lines WLa) provided at the same height is electrically connected for each block BLK in a region (not illustrated). The plurality of conductor layers 22b (word lines WLb) provided at the same height is electrically connected for each block BLK in a region (not illustrated). The plurality of conductor layers 21a (select gate lines SGSa) provided at the same height is electrically connected for each block BLK in a region (not illustrated). The plurality of conductor layers 21b (select gate lines SGSb) provided at the same height is electrically connected for each block BLK in a region (not illustrated).

### (Cross-Sectional Structure of Memory Pillar MPa)

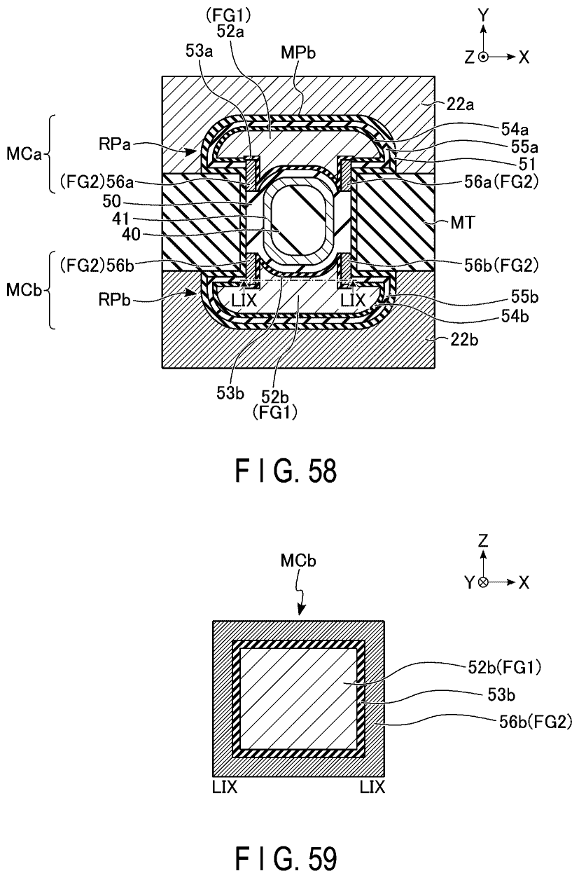

FIG. 58 is a cross-sectional view of an example of a cross-sectional structure of the memory pillar MPa included in the memory device 1 according to the fourth embodiment. FIG. 58 illustrates a cross section along the XY plane including the memory cell transistors MCa and MCb. As illustrated in FIG. 58, the memory pillar MPb includes insulator layers 50 and 51, semiconductor layers 52a and 52b, insulator layers 53a and 53b, insulator layers 54a, 54b, 55a and 55b, and semiconductor layers 56a and 56b, for example. Each of semiconductor layer 52a and insulator layers 53a, 54a, and 55a is provided corresponding to the recess portion RPa. Each of semiconductor layer 52b and insulator layers 53b, 54b, and 55b is provided corresponding to the recess portion RPb.

The core member 40 of the memory pillar MPb is provided at the central portion of the memory pillar MPb. The semiconductor layer 41 of the memory pillar MPb covers the side surfaces of the core member 40. The insulator layer 50 covers the side surfaces of the semiconductor layer 41. The insulator layer 51 is provided along the outer peripheral portion of the memory pillar MP. The insulator layer 51 is in contact with the conductor layer 22a in the recess portion RPa, and is in contact with conductor layer 22b in the recess portion RPb. The insulator layer 51 is provided between the memory trench MT and the semiconductor layer 41.

The semiconductor layer 52a is provided in the center of the recess portion RPa. The periphery of the semiconductor layer 52a is covered by a set of insulator layers 53a and 54a. The insulator layer 53a has a portion provided between the insulator layer 50 and the semiconductor layer 52a. The insulator layer 54a is in contact with the semiconductor layer 52a and the insulator layer 55a, and has a portion provided between the semiconductor layer 52a and the conductor layer 22a and a portion provided between the semiconductor layer 52a and the memory trench MT. The insulator layer 55a is in contact with the insulator layers 54a and 51, and has a portion provided between the insulator layer 54a and the conductor layer 22a and a portion provided between the insulator layer 54a and the memory trench MT. The semiconductor layer 56a is covered with a set of insulator layers 50, 51, 53a, 54a, and 55a, for example. The semiconductor layer 56a has a portion provided between the conductor layer 22a and the semiconductor layer 41. The semiconductor layer 56a is separated and insulated from at least the semiconductor layers 41 and 52a and the conductor layer 22a. In the recess portion RPa, the semiconductor layer 52a has a larger volume ratio than the semiconductor layer 56a.

The semiconductor layer 52b is provided in the center of the recess portion RPb. The periphery of the semiconductor layer 52b is covered with a set of insulator layers 53b and 54b. The insulator layer 53b has a portion provided between the insulator layer 50 and the semiconductor layer 52b. The insulator layer 54b is in contact with the semiconductor layer 52b and the insulator layer 55b, and has a portion provided between the semiconductor layer 52b and the conductor layer 22b and a portion provided between the semiconductor layer 52b and the memory trench MT. The insulator layer 55b is in contact with the insulator layers 54b and 51, and has a portion provided between the insulator layer 54b and the conductor layer 22b and a portion provided between the insulator layer 54b and the memory trench MT. The semiconductor layer 56b is covered with a set of insulator layers 50, 51, 53b, 54ba, and 55b, for example. The semiconductor layer 56b has a portion provided between the conductor layer 22b and the semiconductor layer 41. The semiconductor layer 56b is separated and insulated from at least the semiconductor layers 41 and 52b and the conductor layer 22b. In the recess portion RPb, the semiconductor layer 52b has a larger volume ratio than the semiconductor layer 56b.

The semiconductor layer 52a corresponds to the floating gate portion FG1 of the memory cell transistor MCa provided in the recess portion RPa. The semiconductor layer 52b corresponds to the floating gate portion FG1 of the memory cell transistor MCb provided in the recess portion RPb. The semiconductor layer 56a corresponds to the floating gate portion FG2 of the memory cell transistor MCa provided in the recess portion RPa. The semiconductor layer 56b corresponds to the floating gate portion FG2 of the memory cell transistor MCb provided in the recess portion RPb. The insulator layers 50, 53a, and 53b correspond to tunnel insulating films. The insulator layers 51, 54a, 54b, 55a, and 55b correspond to block insulating films. The semiconductor layer 41 contains silicon, for example. The insulator layer 51 is a silicon oxide film (SiO), for example. The semiconductor layers 52a and 52b contain silicon, for example. The insulator layers 53a and 53b are silicon oxide films (SiO), for example. The insulator layer 54 is a silicon oxide film (SiO), for example. The insulator layer 55 is a silicon oxide film (HfSiO) containing hafnium, for example. The semiconductor layers 56a and 56b contain silicon, for example. In the memory pillar MPb, the semiconductor layer 41 may be divided corresponding to the recess portions RPa and RPb.

FIG. 59 illustrates a cross section taken along line LIX-LIX in FIG. 58 and taken along the XZ plane of the floating gate portions FG1 and FG2 included in the same memory cell transistor MC. As illustrated in FIG. 59, in the memory cell transistor MCb, the semiconductor layer 56b is provided in an annular shape. The insulator layer 53b is provided between the semiconductor layers 56b and 52b. Similarly, although not illustrated, in the memory cell transistor MCa, the semiconductor layer 56a is provided in an annular shape. The insulator layer 53b is provided between the semiconductor layers 56a and 52ab.

### <4-2> Operations

Next, operations of the memory device 1 according to the fourth embodiment will be described. In the following description, the memory group MG connected to the program bit line BLprog will be called “selected memory group”. The memory group connected to the program-inhibit bit line BLinh will be called “unselected memory group”.

### (Specific Example of HE Program)

FIG. 60 is a schematic diagram illustrating a specific example of an HE program for the selected memory group in the memory device 1 according to the fourth embodiment. FIG. 60 illustrates voltages applied to the word lines WLa (k−1), WLa (k), and WLa (k+1), the word lines WLb (k−1), WLb (k), and WLb (k+1), and the select gate lines SGDa, SGSa, SGDb, and SGSb of the selected memory group in a case where the word line WLa (k) is set as the selected word line WLsel in the HE program.

As illustrated in FIG. 60, in the HE program, the sequencer 14 applies VHEP to the word line WLa (k), applies VPASS to the word lines WLa (k−1), WLa (k+1), WLb (k−1), WLb (k), and WLb (k+1), and applies VDDH, VDD, VSS, and VSS to the select gate lines SGDa, SGSa, SGDb, and SGSb of the selected memory group, respectively.

Accordingly, the select transistors STa1 and STa2 are turned on, and electrons are supplied to the channel of the NAND string NSa based on the voltage difference between the source line SL and the program bit line BLprog. On the other hand, the select transistors STb1 and STb2 are turned off, and the current path between the source line SL and the program bit line BLprog is shut off. Accordingly, electrons are injected into the floating gate portion FG2 of the memory cell transistor MCa (k) based on the voltage of the word line WLa (k) and the channel current. On the other hand, in the NAND string NSb, the current path between the source line SL and the program bit line BLprog is shut off. Therefore, even if VHEP is applied to the word line WL (k), injection of electrons into the floating gate portion FG2 of the memory cell transistor MCb (k) is suppressed.

In the HE program, electrons may be injected into the floating gate portion FG1 of the selected memory cell transistor MCsel. This is because even if the threshold voltage of the selected memory cell transistor MCsel changes, the threshold voltage of the selected memory cell transistor MCsel rises until reaching the target state by the subsequent loop process.

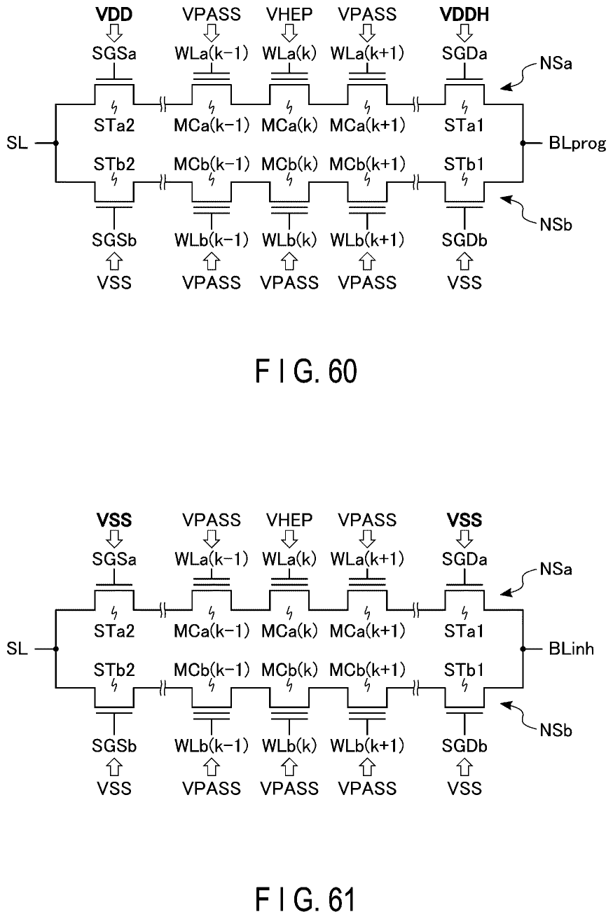

FIG. 61 is a schematic diagram illustrating a specific example of an HE program for the unselected memory group in the memory device 1 according to the fourth embodiment. FIG. 61 illustrates voltages applied to the word lines WLa (k−1), WLa (k), and WLa (k+1), the word lines WLb (k−1), WLb (k), and WLb (k+1), and the select gate lines SGDa, SGSa, SGDb, and SGSb of the selected memory group in a case where the word line WL (k) is set as the selected word line WLsel in the HE program.

As illustrated in FIG. 61, in the HE program, the sequencer 14 applies VHEP to the word line WLa (k), applies VPASS to the word lines WLa (k−1), WLa (k+1), WLb (k−1), WLb (k), and WLb (k+1), and applies VSS to the select gate lines SGDa, SGSa, SGDb, and SGSb of the unselected memory group. Accordingly, the select transistors STa1, STa2, STb1, and STb2 are turned off, and the current path between the source line SL and the program bit line BLprog is shut off in each of the NAND strings NSa and NSb. Therefore, even if VHEP is applied to the word line WLa (k), injection of electrons into the floating gate portion FG2 of the memory cell transistor MCa (k) is suppressed.

### (Specific Example of FN Program)

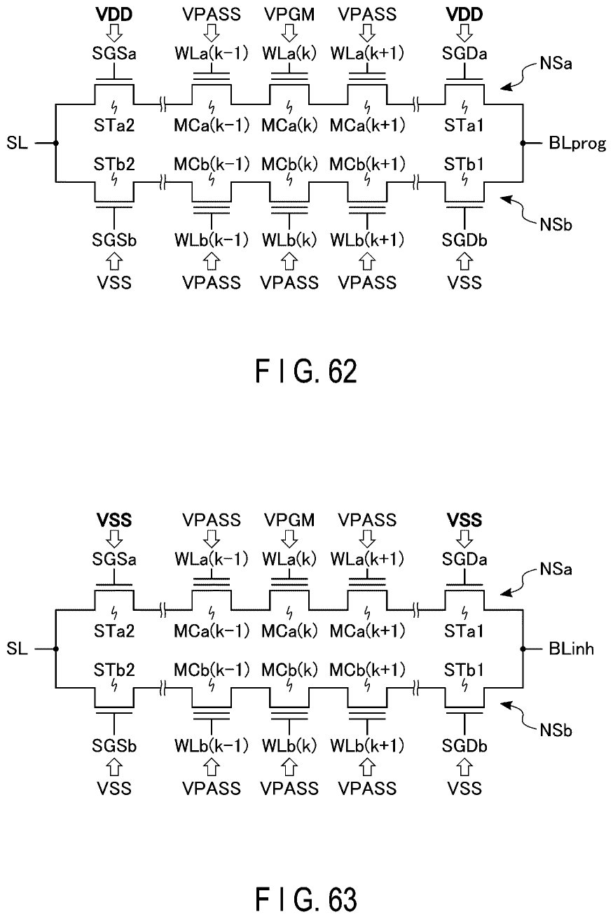

FIG. 62 is a schematic diagram illustrating a specific example of an FN program for the selected memory group in the memory device 1 according to the fourth embodiment. FIG. 62 illustrates voltages applied to the word lines WLa (k−1), WLa (k), and WLa (k+1), the word lines WLb (k−1), WLb (k), and WLb (k+1), and the select gate lines SGDa, SGSa, SGDb, and SGSb of the selected memory group in a case where the word line WLa (k) is set as the selected word line WLsel in the FN program.

As illustrated in FIG. 62, in the FN program, the sequencer 14 applies VPGM to the word line WLa (k), applies VPASS to the word lines WLa (k−1), WLa (k+1), WLb (k−1), WLb (k), and WLb (k+1), and applies VDD, VDD, VSS, and VSS to the select gate lines SGDa, SGSa, SGDb, and SGSb of the selected memory group, respectively.

Accordingly, the select transistors STa1 and STa2 are turned on, and the channel potential of the NAND string NSa becomes VSS based on the voltage applied to the program bit line BLprog. Then, electrons are injected into the floating gate portion FG1 of the memory cell transistor MCa (k) based on the potential difference between the word line WLa (k) and the channel. On the other hand, the select transistors STb1 and STb2 are turned off, and the channel potential of the NAND string NSa is boosted based on VPASS. As a result, in the NAND string NSb, injection of electrons into the floating gate portion FG2 of each memory cell transistor MCb (k) is suppressed.

FIG. 63 is a schematic diagram illustrating a specific example of an FN program for the unselected memory group in the memory device 1 according to the fourth embodiment. FIG. 63 illustrates voltages applied to the word lines WLa (k−1), WLa (k), and WLa (k+1), the word lines WLb (k−1), WLb (k), and WLb (k+1), and the select gate lines SGDa, SGSa, SGDb, and SGSb of the selected memory group in a case where the word line WLa (k) is set as the selected word line WLsel in the FN program.

As illustrated in FIG. 63, in the FN program, the sequencer 14 applies VPGM to the word line WLa (k), applies VPASS to the word lines WLa (k−1), WLa (k+1), WLb (k−1), WLb (k), and WLb (k+1), and applies VSS to the select gate lines SGDa, SGSa, SGDb, and SGSb of the selected memory group. Accordingly, the select transistors STa1, STa2, STb1, and STb2 are turned off, and the current path between the source line SL and the program bit line BLprog is shut off in each of the NAND strings NSa and NSb. Therefore, the channel potentials of the NAND strings NSa and NSb are boosted based on VPASS. As a result, in each of the NAND strings NSa and NSb of the unselected memory group, injection of electrons into the floating gate portion FG1 of each memory cell transistor MCa and the floating gate portion FG1 of each memory cell transistor MCb is suppressed.

Other operations of the memory device 1 according to the fourth embodiment are similar to those of the third embodiment.

### <4-3> Manufacturing Method

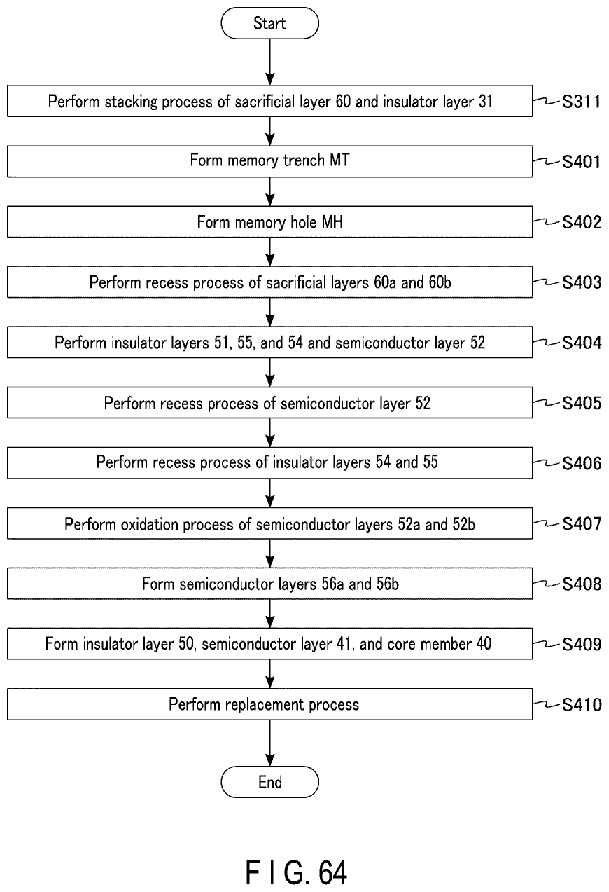

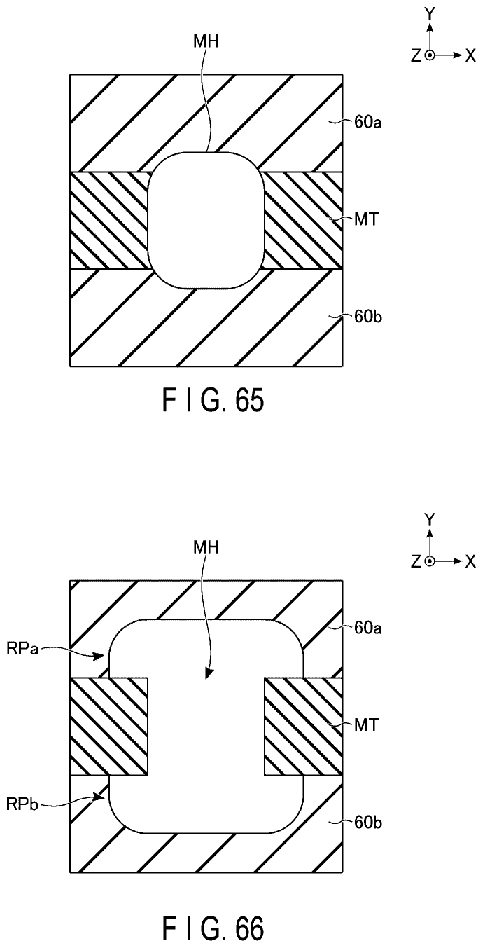

Next, an example of a method of manufacturing the memory device 1 according to the fourth embodiment will be described with reference to FIG. 64 as appropriate. FIG. 64 is a flowchart illustrating an example of a method of manufacturing the memory device 1 according to the fourth embodiment. Each of FIGS. 65 to 72 referred to below is a cross-sectional view of an example of a cross-sectional structure in the process of manufacturing the memory device 1 according to the fourth embodiment. Each of FIGS. 65 to 72 illustrates a region where the memory pillar MP illustrated in FIG. 58 is to be formed.

First, as in the third embodiment, a stacking process of a sacrificial layer 60 and the insulator layer 31 is executed (S311). As a result, for example, a structure in which the insulator layer 31 and the sacrificial layer 60 are alternately stacked is formed on the semiconductor substrate 20.

Next, the memory trench MT is formed (S401). Specifically, first, the memory trench MT is formed by photolithography processing and etching processing. The memory trench MT is provided by dividing the stacked sacrificial layer 60 and insulator layer 31. Then, the formed memory trench MT is filled with an insulator. Hereinafter, in the sacrificial layer 60 divided by the memory trench MT, a portion adjacent to one side of the memory trench MT will be called “sacrificial layer 60a”, and a portion adjacent to the other side of the memory trench MT will be called “sacrificial layer 60b”.

Next, as illustrated in FIG. 65, a memory hole MH is formed (S402). The memory hole MH of the fourth embodiment divides the memory trench MT. In the memory hole MH, the sacrificial layers 60a and 60b are partially exposed.

Next, a recess process of the sacrificial layer 60 is executed (S403). As illustrated in FIG. 66, portions of the sacrificial layers 60a and 60b exposed on the side surfaces of the memory hole MH are removed in step S403. Accordingly, spaces corresponding to the recess portions RPa and RPb of the memory pillar MP are formed on the side surfaces of the memory hole MH.

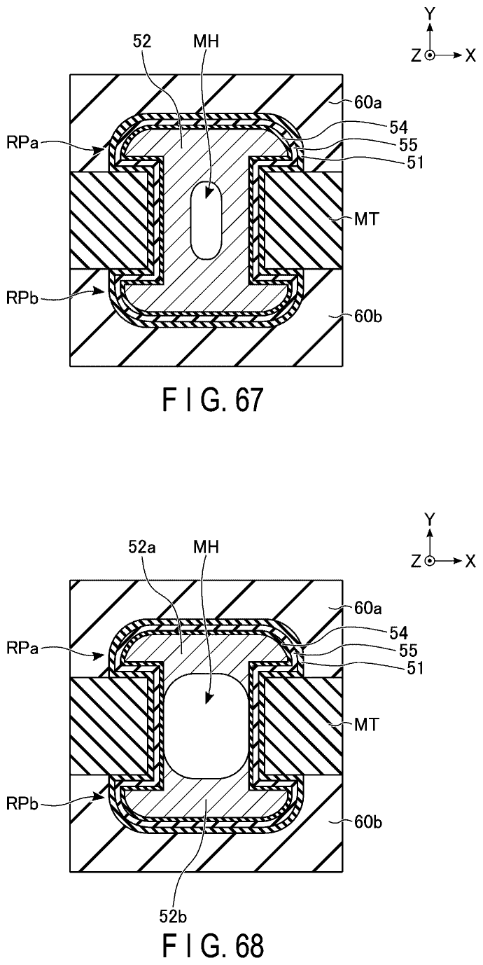

Next, as illustrated in FIG. 67, the insulator layers 51, 55, and 54 and the semiconductor layer 52 are formed (S404). The insulator layers 51, 55, and 54 are sequentially formed along the side surfaces of the memory hole MH and the recess portion RP. The semiconductor layer 52 is formed so as to fill the spaces corresponding to the recess portions RPa and RPb and not to fill the memory hole MH.

Next, a recess process of the semiconductor layer 52 is executed (S405). In step S405, as illustrated in FIG. 68, the semiconductor layer 52 provided on the side surface portions of the memory hole MH is removed, and a portion of the insulator layer 54 is exposed in the memory hole MH. Accordingly, the semiconductor layer 52 is separated into a portion (semiconductor layer 52a) provided in the recess portion RPa and a portion (the semiconductor layer 52b) provided in the recess portion RPb.

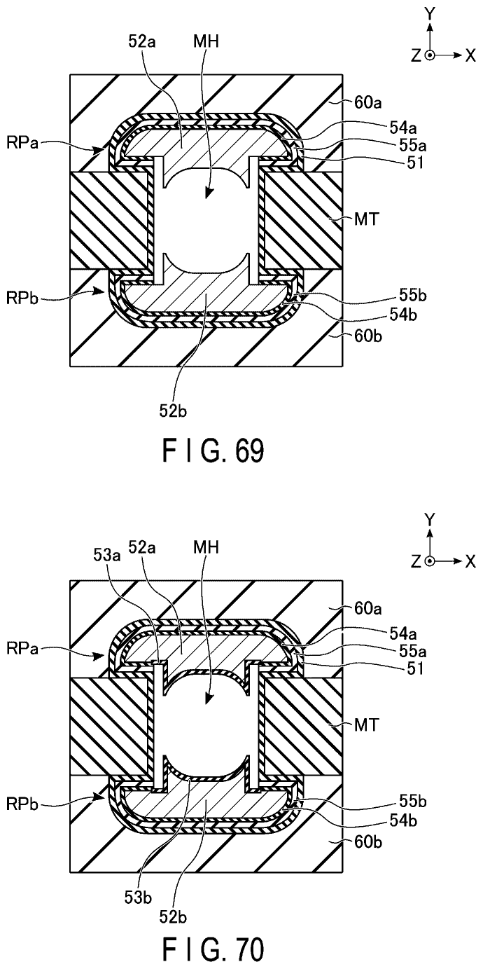

Next, a recess process of the insulator layers 54 and 55 is performed (S406). In step S406, as illustrated in FIG. 69, portions of the insulator layers 54 and 55 exposed at the side surface portions of the memory hole MH are removed so as to enter the recess portions RPa and RPb. Also in this step, the insulator layer 54 is separated into a portion (the insulator layer 54a) provided in the recess portion RPa and a portion (the insulator layer 54b) provided in the recess portion RPb. Similarly, the insulator layer 55 is separated into a portion (the insulator layer 55a) provided in the recess portion RPa and a portion (the insulator layer 55b) provided in the recess portion RPb.

Next, an oxidation process of the semiconductor layers 52a and 52b is executed (S407). Accordingly, as illustrated in FIG. 70, the surface portions of the semiconductor layers 52a and 52b exposed in the memory hole MH are oxidized to form the insulator layers 53a and 54b. At this time, the semiconductor layer 52a is surrounded by the insulator layers 53a and 54a. The semiconductor layer 52b is surrounded by the insulator layers 53b and 54b.

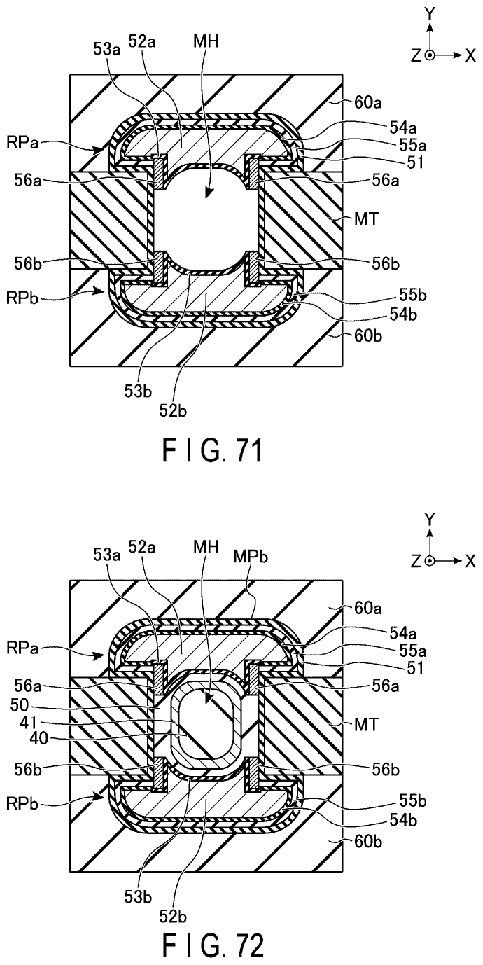

Next, as illustrated in FIG. 71, the semiconductor layers 56a and 56b are formed (S408). Specifically, first, the semiconductor layer 56 is provided on the side surface portions of the memory hole MH. Accordingly, the space portions provided in the recess portions RPa and RPb are filled with the semiconductor layer 56. Thereafter, the semiconductor layer 56 provided on the side surface portions of the memory hole MH is removed by wet etching or the like. Accordingly, the semiconductor layer 56 is separated into a portion (semiconductor layer 56a) provided in the recess portion RPa and a portion (the semiconductor layer 56b) provided in the recess portion RPb.

Next, as illustrated in FIG. 72, the insulator layer 50, the semiconductor layer 41, and the core member 40 are formed (S409). The insulator layer 55 and the semiconductor layer 41 are sequentially formed along the side surfaces of the memory hole MH. The core member 40 is formed so as to fill the memory hole MH. Accordingly, a structure is formed in which the semiconductor layers 52a and 41 are adjacent to each other with the insulator layers 50 and 53a in between. Similarly, a structure is formed in which the semiconductor layers 52b and 41 are adjacent to each other with the insulator layers 50 and 53b in between.

Next, a replacement process is executed (S410). Specifically, first, a replacement hole STH is formed. Then, the stacked sacrificial layers 60a and 60b are selectively removed via the replacement hole STH by wet etching with hot phosphoric acid or the like. Then, a conductor is embedded in the space from which the sacrificial layers 60a and 60b have been removed via the replacement hole STH. For the formation of the conductor in this step, CVD is used, for example. Thereafter, the conductor formed on the side surface portion of the replacement hole STH is removed by etch-back processing, and the conductors formed on the adjacent wiring layers are separated. Accordingly, a stacked wiring including a plurality of conductor layers 22a functioning as the word lines WLa and a plurality of conductor layers 22b functioning as the word lines WLb is formed.

### <4-4> Advantageous Effects of Fourth Embodiment

The memory device 1 according to the fourth embodiment can obtain the same advantageous effects as those of the third embodiment. Furthermore, in the memory device 1 according to the fourth embodiment, since the memory pillar MPb has a structure including the two NAND strings NSa and NSb, the storage capacity can be increased as compared with the third embodiment.

### <5> Others

In the third embodiment, the case of forming the threshold voltage distribution of the memory cell transistor MC in the first embodiment has been described. However, the present invention is not limited thereto. The third embodiment can also form the threshold voltage distribution of the memory cell transistor MC in the second embodiment. In this case, the memory device 1 according to the third embodiment executes the write operation in which steps S104 to S106 are replaced with steps S201 to S206 illustrated in FIG. 25, in accordance with the flowchart illustrated in FIG. 32. Similarly, the memory device 1 according to the fourth embodiment may form the threshold voltage distribution of the memory cell transistor MC in either the first embodiment or the second embodiment.

In the above embodiments, the write order of data in each NAND string NS begins from the memory cell transistor MC on the bit line BL side. However, the present invention is not limited thereto. The write order of data in each NAND string NS may begin from the memory cell transistor MC on the source line SL side. In this case, the storage unit P2 of the memory cell transistor MC (k) faces a portion between the word lines WL (k) and WL (k+1) and is associated with a portion adjacent to the storage unit P1 of the memory cell transistor MC (k). If the selected word line WLsel is the word line WL (k), in each program operation (for example, the “ACE” program, the “BDFG” program, the HE program, and the FN program), the voltage applied to the word line WL (k+1) and the voltage applied to the word line WL (k−1) are interchanged.

In the above embodiments, the memory cell transistor MC stores 3-bit data. However, the present invention is not limited thereto. The memory cell transistor MC may be capable of storing data of two bits or four bits or more. In other words, in the above embodiment, the memory cell transistor MC may be configured to store multi-bit data at a threshold voltage level of two or more values. The technical ideas in the first to fourth embodiments can be applied regardless of the number of bits stored in the memory cell transistor MC.

In the above embodiments, in the read operation using a plurality of read voltages, the sequencer 14 applies the read voltages to the selected word line WLsel in order beginning from the higher read voltage. However, the present invention is not limited thereto. The sequencer 14 may apply the read voltages to the selected word line WLsel in order beginning from the lower read voltage. In the above embodiments, the determination results of a plurality of reads are stored in the latch circuit of the sense amplifier unit SAU. However, the present invention is not limited thereto. The arithmetic processing for determining the data may be sequentially executed according to the progress of the read operation.

In the above embodiments, the memory cell array 10 may include dummy wiring. For example, the memory cell array 10 may include one or more dummy word lines between the uppermost word line WL and the select gate line SGD. Similarly, the memory cell array 10 may include one or more dummy word lines between the lowermost word line WL and the select gate line SGS. The intersecting portion between the dummy word line and the memory pillar MP corresponds to the memory cell transistor MC which is not used to store data. By using the dummy word line, the memory device 1 can execute the write operation in the above embodiments on the memory cell transistor MC arranged at the end portion of the NAND string NS. Similarly, the memory cell array 10a may include dummy wiring.

The timing charts used for describing the write operations in the above embodiments are merely examples. For example, the timings at which the voltages of the signal and the wiring are controlled at individual times may be shifted. The order of some of the steps in each flowchart can be changed within a possible range. For example, the ordinal number of the verify operation to be executed in the loop process can be changed as appropriate. In the above embodiments, the voltages applied to the various wirings in the memory cell array 10 may be estimated based on the voltages of the signal lines CG, SGDD, SGDS, USGD, USGS, and the like. For example, the voltage applied to the selected word line WLsel can be estimated based on the voltage of the signal line CG.

The term “connection” herein refers to electrical connection and does not exclude the intervention of another element between electrically connected components. The off state of the transistor does not exclude the flow of a minute current such as a leakage current. The “H” level is a voltage level at which the N-type MOS transistor to which the voltage is applied to the gate is turned on and the P-type MOS transistor to which the voltage is applied to the gate is turned off. The “L” level is a voltage level at which the N-type MOS transistor to which the voltage is applied to the gate is turned off and the P-type MOS transistor to which the voltage is applied to the gate is turned on. The insulators embedded in the slit SLT, the slit SHE, the memory trench MT, the replacement hole STH, and the like may be called insulating members. Each of VPGM and VHEP may be called program voltage. The term “columnar” indicates a structure provided in a hole formed in the manufacturing process of the memory device 1. The term “diameter (inner diameter)” indicates the diameter of a hole or the like in a cross section parallel to the surface of the substrate. The term “outer diameter” indicates the diameter of the memory pillar MP or the like in a cross section parallel to the surface of the substrate. The term “width” indicates the size of a component in the X direction or the Y direction, for example. The comparison of dimensions is preferably performed in the vicinity of the memory cell transistor MC of interest. The term “semiconductor layer” may be called “conductor layer”. The first to fourth embodiments illustrate the case of 3 bits/1 cell, but the present invention is not limited thereto. The first to fourth embodiments may be applied to memories that store a plurality of thresholds, such as 4-bit/1 cell and 2-bit/1 cell.

While certain embodiments of the present invention have been described, these embodiments have been presented by way of example only, and are not intended to limit the scope of the invention. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a first memory cell configured to store multi-bit data with a k-value threshold voltage level (k is an integer of 2 or larger); and
a sequencer configured to execute a write operation having a loop process including a program operation and a verify operation, wherein
the program operation includes a first program process and a second program process, and
the sequencer further configured to cause the first memory cell to store data by either the first program process or the second program process according to data to be written into the first memory cell in the write operation.

2. The memory device of claim 1, wherein
the first memory cell has:
a first S-factor in storing the data written by the first program process; and
a second S-factor different from the first S-factor in storing the data written by the second program process.

3. The memory device of claim 1, wherein
the sequencer is further configured to use
a first sense time in reading the data written by the first program process from the first memory cell, and
a second sense time different from the first sense time in reading the data written by the second program process from the first memory cell.

4. The memory device of claim 3, further comprising:
a sense amplifier connected to the first memory cell and having a sense node, wherein
each of the first sense time and the second sense time is associated with a time during which a read voltage is applied to the first memory cell from electrical connection between the sense node and the first memory cell to electrical disconnection between the sense node and the first memory cell, and the first sense time is different from the second sense time.

5. The memory device of claim 1, wherein
the k-value threshold voltage level includes first to k-th threshold voltage levels, and
the sequencer is further configured to, in the write operation,
in a case of storing the data in the first memory cell by the first program process, write the memory cell at an n-th threshold voltage level (n is an even number and an integer of 2 or larger and k or smaller), and
in a case of storing the data in the first memory cell by the second program process, write the memory cell at an m-th threshold voltage level (m is an odd number and an integer of 3 or larger and k or smaller).

6. The memory device of claim 5, wherein
the verify operation includes a first verify read and a second verify read, the first verify read being associated with a write of data corresponding to the n-th threshold voltage level and the second verify read being associated with a write of data corresponding to an (n+1)-th threshold voltage level, and
the sequencer is further configured to collectively execute the first verify read and the second verify read using the same verify voltage.

7. The memory device of claim 1, wherein
in the verify operation, the sequencer executes a verify read using the first sense time in each of a case where the first memory cell is a target of the first program process and a case where the first memory cell is a target of the second program process.

8. The memory device of claim 1, wherein
in the verify operation, the sequencer is configured to:
execute a verify read using the first sense time in a case where the first memory cell is a target of the first program process; and
execute a verify read using a second sense time in a case where the first memory cell is a target of the second program process.

9. The memory device of claim 8, further comprising:
a sense amplifier connected to the first memory cell, the sense amplifier having a sense node, wherein
each of the first sense time and the second sense time is associated with a first time,
the first time is associated with a time during which a read voltage is applied to the first memory cell from electrical connection between the sense node and the first memory cell to electrical disconnection between the sense node and the first memory cell, and
the first sense time is different from the second sense time.

10. The memory device of claim 1, further comprising:
a second memory cell and a third memory cell that are connected in series with the first memory cell and are adjacent to the first memory cell, wherein
the sequencer is further configured to
in the first program process for the first memory cell, apply a program voltage to the first memory cell, apply a first voltage to the second memory cell, and apply a third voltage to the third memory cell, and
in the second program process for the first memory cell, apply the program voltage to the first memory cell, apply a fourth voltage lower than the first voltage to the second memory cell, and apply the third voltage to the third memory cell.

11. A memory device comprising:
a memory cell configured to store multi-bit data with a k-value threshold voltage level (k is an integer of 2 or greater);
a select transistor connected to the memory cell;
a bit line connected to the select transistor; and
a sequencer configured to execute a write operation having a first program operation and a loop process, the loop process including a second program operation and a verify operation, wherein
the sequencer is further configured to
in the first program operation in which the memory cell is a program target, apply a first voltage to the select transistor while applying a first program voltage to the memory cell,
in the second program operation in which the memory cell is a program target, apply a second voltage lower than the first voltage to the select transistor while applying a second program voltage to the memory cell, and
in the write operation, execute the first program operation with the memory cell set to be written or be write-inhibited according to data to be written in the memory cell, and store the data in the memory cell by the loop process.

12. The memory device of claim 11, wherein
the memory cell is configured to
have a first S-factor in storing data written by the first program operation, and
have a second S-factor different from the first S-factor in storing data written by the second program operation.

13. The memory device of claim 11, wherein
the memory cell has a first floating gate portion and a second floating gate portion,
the first program operation is a program operation for the second floating gate portion, and
the second program operation is a program operation for the first floating gate portion.

14. The memory device of claim 13, wherein
in the first program operation, electrons are injected into the second floating gate portion using hot electrons, and
in the second program operation, electrons are injected into the first floating gate portion using a Fowler-Nordheim (FN) tunnel current.
